(19) United States
(12) Patent Application Publication
(10) Pub. No.: US 2011/0049609 A1
(43) Pub. Date: Mar. 3, 2011

(54) NONVOLATILE SEMICONDUCTOR MEMORY DEVICE AND METHOD OF MANUFACTURING THE SAME

(75) Inventor: Takaaki Nagai, Kanagawa (JP)

(73) Assignee: RENESAS ELECTRONICS CORPORATION, Kanagawa (JP)

(21) Appl. No.: 12/844,421

(22) Filed: Jul. 27, 2010

(30) Foreign Application Priority Data
Aug. 26, 2009 (JP) 2009-196038

(51) Int. Cl. H01L 29/792; H01L 29/78

(52) U.S. Cl. 257/324; 257/288; 257/E29.309; 257/E29.255

(57) ABSTRACT

A nonvolatile semiconductor memory device has: a first source/drain diffusion region; a second source/drain diffusion region; a channel region between the first source/drain diffusion region and the second source/drain diffusion region; a first charge storage layer formed on the channel region; a second charge storage layer formed in a same layer as the first charge storage layer and electrically isolated from the first charge storage layer; a first gate electrode; and a second gate electrode electrically isolated from the first gate electrode. The first charge storage layer includes a first memory section and a second memory section. The second charge storage layer includes a third memory section and a fourth memory section. The first gate electrode is formed on the first memory section and the third memory section. The second gate electrode is formed on the second memory section and the fourth memory section.

### INCORPORATION BY REFERENCE

This application is based upon and claims the benefit of priority from Japanese patent application No. 2009-196038, filed on Aug. 26, 2009, the disclosure of which is incorporated herein in its entirety by reference.

### BACKGROUND OF THE INVENTION

1. Field of the Invention

The present invention relates to a nonvolatile semiconductor memory device and a method of manufacturing the nonvolatile semiconductor memory device.

2. Description of Related Art

As a data processing technique progresses, it has been demanded to provide a semiconductor memory device which is capable of storing more data while suppressing increase in a memory cell area. To meet such demand, in the field of nonvolatile semiconductor memory devices, there is known a technique regarding an element in which two bit values can be stored by a single memory cell. For example, refer to Japanese Patent Publication JP-2004-247714A (Patent Document 1) and Japanese Patent Publication JP-2004-80022A (Patent Document 2).

The Patent Document 1 discloses a technique regarding a SONGS memory cell which is capable of storing 2-bit data and has excellent data identification characteristics, and a manufacturing method thereof. The memory cell disclosed in the Patent Document 1 includes: a source region and a drain region formed to be separated from each other with a predetermined interval; and a channel region defined between the source region and the drain region, in a semiconductor substrate. Moreover, charge storage insulating layers are formed on edge portions of the channel region which are respectively adjacent to the source region and the drain region. Furthermore, a gate insulating film is formed on the channel region between the charge storage insulating layers, and a gate electrode is formed on the gate insulating film and the charge storage insulating layers.

On manufacturing this element, a multi-layer insulating film, a lower conductive film and a hard mask film are first formed to be stacked in this order on a semiconductor substrate. After that, the hard mask film, the lower conductive film and the multi-layer insulating film are patterned in this order to form a gap region. Then, a gate oxide film is formed on surfaces of the semiconductor substrate and the lower conductive film exposed in the gap region, and a gate pattern is so formed on the gate oxide film as to fill in the gap region.

The Patent Document 2 discloses a technique regarding a method of manufacturing a nonvolatile memory element having a local SONGS structure. According to the technique disclosed in the Patent Document 2, a vertical structure in which a first oxide film pattern, a nitride film pattern and a second oxide film pattern are stacked in this order on a semiconductor substrate is first mode. After that, a third oxide film pattern is formed, and further a polysilicon film is formed on the third oxide film pattern. Next, a control gate electrode is formed through a planarization process. Next, by an etching by using the electrode as a mask, an ONO film, in which a tunneling layer formed of the first oxide film pattern, a charge trap layer formed of the nitride film pattern and a shielding layer formed of the second oxide film pattern are stacked in this order, and a gate insulating film formed of the third oxide film are formed laterally under the control gate electrode. Next, a source region and a drain region are formed by carrying out an ion injection process with respect to the semiconductor substrate.

The inventor of the present application has recognized the following points. In the above-described nonvolatile semiconductor memory device according to the related techniques, a single memory cell is provided with two charge trap layers. Therefore, in the above-described nonvolatile semiconductor memory device according to the related techniques, only a 2-bit data can be stored in the single memory cell.

### SUMMARY

In one embodiment of the present invention, a nonvolatile semiconductor memory device has: a first source/drain diffusion region; a second source/drain diffusion region; a channel region between the first source/drain diffusion region and the second source/drain diffusion region; a first charge storage layer formed on the channel region; a second charge storage layer formed in a same layer as the first charge storage layer and electrically isolated from the first charge storage layer; a first gate electrode; and a second gate electrode electrically isolated from the first gate electrode. The first charge storage layer includes a first memory section and a second memory section. The second charge storage layer includes a third memory section and a fourth memory section. The first gate electrode is formed on the first memory section and the third memory section. The second gate electrode is formed on the second memory section and the fourth memory section.

In another embodiment of the present invention, a nonvolatile semiconductor memory device has memory elements arranged in an array form. Each of the memory elements has: a first charge storage layer including a first trap region and a second trap region; a second charge storage layer including a third trap region and a fourth trap region; a first gate electrode formed on the first trap region and the third trap region; and a second gate electrode formed on the second trap region and the fourth trap region.

In still another embodiment of the present invention, a semiconductor device has: a first element formed between a first device isolation and a second device isolation and comprising: a first gate formed on a side of the first device isolation; and a second gate formed on a side of the second device isolation; a second element formed between the first device isolation and the second device isolation and comprising: a third gate formed on a side of the second device isolation and a fourth gate formed on a side of the first device isolation; a first source diffusion region shared by the first element and the second element; a first drain diffusion region associated with the first element; a second drain diffusion region associated with the second element; a first interconnection connected to the first gate and the fourth gate; a second interconnection connected to the second gate and the third gate; a third interconnection connected to the first drain diffusion region; and a fourth interconnection connected to the second drain diffusion region.

According to the present invention, it is possible to provide a nonvolatile semiconductor memory element which is capable of storing more data while suppressing increase in a memory cell area.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is an equivalent circuit diagram showing a configuration of a nonvolatile semiconductor memory element 2 according to the present embodiment;

FIG. 2 is a plan view showing a structure of the nonvolatile semiconductor memory element 2;

FIG. 3 is a cross sectional view showing a structure of the nonvolatile semiconductor memory element 2;

FIG. 4 is a cross sectional view showing a structure of the nonvolatile semiconductor memory element 2;

FIG. 5 is a cross sectional view showing a structure of the nonvolatile semiconductor memory element 2;

FIG. 6 is a cross sectional view showing a structure of the nonvolatile semiconductor memory element 2;

FIG. 7 is a cross sectional view showing a structure of the nonvolatile semiconductor memory element 2;

FIG. 8 is a cross sectional view showing a structure of the nonvolatile semiconductor memory element 2;

FIGS. 9A to 9G show a state in a first process for manufacturing the nonvolatile semiconductor memory element 2 according to a first embodiment;

FIGS. 10A to 10G show a state in a second process for manufacturing the nonvolatile semiconductor memory element 2;

FIGS. 11A to 11G show a state in a third process for manufacturing the nonvolatile semiconductor memory element 2;

FIGS. 12A to 12G show a state in a fourth process for manufacturing the nonvolatile semiconductor memory element 2;

FIGS. 13A to 13G show a state in a fifth process for manufacturing the nonvolatile semiconductor memory element 2;

FIGS. 14A to 14G show a state in a sixth process for manufacturing the nonvolatile semiconductor memory element 2;

FIGS. 15A to 15G show a state in a seventh process for manufacturing the nonvolatile semiconductor memory element 2;

FIGS. 16A to 16G show a state in an eighth process for manufacturing the nonvolatile semiconductor memory element 2;

FIGS. 17A to 17G show a state in a ninth process for manufacturing the nonvolatile semiconductor memory element 2;

FIGS. 18A to 18G show a state in a tenth process for manufacturing the nonvolatile semiconductor memory element 2;

FIGS. 19A to 19G show a state in an eleventh process for manufacturing the nonvolatile semiconductor memory element 2;

FIGS. 20A to 20G show a state in a twelfth process for manufacturing the nonvolatile semiconductor memory element 2;

FIGS. 21A to 21G show a state in a thirteenth process for manufacturing the nonvolatile semiconductor memory element 2;

FIGS. 22A to 22G show a state in a fourteenth process for manufacturing the nonvolatile semiconductor memory element 2;

FIGS. 23A to 23G show a state in a fifteenth process for manufacturing the nonvolatile semiconductor memory element 2;

FIGS. 24A to 24G show a state in a sixteenth process for manufacturing the nonvolatile semiconductor memory element 2;

FIGS. 25A to 25G show a state in a seventeenth process for manufacturing the nonvolatile semiconductor memory element 2;

FIGS. 26A to 26G show a state in an eighteenth process for manufacturing the nonvolatile semiconductor memory element 2;

FIG. 27 is a plan view showing a structure of the nonvolatile semiconductor memory element 2 according to a second embodiment;

FIG. 28 is a cross sectional view showing a structure of the nonvolatile semiconductor memory element 2 according to the second embodiment;

FIG. 29 is a cross sectional view showing a structure of the nonvolatile semiconductor memory element 2 according to the second embodiment;

FIG. 30 is a cross sectional view showing a structure of the nonvolatile semiconductor memory element 2 according to the second embodiment;

FIG. 31 is a cross sectional view showing a structure of the nonvolatile semiconductor memory element 2 according to the second embodiment;

FIG. 32 is a cross sectional view showing a structure of the nonvolatile semiconductor memory element 2 according to the second embodiment;

FIG. 33 is a cross sectional view showing a structure of the nonvolatile semiconductor memory element 2 according to the second embodiment;

FIGS. 34A to 34G show a state in a first process for manufacturing the nonvolatile semiconductor memory element 2 according to the second embodiment;

FIGS. 35A to 35G show a state in a second process for manufacturing the nonvolatile semiconductor memory element 2 according to the second embodiment;

FIGS. 36A to 36G show a state in a third process for manufacturing the nonvolatile semiconductor memory element 2 according to the second embodiment;

FIGS. 37A to 37G show a state in a fourth process for manufacturing the nonvolatile semiconductor memory element 2 according to the second embodiment;

FIGS. 38A to 38G show a state in a fifth process for manufacturing the nonvolatile semiconductor memory element 2 according to the second embodiment;

FIGS. 39A to 39G show a state in a sixth process for manufacturing the nonvolatile semiconductor memory element 2 according to the second embodiment;

FIGS. 40A to 40G show a state in a seventh process for manufacturing the nonvolatile semiconductor memory element 2 according to the second embodiment;

FIGS. 41A to 41G show a state in an eighth process for manufacturing the nonvolatile semiconductor memory element 2 according to the second embodiment;

FIGS. 42A to 42G show a state in a ninth process for manufacturing the nonvolatile semiconductor memory element 2 according to the second embodiment;

FIGS. 43A to 43G show a state in a tenth process for manufacturing the nonvolatile semiconductor memory element 2 according to the second embodiment;

FIGS. 44A to 44G show a state in an eleventh process for manufacturing the nonvolatile semiconductor memory element 2 according to the second embodiment;

FIGS. 45A to 45G show a state in a twelfth process for manufacturing the nonvolatile semiconductor memory element 2 according to the second embodiment;

FIGS. 46A to 46G show a state in a thirteenth process for manufacturing the nonvolatile semiconductor memory element 2 according to the second embodiment;

FIGS. 47A to 47G show a state in a fourteenth process for manufacturing the nonvolatile semiconductor memory element 2 according to the second embodiment;

FIGS. 48A to 48G show a state in a fifteenth process for manufacturing the nonvolatile semiconductor memory element 2 according to the second embodiment;

FIGS. 49A to 49G show a state in a sixteenth process for manufacturing the nonvolatile semiconductor memory element 2 according to the second embodiment;

FIGS. 50A to 50G show a state in a seventeenth process for manufacturing the nonvolatile semiconductor memory element 2 according to the second embodiment;

FIGS. 51A to 51G show a state in an eighteenth process for manufacturing the nonvolatile semiconductor memory element 2 according to the second embodiment;

FIGS. 52A to 52G show a state in a nineteenth process for manufacturing the nonvolatile semiconductor memory element 2 according to the second embodiment;

FIGS. 53A to 53G show a state in a twentieth process for manufacturing the nonvolatile semiconductor memory element 2 according to the second embodiment;

FIGS. 54A to 54G show a state in a twenty-first process for manufacturing the nonvolatile semiconductor memory element 2 according to the second embodiment;

FIGS. 55A to 55G show a state in a twenty-second process for manufacturing the nonvolatile semiconductor memory element 2 according to the second embodiment;

FIGS. 56A to 56G show a state in a twenty-third process for manufacturing the nonvolatile semiconductor memory element 2 according to the second embodiment;

FIGS. 57A to 57G show a state in a twenty-fourth process for manufacturing the nonvolatile semiconductor memory element 2 according to the second embodiment;

FIGS. 58A to 58G show a state in a twenty-fifth process for manufacturing the nonvolatile semiconductor memory element 2 according to the second embodiment;

FIGS. 59A to 59G show a state in a twenty-sixth process for manufacturing the nonvolatile semiconductor memory element 2 according to the second embodiment;

FIGS. 60A to 60G show a state in a twenty-seventh process for manufacturing the nonvolatile semiconductor memory element 2 according to the second embodiment;

FIG. 61 is an equivalent circuit diagram showing a configuration example of a memory cell array 1a having the nonvolatile semiconductor memory elements 2;

FIG. 62 is a table showing an operation of writing data to the nonvolatile semiconductor memory element 2;

FIG. 63 is a table showing an operation of erasing data stored in the nonvolatile semiconductor memory element 2;

FIG. 64 is a table showing an operation of reading data stored in the nonvolatile semiconductor memory element 2;

FIG. 65 is a block diagram showing a configuration example of a memory circuit 48 having the memory cell array 1a;

FIG. 66 is a plan view showing a configuration example of an interconnect layout in the memory cell array 1a;

FIG. 67 is a cross sectional view showing a cross sectional structure of the memory cell array 1a;

FIG. 68 is a cross sectional view showing a cross sectional structure of the memory cell array 1a;

FIG. 69 is a plan view showing a structure of a base layer when viewed from above;

FIG. 70 is a plan view showing a structure when contacts are formed on the base layer;

FIG. 71 is a plan view showing the base layer and a first word line 3 formed in a first interconnect layer 55;

FIG. 72 is a plan view showing the base layer and a second word line 4 formed in a second interconnect layer 56;

FIG. 73 is a plan view showing the base layer and a first bit line 6 formed in a third interconnect layer 57; and

FIG. 74 is a plan view showing the base layer and a second bit line 7 formed in a fourth interconnect layer 58.

### DESCRIPTION OF PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposed.

### First Embodiment

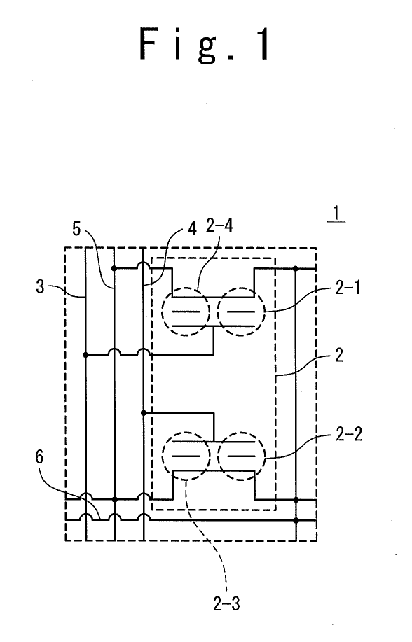

A nonvolatile semiconductor memory element 2 according to the present embodiment will be described below with reference to the attached drawings. FIG. 1 is an equivalent circuit diagram showing a configuration of the nonvolatile semiconductor memory element 2 according to the present embodiment. The nonvolatile semiconductor memory element 2 is provided in a semiconductor device 1. The nonvolatile semiconductor memory element 2 has a gate connected to a first word line 3 and a gate connected to a second word line 4. The nonvolatile semiconductor memory element 2 also has a first memory section 2-1, a second memory section 2-2, a third memory section 2-3 and a fourth memory section 2-4. A gate of the first memory section 2-1 and a gate of the fourth memory section 2-4 are connected to the first word line 3. A source of the first memory section 2-1 and the fourth memory section 2-4 is connected to a source line 5, and a drain thereof is connected to a first bit line 6. Similarly, respective gates of the second memory section 2-2 and the third memory section 2-3 are connected to the second word line 4. A source of the second memory section 2-2 and the fourth memory section 2-4 is connected to the source line 5, and a drain thereof is connected to the first bit line 6.

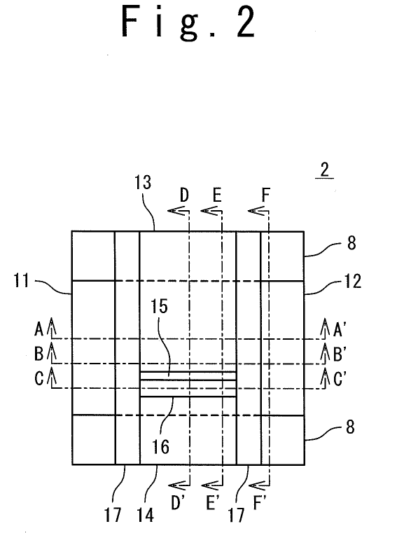

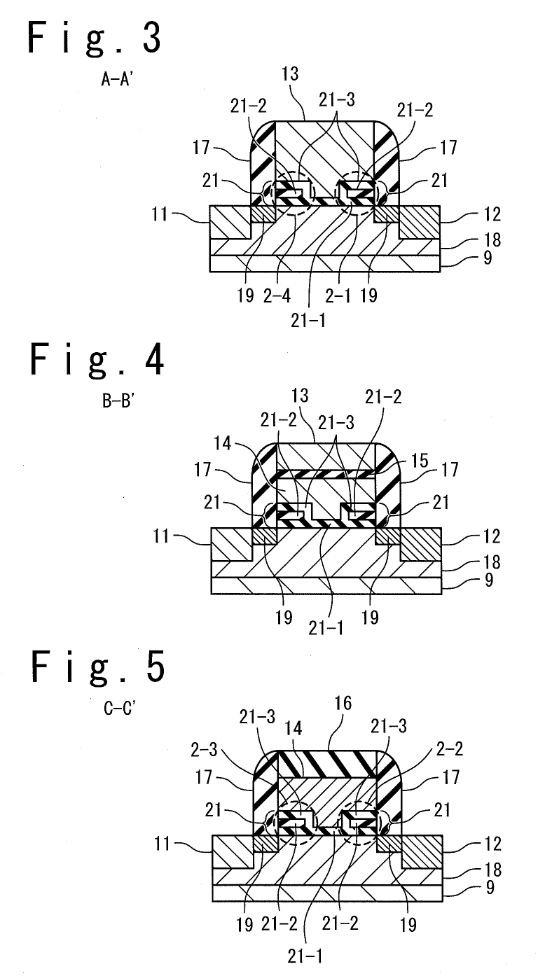

FIG. 2 is a plan view showing a structure of the nonvolatile semiconductor memory element 2. FIGS. 3 to 8 are cross sectional views showing the structure of the nonvolatile semiconductor memory element 2. As shown in FIG. 2, the nonvolatile semiconductor memory element 2 is placed between two STIs 8. The nonvolatile semiconductor memory element 2 has a first source/drain region 11, a second source/drain region 12, a first word gate 13 and a second word gate 14. An insulating film 15 is provided between the first word gate 13 and the second word gate 14. The nonvolatile semiconductor memory element 2 is also provided with a side wall 16 and a side wall 17.

FIG. 3 shows a cross section (hereinafter referred to as an A-A′ cross section) which is obtained when the nonvolatile semiconductor memory element 2 in the plan view of FIG. 2 is cut along a line A-A′. As shown in FIG. 3, the nonvolatile semiconductor memory element 2 is formed on a P well 18 which is formed on a semiconductor substrate 9. The first source/drain region 11, the second source/drain region 12 and an LDD structure 19 are formed in the P well 18. Each of the first source/drain region 11 and the second source/drain region 12 serves as a source or a drain. Exemplified in the present embodiment is a case where the semiconductor substrate 9 is a P-type silicon substrate (P-type well). In this case, the first source/drain region 11 and the second source/drain region 12 each is an N-type diffusion region. A semiconductor region between the first source/drain region 11 and the second source/drain region 12 serves as a channel region. The nonvolatile semiconductor memory element 2 is provided with a plurality of gate electrodes (the first word gate 13 and the second word gate 14) formed on the channel region. Side surfaces of the first word gate 13 are electrically insulated from the surrounding by the side walls 17. The LDD structures 19 are formed in the P well 18 below the respective side walls 17.

As shown in FIG. 3, the nonvolatile semiconductor memory element 2 in the A-A′ cross section includes a charge storage layer 21 corresponding to the first memory section 2-1 and a charge storage layer 21 corresponding to the fourth memory section 2-4 between the first word gate 13 and the P well 18. Each of the charge storage layers 21 includes a bottom insulating film 21-1, a charge trapping film 21-2 and a top insulating film 21-3.

The bottom insulating film 21-1 is an insulating film facing the P well 18 and formed between the charge trapping film 21-2 and the P well 18. On the other hand, the top insulating film 21-3 is an insulating film facing the first word gate 13 and formed between the charge trapping film 21-2 and the first word gate 13. The charge trapping film 21-2 is an insulating film having charge trapping ability and is sandwiched between the bottom insulating film 21-1 and the top insulating film 21-3. The charge storage layer 21 is, for example, an ONO film. In this case, the bottom insulating film 21-1, the charge trapping film 21-2 and the top insulating film 21-3 are a silicon oxide film, a silicon nitride film and a silicon oxide film, respectively. In the nonvolatile semiconductor memory element 2 according to the present embodiment, the first memory section 2-1 and the fourth memory section 2-4 are so formed as to have the same shape.

As shown in FIG. 3, the nonvolatile semiconductor memory element 2 includes, between the first memory section 2-1 and the fourth memory section 2-4, a region in which the charge trapping film 21-2 is not formed. Accordingly, movement of charges between the first memory section 2-1 and the fourth memory section 2-4 is suppressed.

FIG. 4 shows a cross section (hereinafter referred to as a B-B′ cross section) which is obtained when the nonvolatile semiconductor memory element 2 in the plan view of FIG. 2 is cut along a line B-B′. As shown in FIG. 4, the nonvolatile semiconductor memory element 2 in the B-B′ cross section includes the first word gate 13 formed on the insulating film 15 and the second word gate 14 formed under the insulating film 15.

As shown in FIG. 4, the first word gate 13 and the second word gate 14 are electrically insulated from each other due to the insulating film 15. Moreover, the charge storage layers 21 are formed between the second word gate 14 and the P well 18. As in the case of the above-described FIG. 3, each charge storage layer 21 includes the bottom insulating film 21-1, the charge trapping film 21-2 and the top insulating film 21-3. In the B-B′ cross section of the nonvolatile semiconductor memory element 2, the first memory section 2-1 and the fourth memory section 2-4 are formed similarly. Furthermore, the nonvolatile semiconductor memory element 2 includes, between the first memory section 2-1 and the fourth memory section 2-4, a region in which the charge trapping film 21-2 is not formed.

FIG. 5 shows a cross section (hereinafter referred to as a C-C′ cross section) which is obtained when the nonvolatile semiconductor memory element 2 in the plan view of FIG. 2 is cut along a line C-C′. As shown in FIG. 5, in the C-C′ cross section, the nonvolatile semiconductor memory element 2 is provided with the second word gate 14. As shown in FIG. 5, the nonvolatile semiconductor memory element 2 in the C-C′ cross section includes a charge storage layer 21 corresponding to the second memory section 2-2 and a charge storage layer 21 corresponding to the third memory section 2-3 between the second word gate 14 and the P well 18. Each charge storage layer 21 includes the bottom insulating film 21-1, the charge trapping film 21-2 and the top insulating film 21-3.

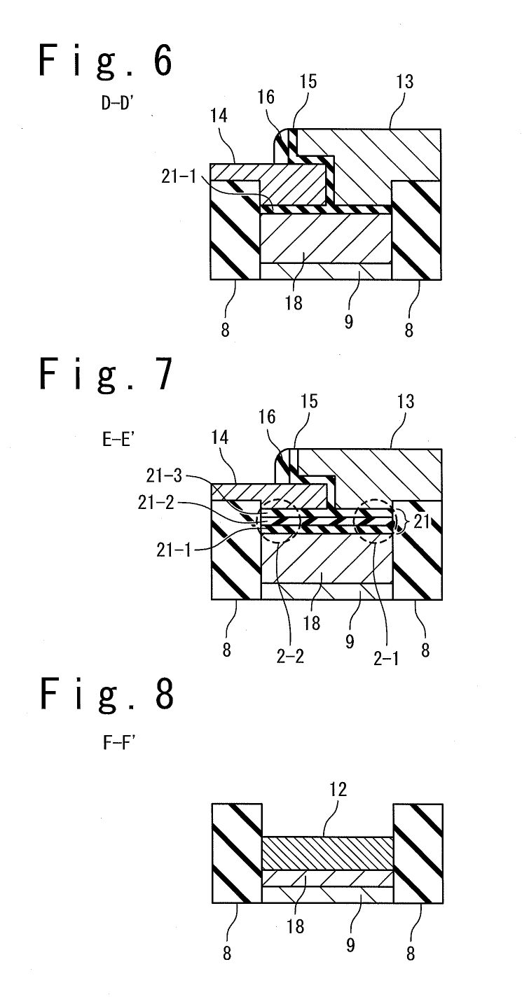

FIG. 6 shows a cross section (hereinafter referred to as a D-D′ cross section) which is obtained when the nonvolatile semiconductor memory element 2 in the plan view of FIG. 2 is cut along a line D-D′. The nonvolatile semiconductor memory element 2 is formed between two STIs 8. The nonvolatile semiconductor memory element 2 is provided with the bottom insulating film 21-1 which is formed on the P well 18. The bottom insulating film 21-1 is connected to the insulating film 15. As shown in FIG. 6, the first word gate 13 and the second word gate 14 are electrically insulated from each other due to the insulating film 15.

FIG. 7 shows a cross section (hereinafter referred to as an E-E′ cross section) which is obtained when the nonvolatile semiconductor memory element 2 in the plan view of FIG. 2 is cut along a line E-E′. The nonvolatile semiconductor memory element 2 in the E-E′ cross section includes the first memory section 2-1 and the second memory section 2-2. The charge storage layers 21 are formed between two STIs 8. The nonvolatile semiconductor memory element 2 is provided with the insulating film 15 which is connected to the top insulating film 21-3. The first word gate 13 and the second word gate 14 are electrically insulated from each other due to the insulating film 15.

FIG. 8 shows a cross section (hereinafter referred to as an F-F′ cross section) which is obtained when the nonvolatile semiconductor memory element 2 in the plan view of FIG. 2 is cut along a line F-F′. The nonvolatile semiconductor memory element 2 in the F-F′ cross section has the second source/drain region 12, and the second source/drain region 12 is formed between two STIs 8. The second source/drain region 12 is formed in the P well 18. It should be noted that the first source/drain region 11 is formed in the same manner as in the case of the second source/drain region 12.

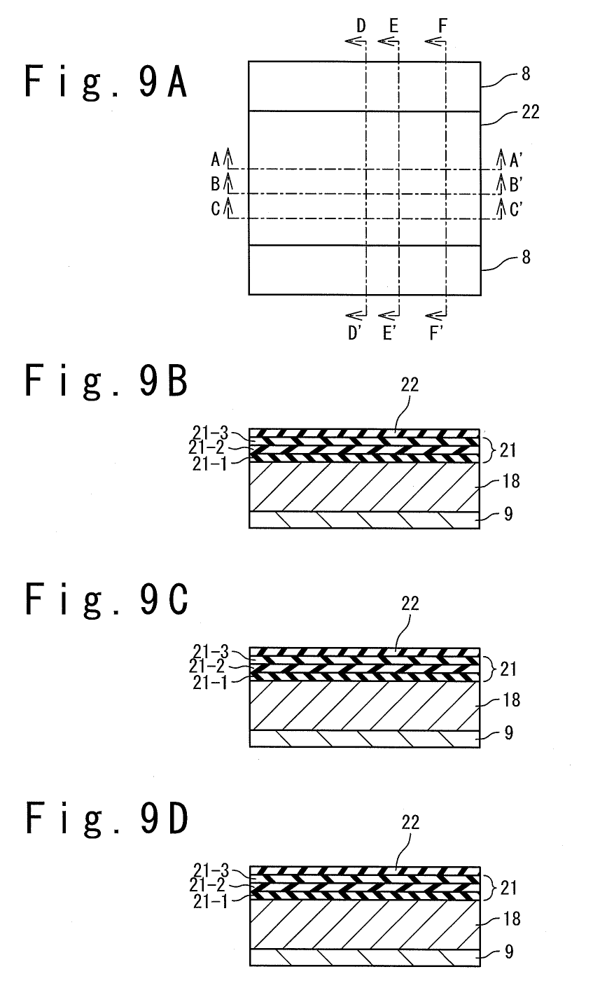

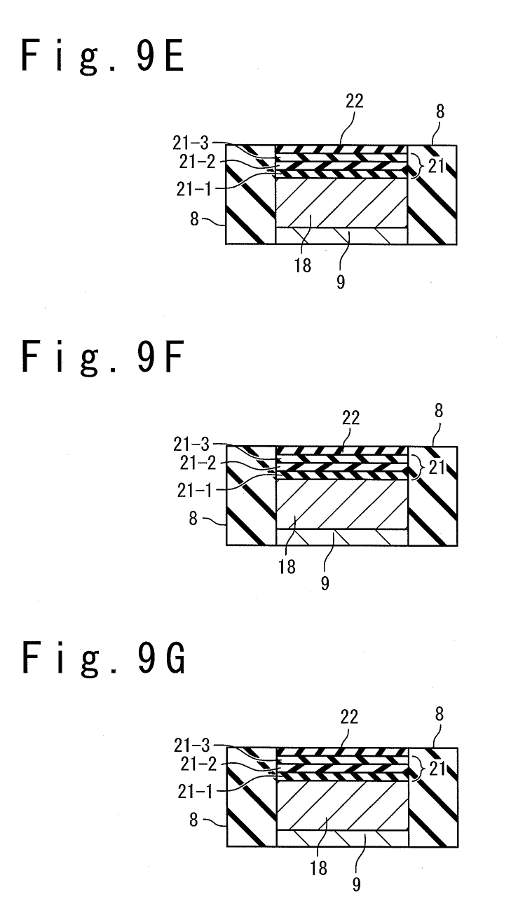

Next, a process of manufacturing the nonvolatile semiconductor memory element 2 according to the present embodiment will be described below. FIGS. 9A to 9G show a state in a first process for manufacturing the nonvolatile semiconductor memory element 2 according to the present embodiment. FIG. 9A is a plan view showing a structure in the first process viewed from above. FIG. 9B is a cross sectional view showing a cross sectional structure in the first process taken along a line A-A′ shown in FIG. 9A. FIG. 9C is a cross sectional view showing a cross sectional structure in the first process taken along a line B-B′ shown in FIG. 9A. FIG. 9D is a cross sectional view showing a cross sectional structure in the first process taken along a line C-C′ shown in FIG. 9A. FIG. 9E is a cross sectional view showing a cross sectional structure in the first process taken along a line D-D′ shown in FIG. 9A. FIG. 9F is a cross sectional view showing a cross sectional structure in the first process taken along a line E-E′ shown in FIG. 9A. FIG. 9G is a cross sectional view showing a cross sectional structure in the first process taken along a line F-F′ shown in FIG. 9A.

As shown in FIG. 9A, in the first process of manufacturing the nonvolatile semiconductor memory element 2, the STIs 8 are formed to sandwich a nitride film 22. As shown in FIGS. 9B, 9C and 9D, in the first process, an oxide film (i.e. bottom insulating film 21-1) with a thickness of 3 to 6 nm, a nitride film (i.e. charge trapping film 21-2) with a thickness of 4 to 8 nm and an oxide film (i.e. top insulating film 21-3) with a thickness of 3 to 6 nm are formed in this order on the semiconductor substrate 9 by a CVD method, to form the charge storage layer 21.

After that, the nitride film 22 is formed on the charge storage layer 21 by the CVD method. A thermal oxidization method may be employed for forming the bottom insulating film 21-1 and the top insulating film 21-3. The oxide film, nitride film and oxide film serve as an ONO film which forms a trap layer in the memory cell.

Next, photoresist is applied on the nitride film 22 and then patterning of it is carried out (not shown). By using the patterned resist (not shown) as a mask, the nitride film 22, the charge storage layer 21 and the semiconductor substrate 9 are removed sequentially by an etching. At this time, the silicon substrate is etched by about 200 to 300 nm. Thereafter, the photoresist is peeled off.

Next, an oxide film is blanket deposited by the CVD method. A trench portion which is formed previously by etching is also filled with the oxide film. Then, the oxide film is planarized by a CMP method until the surface of the nitride film 22 is exposed. The oxide film filled in the trench portion is used as the STI 8. As shown in FIGS. 9E, 9F and 9G, in the first process, after the charge storage layer 21 is formed, the charge storage layer 21 is separated by the STI 8.

After the charge storage layer 21 is separated as shown in FIGS. 9B to 9G, a resist is applied and then patterning of it is carried out (not shown). Then, by using the patterned resist as a mask, P-type impurities such as boron are injected to form the P well 18.

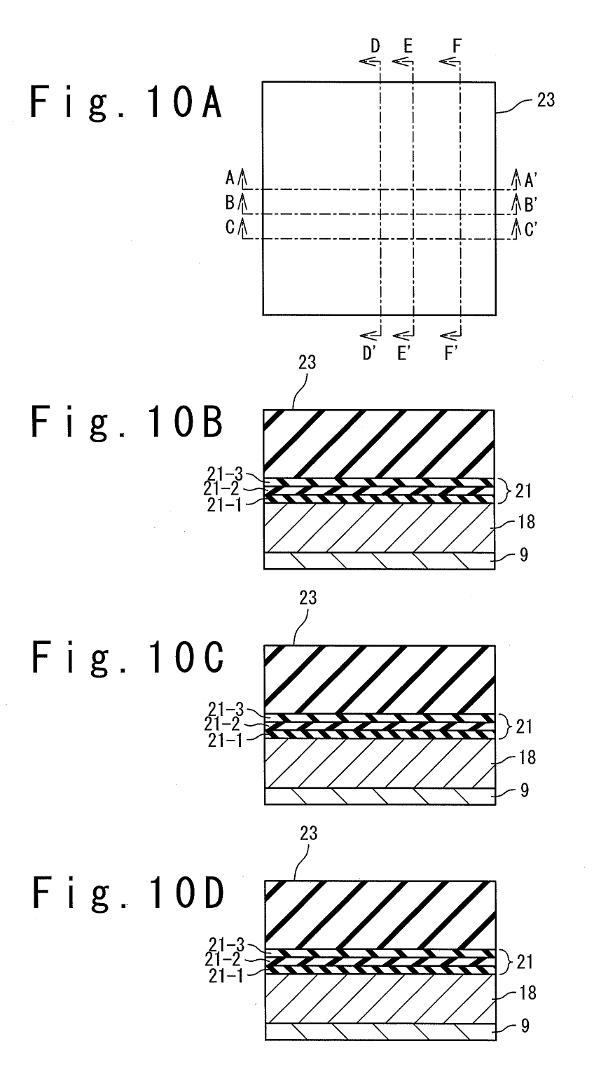

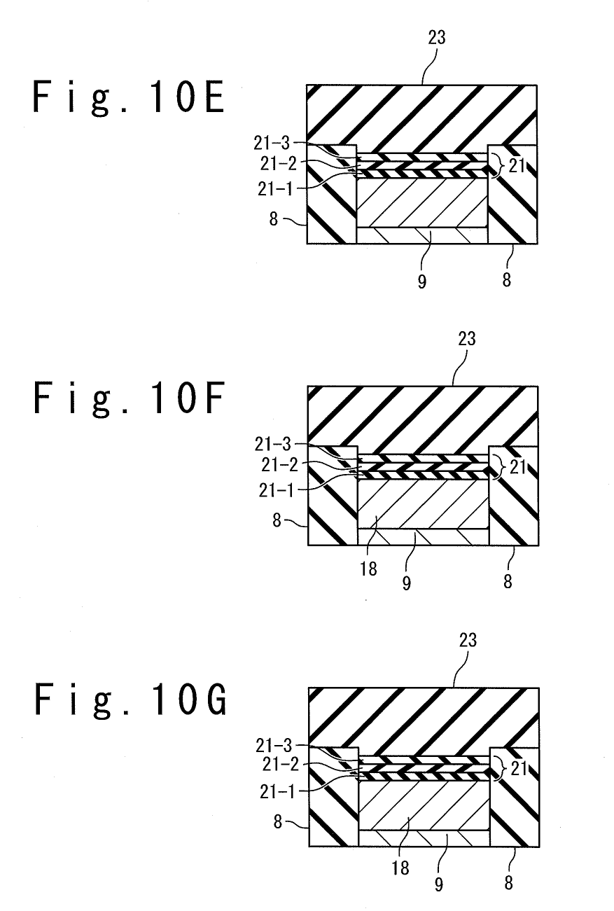

FIGS. 10A to 10G show a state in a second process for manufacturing the nonvolatile semiconductor memory element 2. FIG. 10A is a plan view showing a structure in the second process viewed from above. FIG. 10B is a cross sectional view showing the A-A′ cross section in the second process. FIG. 10C is a cross sectional view showing the B-B′ cross section in the second process. FIG. 10D is a cross sectional view showing the C-C′ cross section in the second process. FIG. 10E is a cross sectional view showing the D-D′ cross section in the second process. FIG. 10F is a cross sectional view showing the E-E′ cross section in the second process. FIG. 10G is a cross sectional view showing the F-F′ cross section in the second process.

As shown in FIG. 10A, in the second process, a nitride film is formed on the nitride film 22 and the STIs 8, whereby a nitride film 23 is formed. At this time, the nitride film is preferably formed such that a film thickness of the nitride film 23 becomes about 300 to 450 nm. As shown in FIGS. 10B, 10C and 10D, the nitride film formed in the second process is integrated with the above-mentioned nitride film 22 to constitute the nitride film 23 on the charge storage layer 21.

Also, as shown in FIGS. 10E, 10F and 10G, the nitride film formed in the second process is formed on the STIs 8 and the nitride film 22. The nitride film 22 formed on the charge storage layer 21 is integrated with the above nitride film to constitute the nitride film 23.

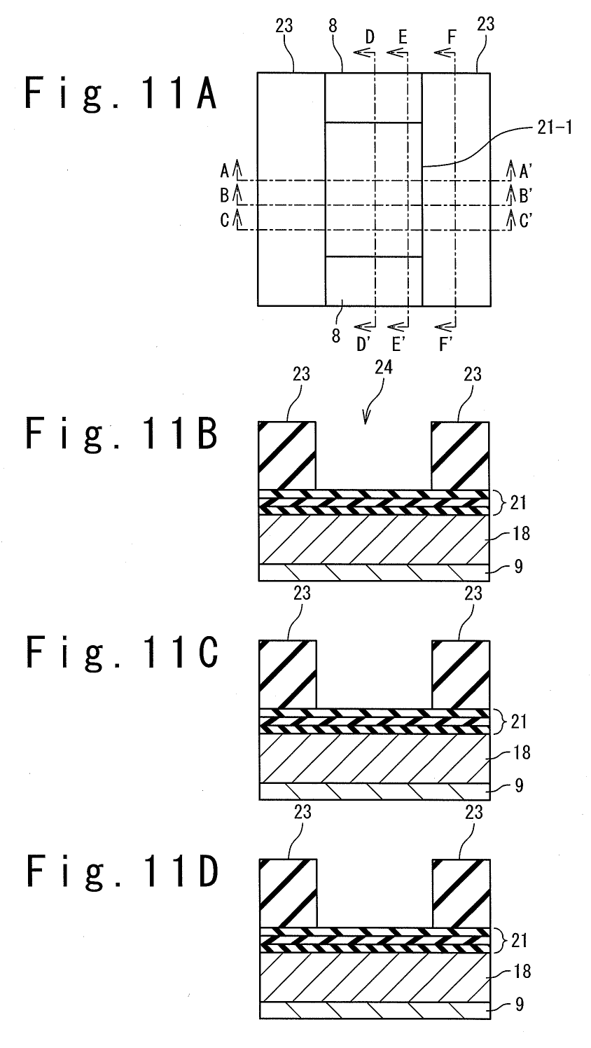

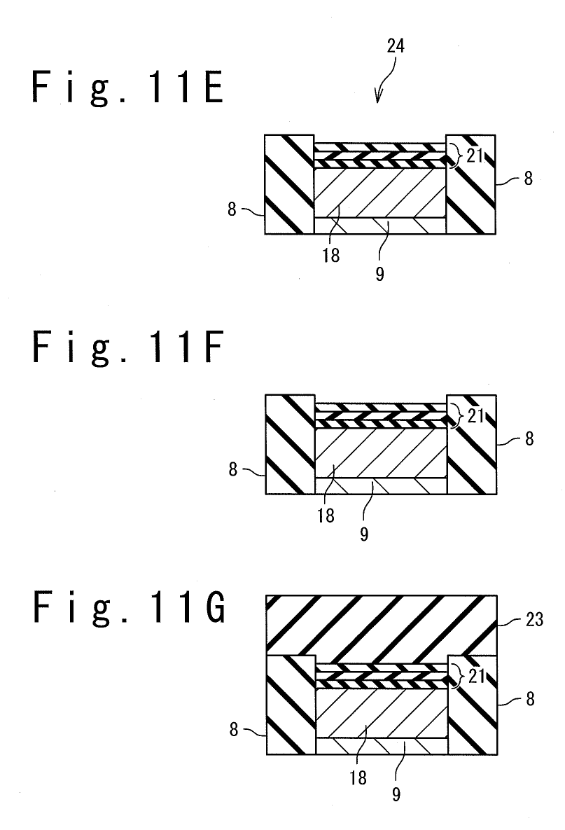

FIGS. 11A to 11G show a state in a third process for manufacturing the nonvolatile semiconductor memory element 2. FIG. 11A is a plan view showing a structure in the third process viewed from above. FIG. 11B is a cross sectional view showing the A-A′ cross section in the third process. FIG. 11C is a cross sectional view showing the B-B′ cross section in the third process. FIG. 11D is a cross sectional view showing the C-C′ cross section in the third process. FIG. 11E is a cross sectional view showing the D-D′ cross section in the third process. FIG. 11F is a cross sectional view showing the E-E′ cross section in the third process. FIG. 11G is a cross sectional view showing the F-F′ cross section in the third process.

As shown in FIG. 11A, in the third process, an opening portion 24 is formed in the nitride film 23 such that the charge storage layer 21 and the STIs 8 are exposed. As shown in FIGS. 11B, 11C and 11D, in the third process, a resist is applied and then patterning of it is carried out (not shown). By using the patterned resist as a mask (not shown), the nitride film 23 is etched to form the opening portion 24. A surface of the charge storage layer 21 is exposed due to the formation of the opening portion 24. After that, the resist is peeled off. As shown in FIGS. 11E and 11F, the surface of the charge storage layer 21 is exposed in the D-D′ cross section and the E-E′ cross section. At this time, as shown in FIG. 11G, the nitride film 23 in the F-F′ cross section protected by the resist remains therein without being removed.

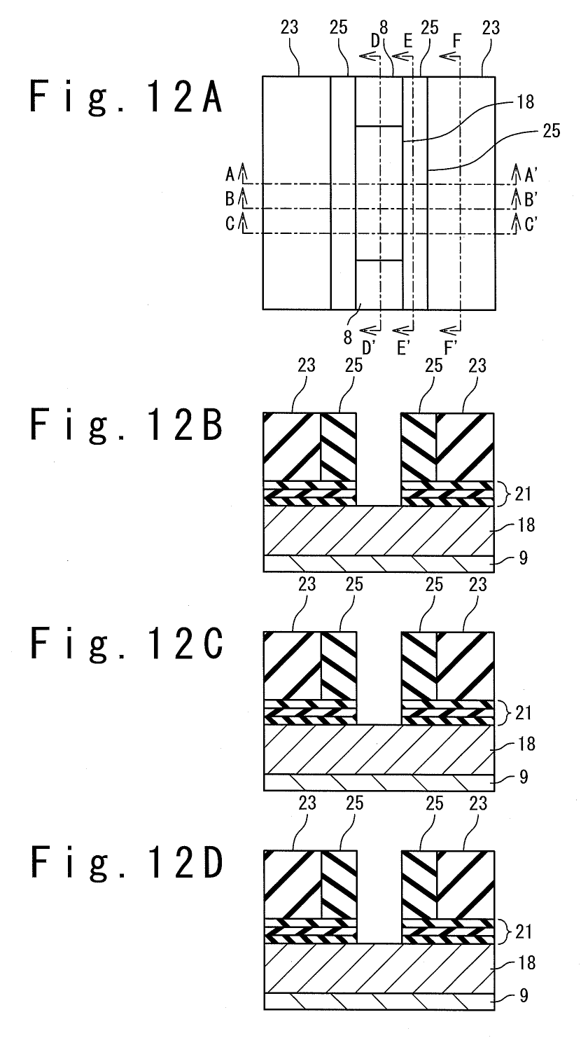

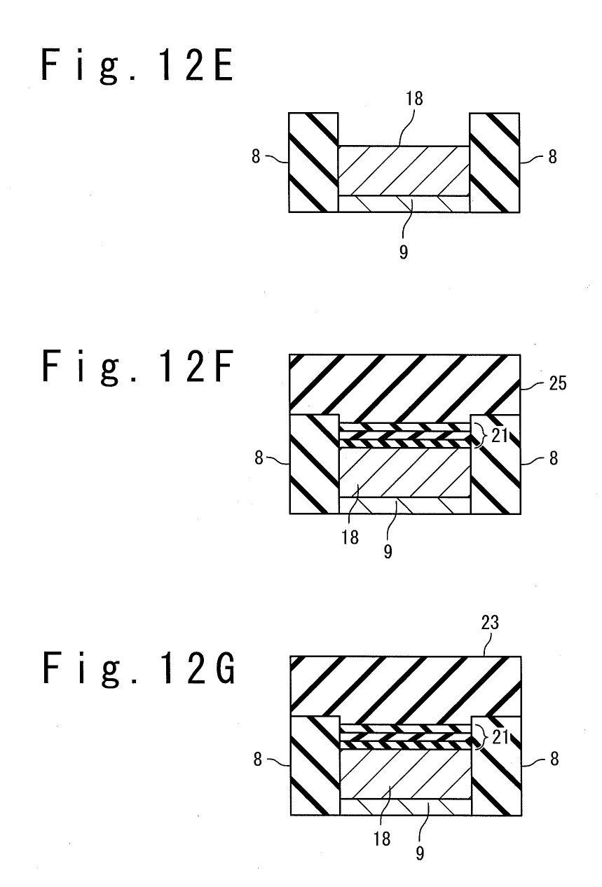

FIGS. 12A to 12G show a fourth process for manufacturing the nonvolatile semiconductor memory element 2. FIG. 12A is a plan view showing a structure in the fourth process viewed from above. FIG. 12B is a cross sectional view showing the A-A′ cross section in the fourth process. FIG. 12C is a cross sectional view showing the B-B′ cross section in the fourth process. FIG. 12D is a cross sectional view showing the C-C′ cross section in the fourth process. FIG. 12E is a cross sectional view showing the D-D′ cross section in the fourth process. FIG. 12F is a cross sectional view showing the E-E′ cross section in the fourth process. FIG. 12G is a cross sectional view showing the F-F′ cross section in the fourth process.

As shown in FIG. 12A, in the fourth process, oxide film side walls 25 are formed in the opening portion 24 (on side surfaces of the nitride film 23). As shown in FIGS. 12B, 12C and 12D, in the fourth process, after the opening portion 24 is formed in the nitride film 23, an oxide film with a thickness of about 100 to 200 nm is first formed by the CVD method so as to cover the nitride film 23, the STIs 8 and the charge storage layer 21. After that, the oxide film is etched back to form the oxide film side walls 25. It is preferable to set a condition such that the charge storage layer 21 on the channel region also is removed by the etching when the oxide film is etched back. In this case, the charge storage layer 21 in a portion surrounded by the STIs 8 and the oxide film side walls 25 is removed simultaneously by the etching, and a surface of the P wall 18 is exposed.

As shown in FIG. 12E, in the fourth process, the charge storage layer 21 between the STIs 8 is removed and a surface of the P well 18 is exposed in the D-D′ cross section. Also, as shown in FIG. 12F, in the fourth process, the oxide film side wall 25 is formed on the charge storage layer 21 and the STIs 8 in the E-E′ cross section. Furthermore, as shown in FIG. 12G, in the fourth process, the nitride film 23 formed on the charge storage layer 21 and the STIs 8 in the F-F′ cross section is in the same state as shown in the third process.

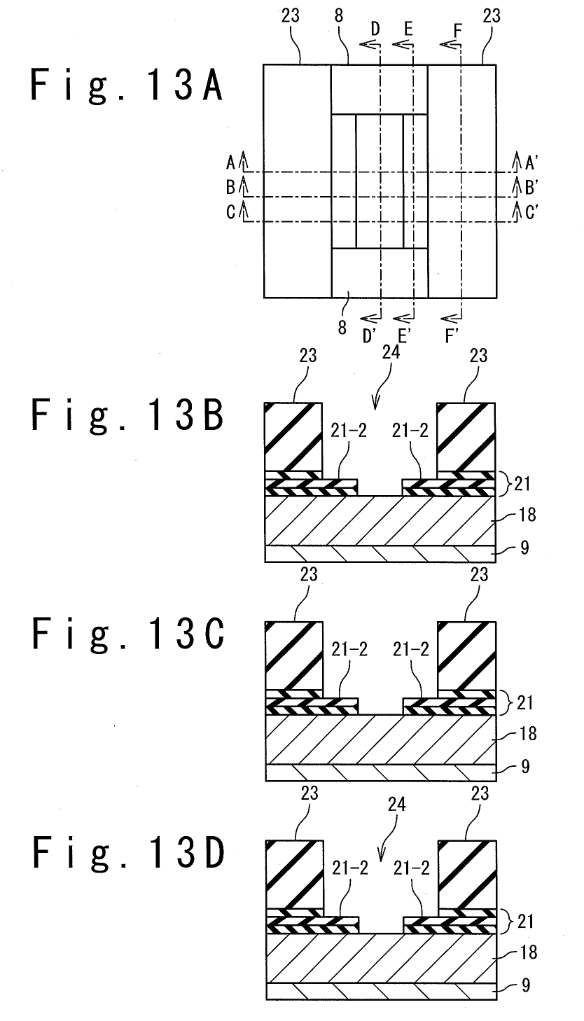

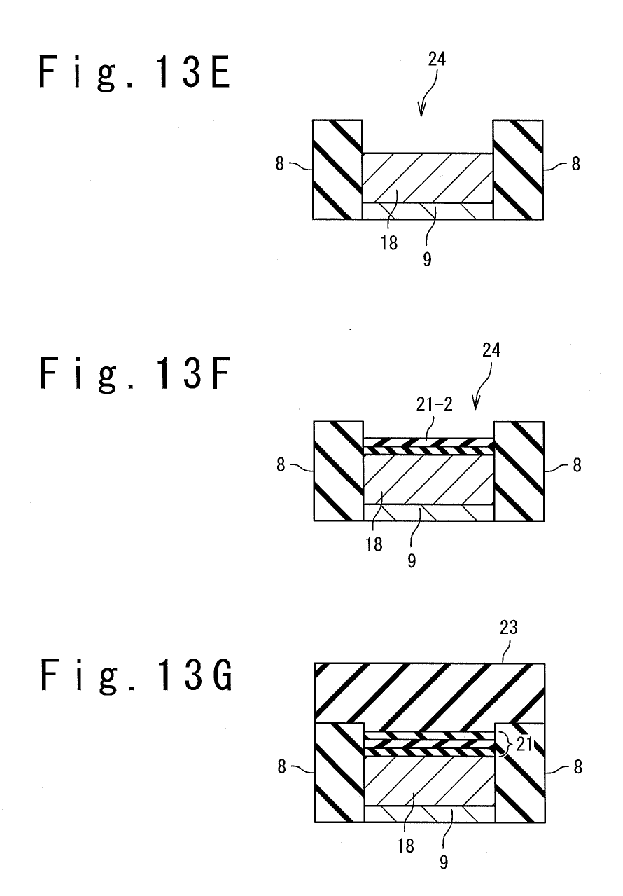

FIGS. 13A to 13G show a state in a fifth process for manufacturing the nonvolatile semiconductor memory element 2. FIG. 13A is a plan view showing a structure in the fifth process viewed from above. FIG. 13B is a cross sectional view showing the A-A′ cross section in the fifth process. FIG. 13C is a cross sectional view showing the B-B′ cross section in the fifth process. FIG. 13D is a cross sectional view showing the C-C′ cross section in the fifth process. FIG. 13E is a cross sectional view showing the D-D′ cross section in the fifth process. FIG. 13F is a cross sectional view showing the E-E′ cross section in the fifth process. FIG. 13G is a cross sectional view showing the F-F′ cross section in the fifth process.

As shown in FIG. 13A, in the fifth process, the oxide film side walls 25 are removed. At this time, the top insulating film 21-3 formed under the oxide film side wall 25 also is removed simultaneously and thereby the charge trapping film 21-2 is exposed. As shown in FIGS. 13B, 13C and 13D, in the fifth process, the top insulating film 21-3 in the opening portion 24 is removed and thereby surfaces of the charge trapping films 21-2 in the opening portion 24 are exposed.

As shown in FIG. 13F, in the fifth process, the oxide film side wall 25 and the top insulating film 21-3 are removed simultaneously and the charge trapping film 21-2 between the STIs 8 is exposed in the E-E′ cross section. Note that, in the fifth process, as shown in FIGS. 13E and 13G, the D-D′ cross section and the F-F′ cross section are in the same states as shown in the fourth process.

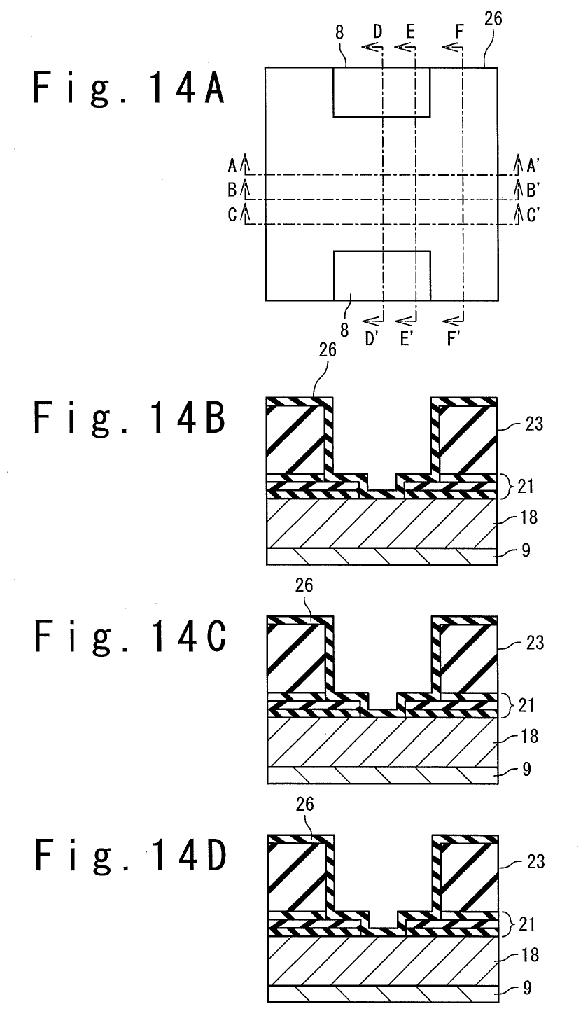

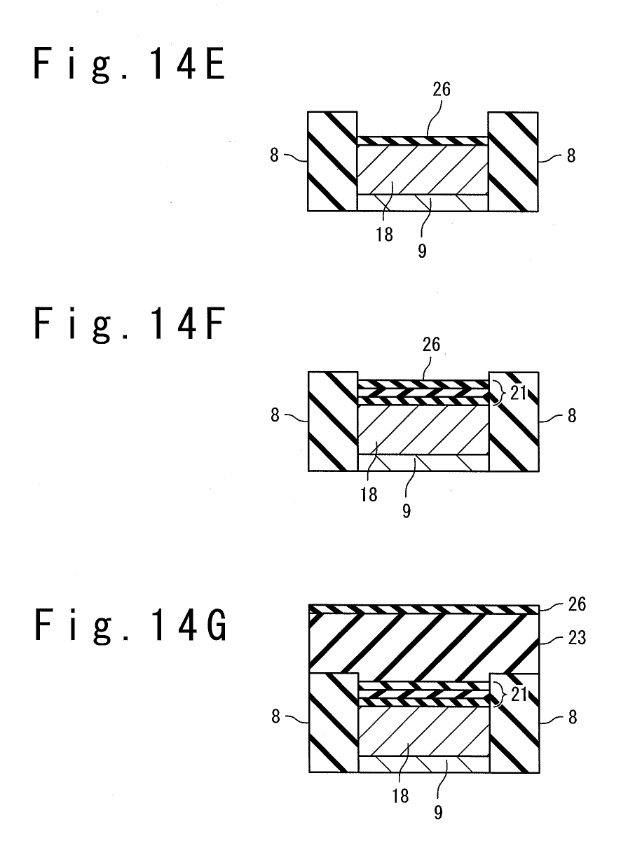

FIGS. 14A to 14G show a state in a sixth process for manufacturing the nonvolatile semiconductor memory element 2. FIG. 14A is a plan view showing a structure in the sixth process viewed from above. FIG. 14B is a cross sectional view showing the A-A′ cross section in the sixth process. FIG. 14C is a cross sectional view showing the B-B′ cross section in the sixth process. FIG. 14D is a cross sectional view showing the C-C′ cross section in the sixth process. FIG. 14E is a cross sectional view showing the D-D′ cross section in the sixth process. FIG. 14F is a cross sectional view showing the E-E′ cross section in the sixth process. FIG. 14G is a cross sectional view showing the F-F′ cross section in the sixth process.

As shown in FIG. 14A, in the sixth process, an oxide film 26 with a thickness of 3 to 6 nm is blanket deposited by the CVD method or the thermal oxidization method so as to cover exposed surfaces of the nitride film 23, the charge trapping films 21-2 and the P well 18. As shown in FIGS. 14B, 14C and 14D, in the sixth process, a top surface and a side surface of the nitride film 23 is covered by the oxide film 26. Moreover, surfaces of the charge trapping films 21-2 and of the P well 18 are covered by the oxide film 26. The oxide film 26 formed in the present process becomes a new top insulating film 21-3 in the later process. Moreover, the oxide film 26 serves as a channel oxide film between the charge storage layers 21.

As shown in FIG. 14E, in the sixth process, the oxide film 26 is formed on the P well 18 in the D-D′ cross section. As shown in FIG. 14F, in the sixth process, the oxide film 26 is formed on the exposed charge trapping film 21-2 in the E-E′ cross section. As mentioned above, the oxide film 26 serves as a new top insulating film 21-3 in the later process. As shown in FIG. 14G, in the sixth process, the oxide film 26 is formed on the nitride film 23 in the F-F′ cross section exhibits.

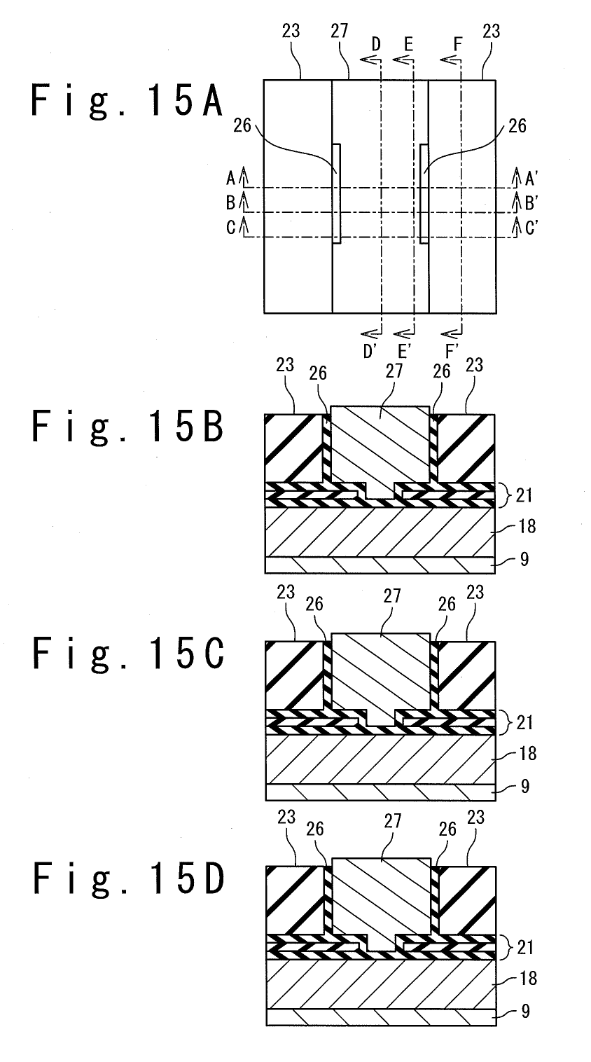

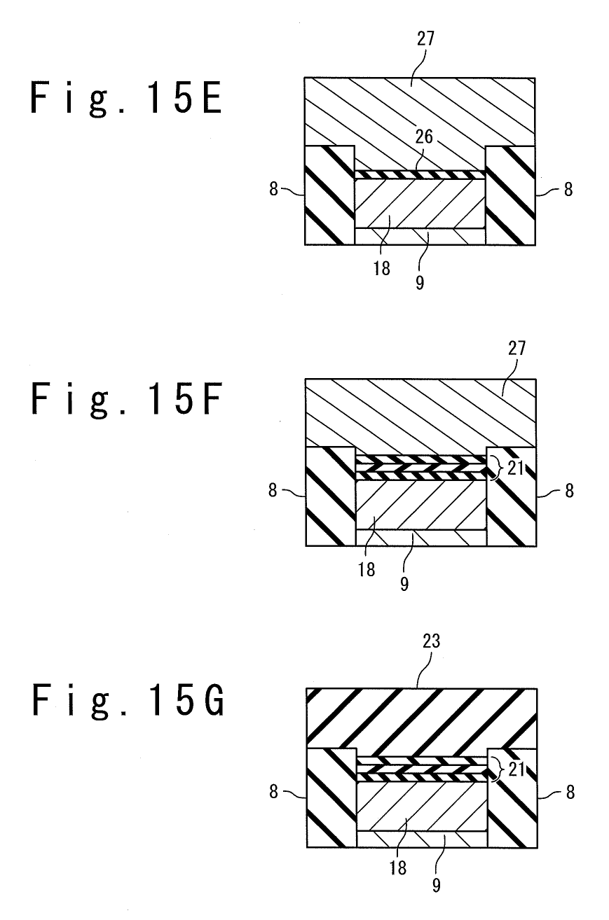

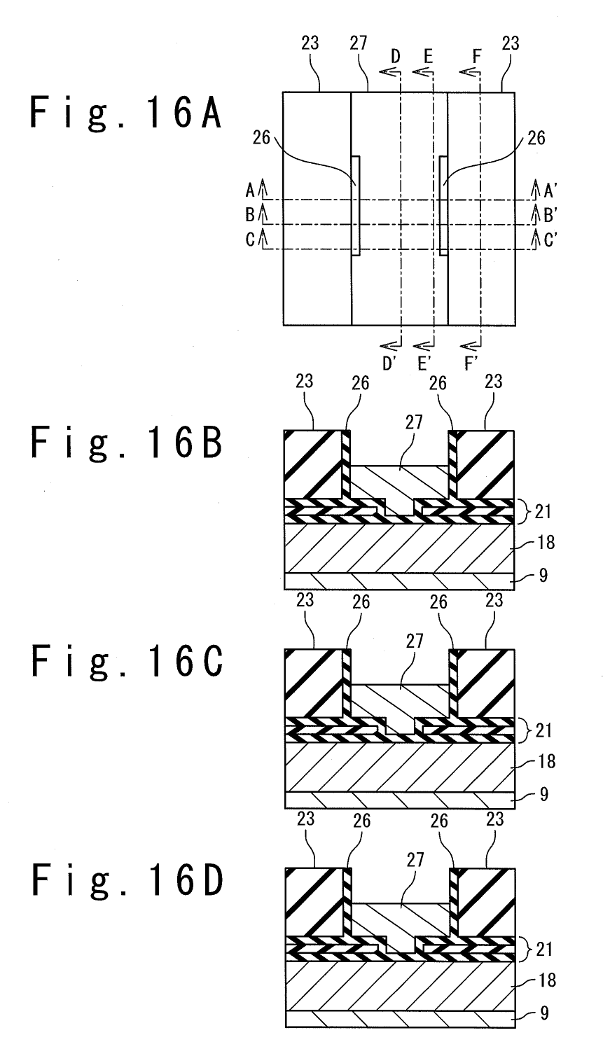

FIGS. 15A to 15G show a state in a seventh process for manufacturing the nonvolatile semiconductor memory element 2. FIG. 15A is a plan view showing a structure in the seventh process viewed from above. FIG. 15B is a cross sectional view showing the A-A′ cross section in the seventh process. FIG. 15C is a cross sectional view showing the B-B′ cross section in the seventh process. FIG. 15D is a cross sectional view showing the C-C′ cross section in the seventh process. FIG. 15E is a cross sectional view showing the D-D′ cross section in the seventh process. FIG. 15F is a cross sectional view showing the E-E′ cross section in the seventh process. FIG. 15G is a cross sectional view showing the F-F′ cross section in the seventh process.

As shown in FIG. 15A, in the seventh process, a first polysilicon film 27 is formed between the nitride films 23. The first polysilicon film 27 may be doped polysilicon that is doped with n-type impurities such as phosphorus and arsenic. Alternatively, after the first polysilicon film 27 is formed, n-type impurities such as phosphorus and arsenic may be injected into the first polysilicon film 27.

As shown in FIGS. 15B, 15C and 15D, in the seventh process, the first polysilicon film 27 with a thickness of about 300 to 400 nm is blanket deposited by the CVD method or the like. Next, planarization is carried out by the CMP method or the like until the oxide film 26 formed on the nitride film 23 is exposed. After that, the oxide film 26 formed on the nitride film 23 is removed by a wet etching.

As shown in FIG. 15E, in the seventh process, the first polysilicon film 27 is formed on the oxide film 26 in the D-D′ cross section exhibits. Moreover, as shown in FIG. 15F, in the seventh process, the first polysilicon film 27 is formed on the charge storage layer 21 in the E-E′ cross section. At this time, as shown in FIG. 15G, in the seventh process, the oxide film 26 formed on the nitride film 23 is removed and thereby a top surface of the nitride film 23 is exposed in the F-F′ cross section.

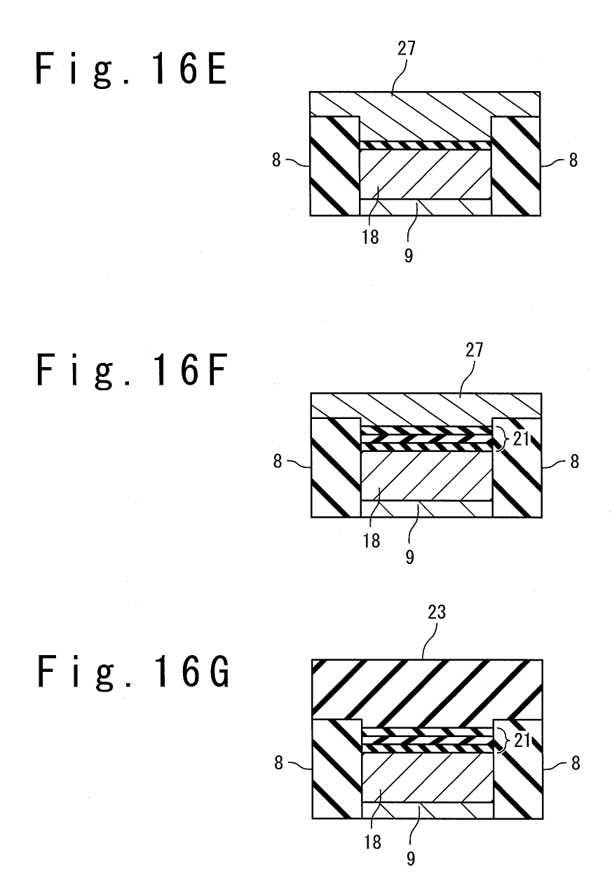

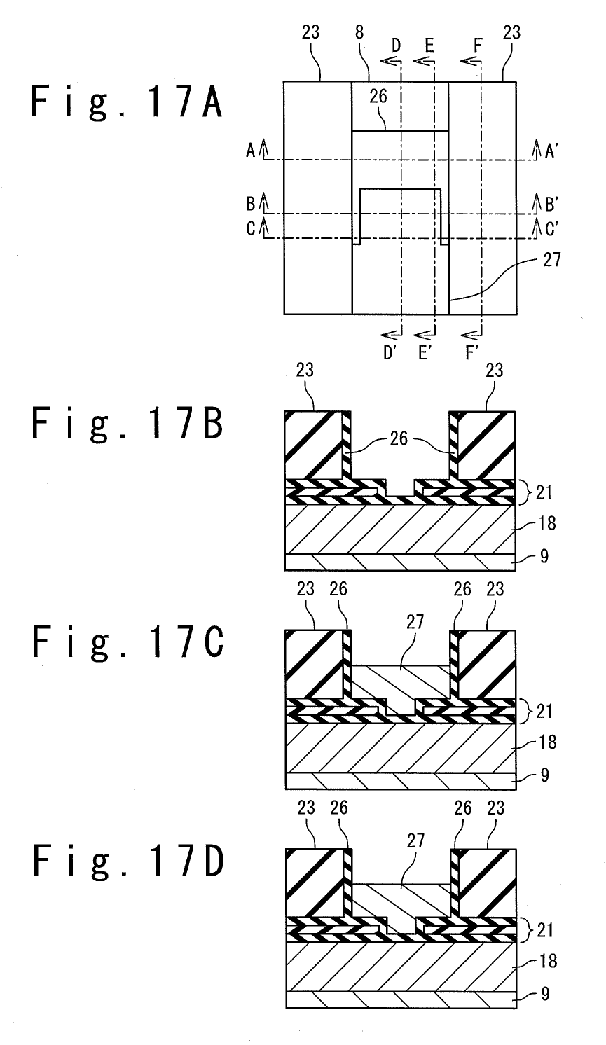

FIGS. 16A to 16G show a state in an eighth process for manufacturing the nonvolatile semiconductor memory element 2. FIG. 16A is a plan view showing a structure in the eighth process viewed from above. FIG. 16B is a cross sectional view showing the A-A′ cross section in the eighth process. FIG. 16C is a cross sectional view showing the B-B′ cross section in the eighth process. FIG. 16D is a cross sectional view showing the C-C′ cross section in the eighth process. FIG. 16E is a cross sectional view showing the D-D′ cross section in the eighth process. FIG. 16F is a cross sectional view showing the E-E′ cross section in the eighth process. FIG. 16G is a cross sectional view showing the F-F′ cross section in the eighth process.

As shown in FIGS. 16A to 16F, in the eighth process, a dry etching method is applied on the entire surface to etch and remove the polysilicon film 27 selectively by 50 to 100 nm. At this time, as shown in FIG. 16G, the F-F′ cross section is in the same state as shown in the seventh process.

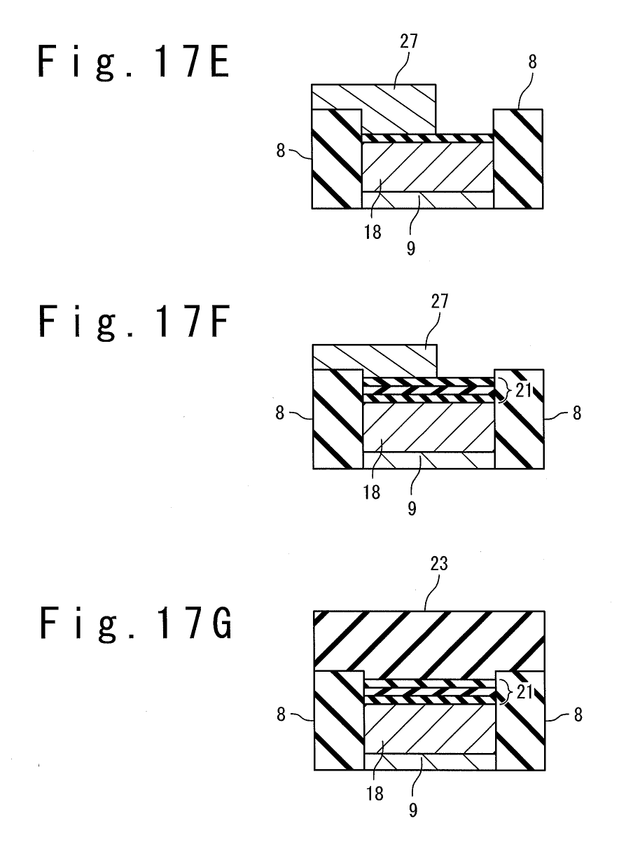

FIGS. 17A to 17G show a state in a ninth process for manufacturing the nonvolatile semiconductor memory element 2. FIG. 17A is a plan view showing a structure in the ninth process viewed from above. FIG. 17B is a cross sectional view showing the A-A′ cross section in the ninth process. FIG. 17C is a cross sectional view showing the B-B′ cross section in the ninth process. FIG. 17D is a cross sectional view showing the C-C′ cross section in the ninth process. FIG. 17E is a cross sectional view showing the D-D′ cross section in the ninth process. FIG. 17F is a cross sectional view showing the E-E′ cross section in the ninth process. FIG. 17G is a cross sectional view showing the F-F′ cross section in the ninth process.

As shown in FIG. 17A, in the ninth process, a part of the first polysilicon film 27 is removed and thereby the oxide film 26 and the STI 8 are exposed. As shown in FIG. 17B, in the ninth process, the first polysilicon film 27 is removed in the A-A′ cross section. Moreover, as shown in FIGS. 17C and 17D, in the ninth process, the first polysilicon film 27 remains in the B-B′ cross section and the C-C′ cross section.

Referring to FIGS. 17E and 17F, in the ninth process, a resist is applied and patterning of it is carried out (not shown), and then a part of the first polysilicon film 27 on the channel region is removed by the etching by the use of the patterned resist as a mask. As a result, a surface of the oxide film 26 and a surface of the charge storage layer 21 are exposed. Thereafter, the resist is peeled off and thereby a surface of the remaining first polysilicon film 27 is exposed. As shown in FIG. 17G, the F-F′ cross section in the ninth process is in the same state as shown in the seventh process.

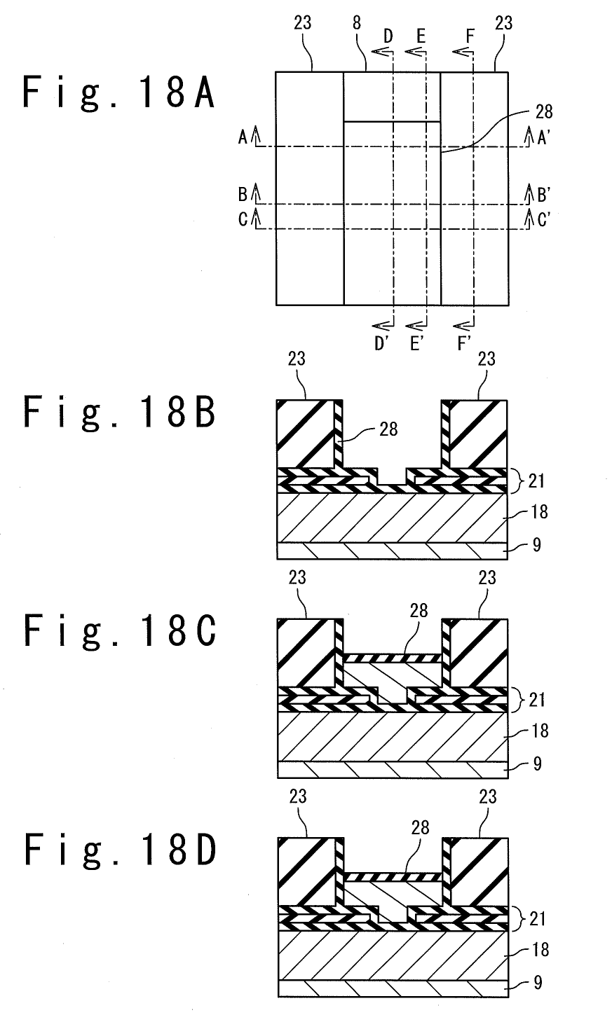

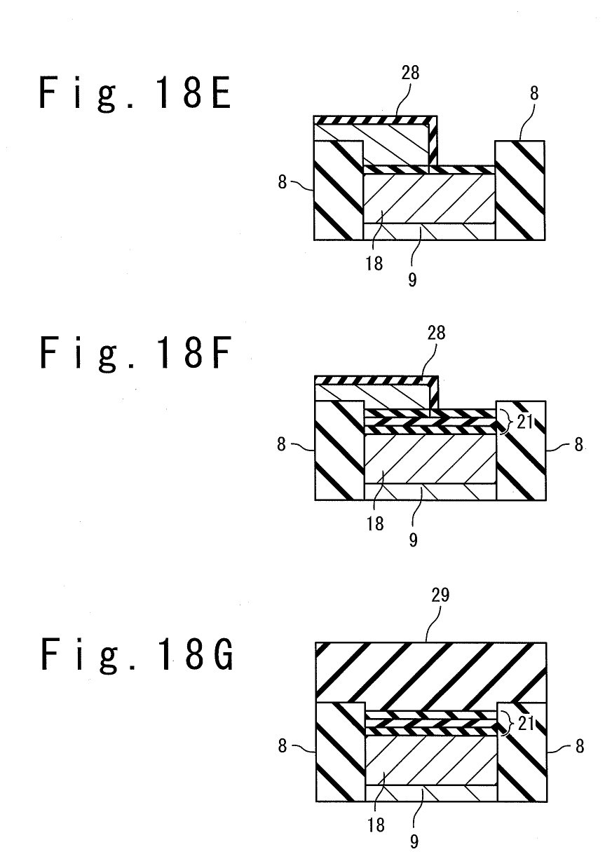

FIGS. 18A to 18G show a state in a tenth process for manufacturing the nonvolatile semiconductor memory element 2. FIG. 18A is a plan view showing a structure in the tenth process viewed from above. FIG. 18B is a cross sectional view showing the A-A′ cross section in the tenth process. FIG. 18C is a cross sectional view showing the B-B′ cross section in the tenth process. FIG. 18D is a cross sectional view showing the C-C′ cross section in the tenth process. FIG. 18E is a cross sectional view showing the D-D′ cross section in the tenth process. FIG. 18F is a cross sectional view showing the E-E′ cross section in the tenth process. FIG. 18G is a cross sectional view showing the F-F′ cross section in the tenth process.

As shown in FIG. 18A, in the tenth process, an oxide film 28 is formed to cover a surface of the exposed first polysilicon film 27. In the tenth process, an oxide film formed on the exposed polysilicon film 27 is first removed by a wet etching by using hydrofluoric acid. After that, the oxide film 28 with a thickness of 3 to 6 nm is formed on the channel in the opening portion and on side walls and a top surface of the first polysilicon film 27 by the CVD method or the thermal oxidization method.

As shown in FIGS. 18C and 18D, in the tenth process, the oxide film 28 is formed on a surface of the first polysilicon film 27 in the B-B′ cross section and the C-C′ cross section. As shown in FIG. 18B, in the tenth process, the A-A′ cross section is in the same state as shown in the ninth process. Moreover, as shown in FIGS. 18E and 18F, in the tenth process, the oxide film 28 is formed on a top surface and a side surface of the first polysilicon film 27 in the D-D′ cross section and the E-E′ cross section. At this time, as shown in FIG. 18G, the F-F′ cross section is in the same state as shown in the seventh process.

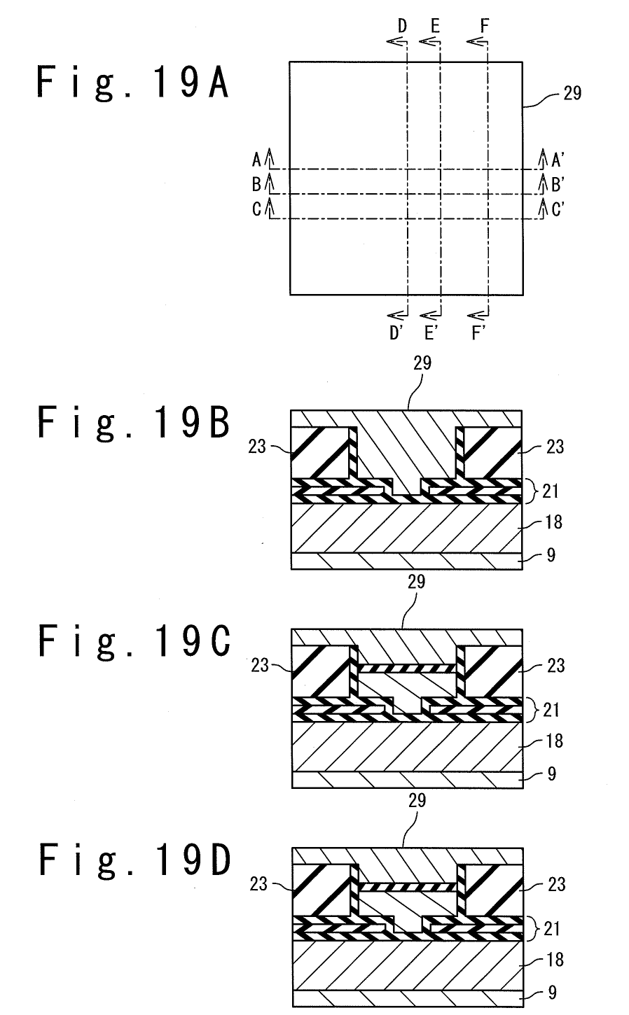

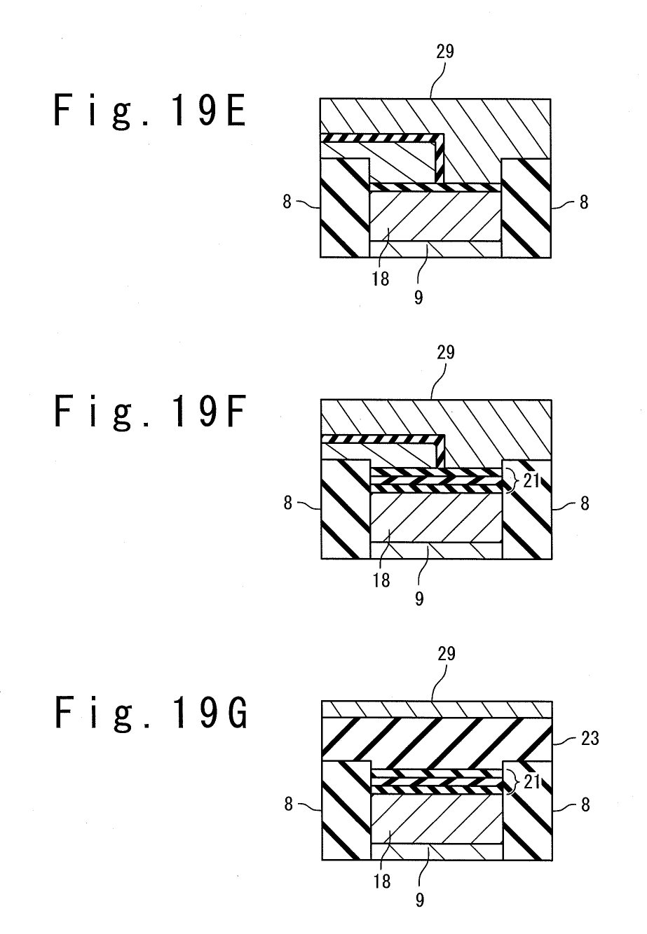

FIGS. 19A to 19G show a state in an eleventh process for manufacturing the nonvolatile semiconductor memory element 2. FIG. 19A is a plan view showing a structure in the eleventh process viewed from above. FIG. 19B is a cross sectional view showing the A-A′ cross section in the eleventh process. FIG. 19C is a cross sectional view showing the B-B′ cross section in the eleventh process. FIG. 19D is a cross sectional view showing the C-C′ cross section in the eleventh process. FIG. 19E is a cross sectional view showing the D-D′ cross section in the eleventh process. FIG. 19F is a cross sectional view showing the E-E′ cross section in the eleventh process. FIG. 19G is a cross sectional view showing the F-F′ cross section in the eleventh process.

As shown in FIGS. 19A to 19G, in the eleventh process, a second polysilicon film 29 with a film thickness of about 300 to 400 nm is blanket deposited by the CVD method or the like. The second polysilicon film 29 in the eleventh process may be doped polysilicon that is doped with n-type impurities such as phosphorus and arsenic. Alternatively, after the second polysilicon film 29 is formed, n-type impurities such as phosphorus and arsenic may be injected into the second polysilicon film 29.

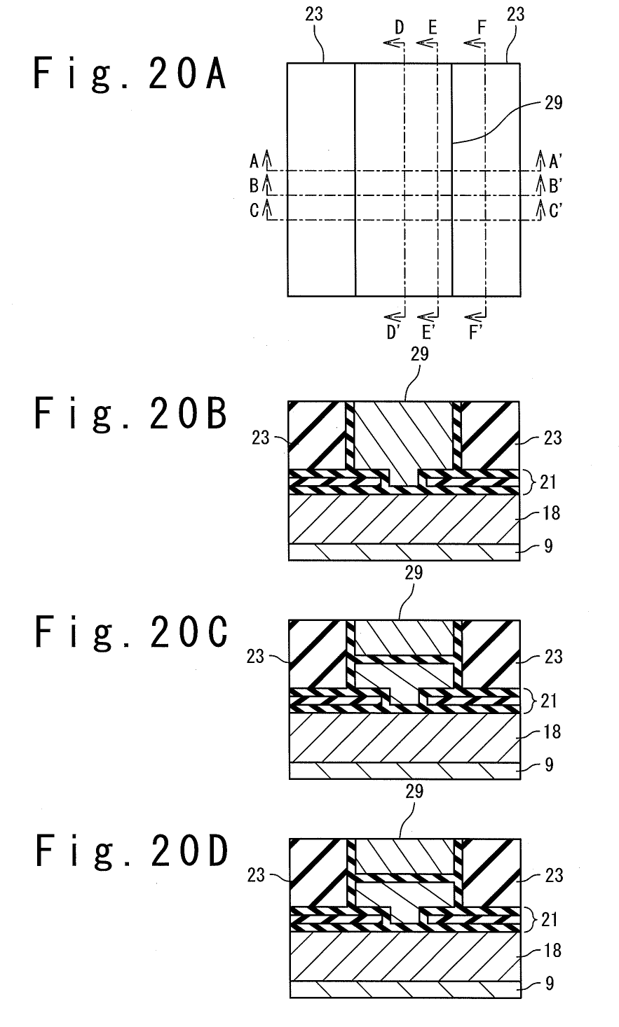

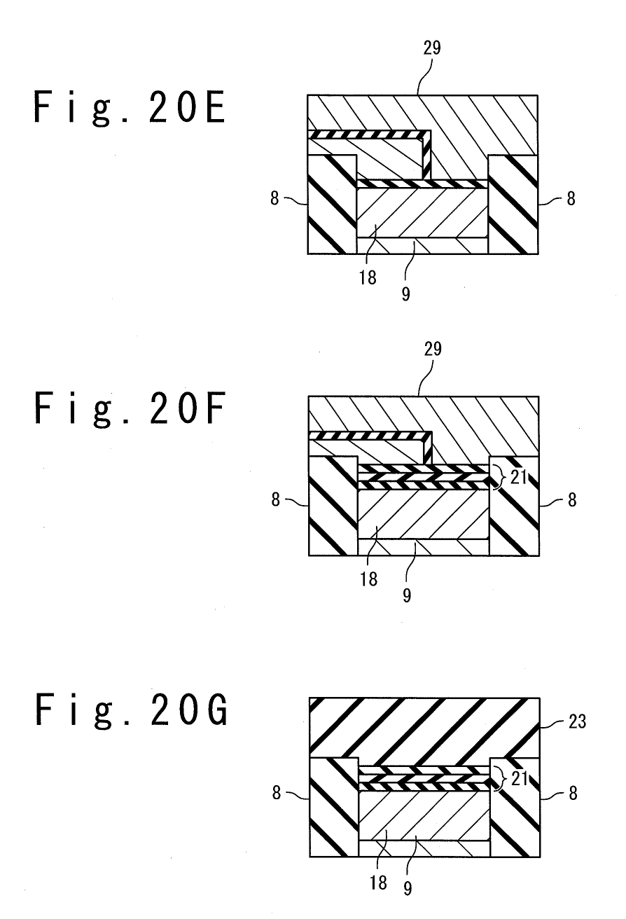

FIGS. 20A to 20G show a state in a twelfth process for manufacturing the nonvolatile semiconductor memory element 2. FIG. 20A is a plan view showing a structure in the twelfth process viewed from above. FIG. 20B is a cross sectional view showing the A-A′ cross section in the twelfth process. FIG. 20C is a cross sectional view showing the B-B′ cross section in the twelfth process. FIG. 20D is a cross sectional view showing the C-C′ cross section in the twelfth process. FIG. 20E is a cross sectional view showing the D-D′ cross section in the twelfth process. FIG. 20F is a cross sectional view showing the E-E′ cross section in the twelfth process. FIG. 20G is a cross sectional view showing the F-F′ cross section in the twelfth process.

As shown in FIGS. 20A to 20G, in the twelfth process, the second polysilicon film 29 is subjected to planarization by the CMP method or the like until the nitride film 23 is exposed.

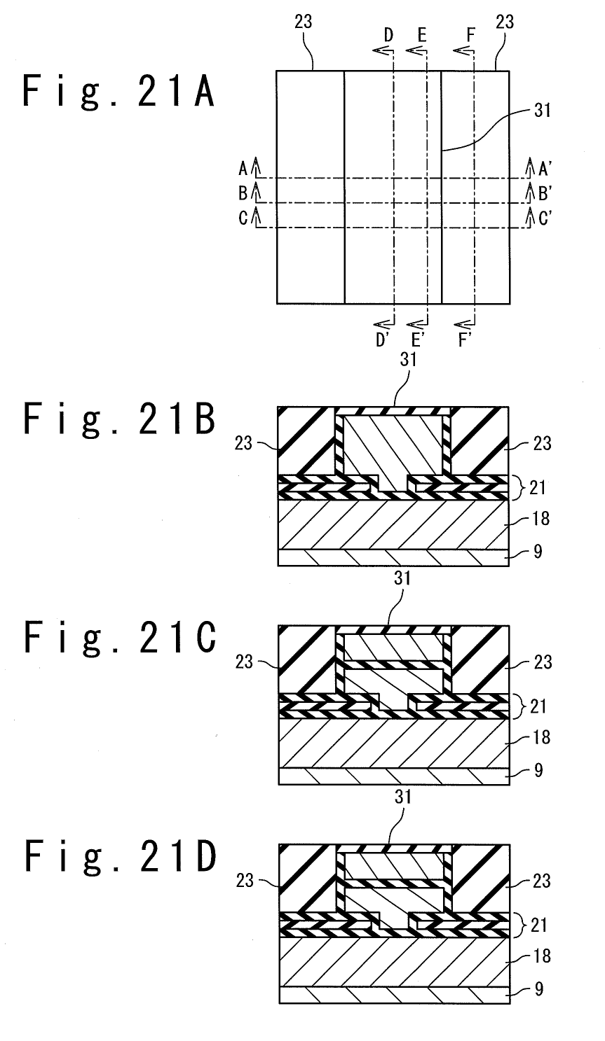

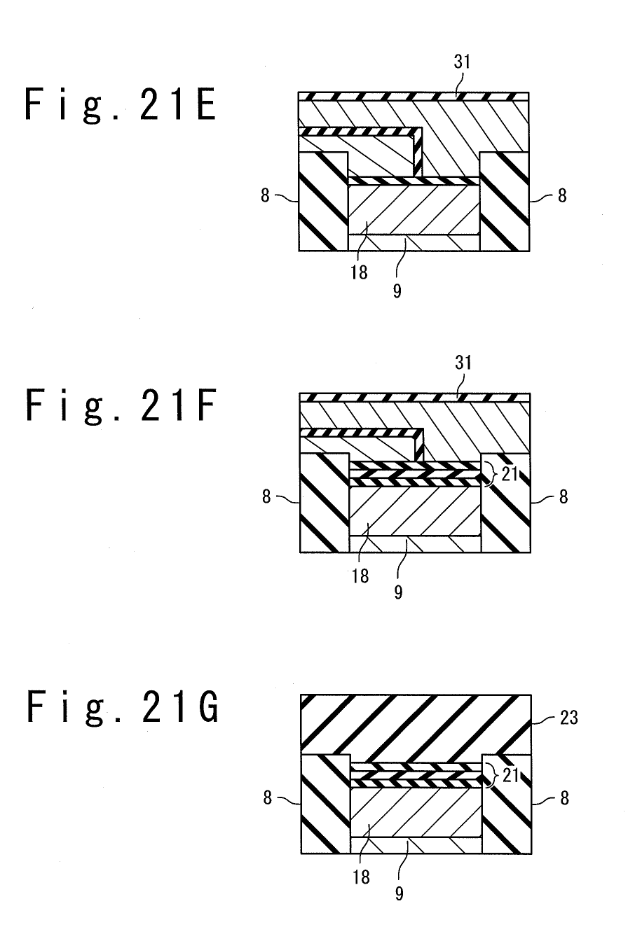

FIGS. 21A to 21G show a state in a thirteenth process for manufacturing the nonvolatile semiconductor memory element 2. FIG. 21A is a plan view showing a structure in the thirteenth process viewed from above. FIG. 21B is a cross sectional view showing the A-A′ cross section in the thirteenth process. FIG. 21C is a cross sectional view showing the B-B′ cross section in the thirteenth process.

FIG. 21D is a cross sectional view showing the C-C′ cross section in the thirteenth process. FIG. 21E is a cross sectional view showing the D-D′ cross section in the thirteenth process. FIG. 21F is a cross sectional view showing the E-E′ cross section in the thirteenth process. FIG. 21G is a cross sectional view showing the F-F′ cross section in the thirteenth process.

As shown in FIG. 21A, in the thirteenth process, an oxide film 31 is formed on the planarized surface of the second polysilicon film 29. As shown in FIGS. 21B to 21F, in the thirteenth process, the oxide film 31 with a film thickness of about 10 to 15 nm is formed on the second polysilicon film 29 by the CVD method or the thermal oxidization method. Here, as shown in FIG. 21G, the F-F′ cross section is in the same state as shown in the seventh process.

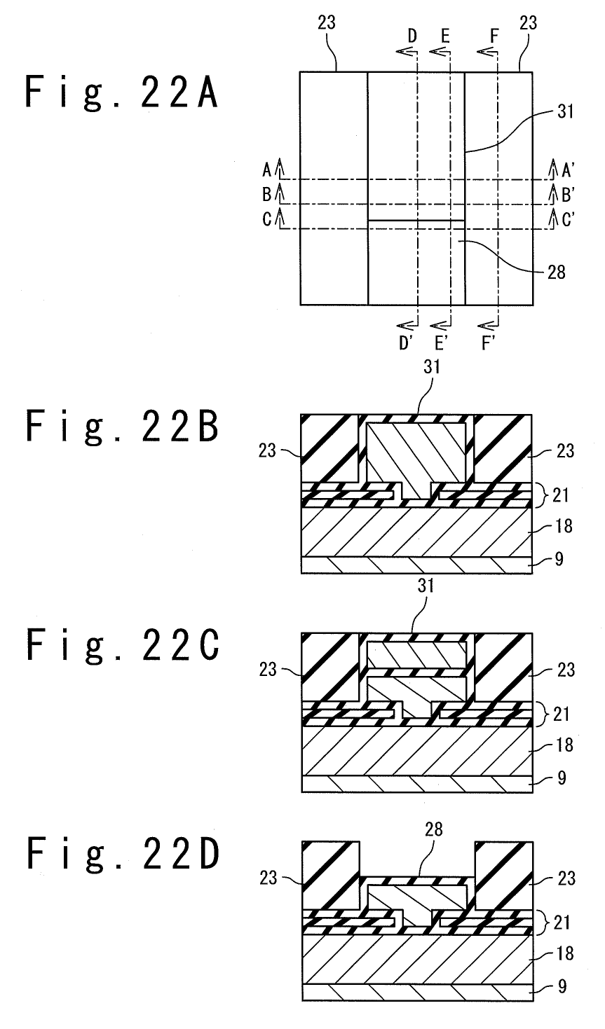

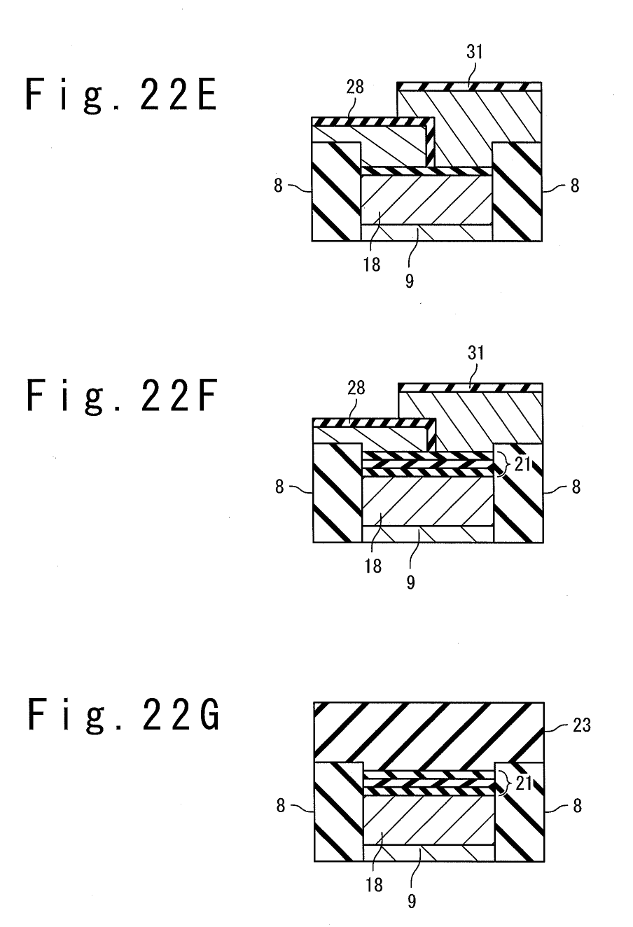

FIGS. 22A to 22G show a state in a fourteenth process for manufacturing the nonvolatile semiconductor memory element 2. FIG. 22A is a plan view showing a structure in the fourteenth process viewed from above. FIG. 22B is a cross sectional view showing the A-A′ cross section in the fourteenth process. FIG. 22C is a cross sectional view showing the B-B′ cross section in the fourteenth process. FIG. 22D is a cross sectional view showing the C-C′ cross section in the fourteenth process. FIG. 22E is a cross sectional view showing the D-D′ cross section in the fourteenth process. FIG. 22F is a cross sectional view showing the E-E′ cross section in the fourteenth process. FIG. 22G is a cross sectional view showing the F-F′ cross section in the fourteenth process.

As shown in FIG. 22A, in the fourteenth process, a part of the oxide film 31 and a part of the second polysilicon film 29 are removed and thereby the oxide film 28 is exposed. As shown in FIGS. 22B and 22C, in the A-A′ cross section and the B-B′ cross section, the oxide film 31 and the second polysilicon film 29 remain therein without being removed in the fourteenth process. As shown in FIG. 22D, in the C-C′ cross section, the oxide film 31 and the second polysilicon film 29 are removed in the fourteenth process. As shown in FIGS. 22E and 22F, in the fourteenth process, a resist is applied and patterning of it is carried out, and then a part of the oxide film 31 and a part of the second polysilicon film 29 formed on the first polysilicon film 27 are removed by an etching by using the patterned resist as a mask. After that, the resist is peeled off.

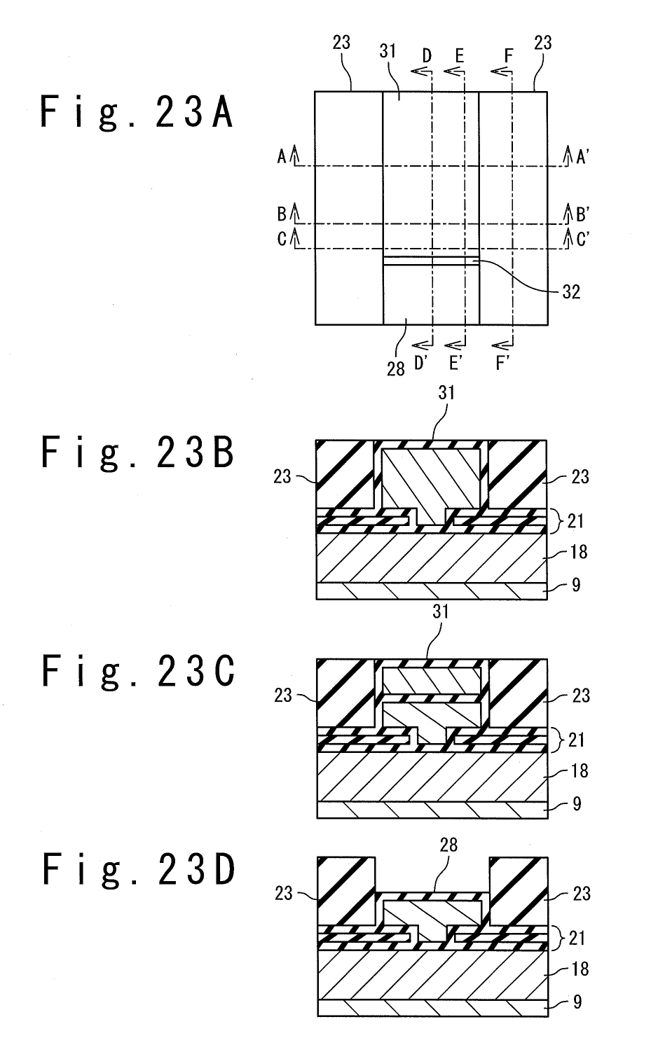

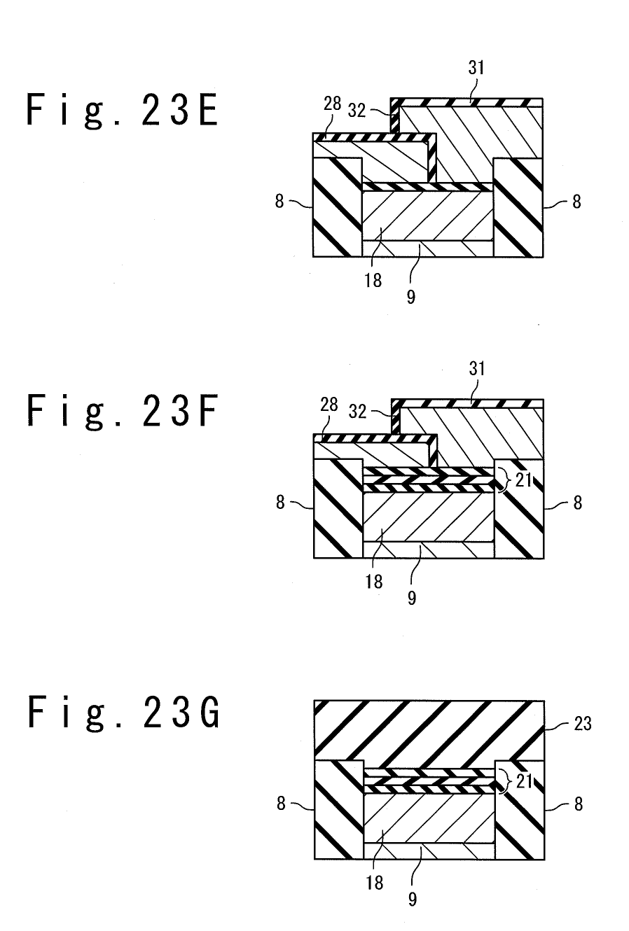

FIGS. 23A to 23G show a state in a fifteenth process for manufacturing the nonvolatile semiconductor memory element 2. FIG. 23A is a plan view showing a structure in the fifteenth process viewed from above. FIG. 23B is a cross sectional view showing the A-A′ cross section in the fifteenth process. FIG. 23C is a cross sectional view showing the B-B′ cross section in the fifteenth process. FIG. 23D is a cross sectional view showing the C-C′ cross section in the fifteenth process. FIG. 23E is a cross sectional view showing the D-D′ cross section in the fifteenth process. FIG. 23F is a cross sectional view showing the E-E′ cross section in the fifteenth process. FIG. 23G is a cross sectional view showing the F-F′ cross section in the fifteenth process.

As shown in FIGS. 23A, 23E and 23F, in the fifteenth process, thermal oxidization is applied to a side surface of the exposed second polysilicon film 29. Thereby, an oxide film 32 with a thickness of about 10 to 15 nm is formed on the exposed side surface of the second polysilicon film 29. At this time, as shown in FIGS. 23B to 23D and FIG. 23G, the A-A′ cross section, the B-B′ cross section, the C-C′ cross section and the F-F′ cross section are in the same states as shown in the fourteenth process.

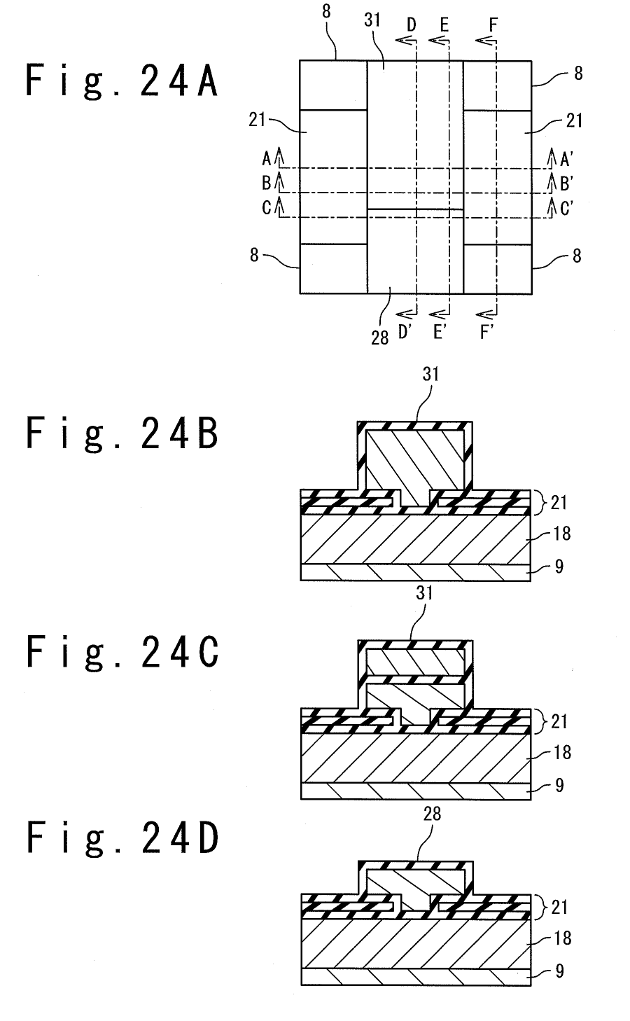

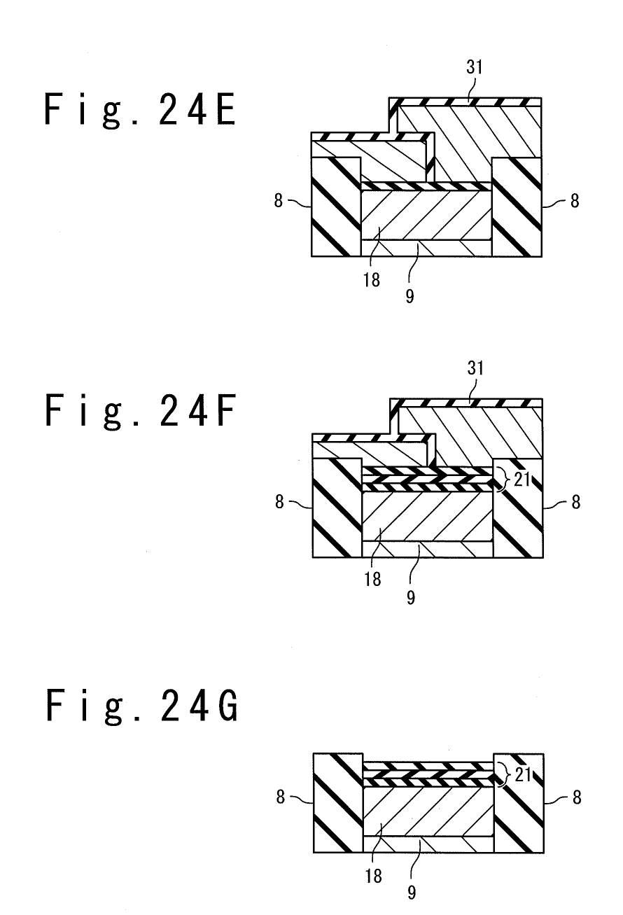

FIGS. 24A to 24G show a state in a sixteenth process for manufacturing the nonvolatile semiconductor memory element 2. FIG. 24A is a plan view showing a structure in the sixteenth process viewed from above. FIG. 24B is a cross sectional view showing the A-A′ cross section in the sixteenth process. FIG. 24C is a cross sectional view showing the B-B′ cross section in the sixteenth process. FIG. 24D is a cross sectional view showing the C-C′ cross section in the sixteenth process. FIG. 24E is a cross sectional view showing the D-D′ cross section in the sixteenth process. FIG. 24F is a cross sectional view showing the E-E′ cross section in the sixteenth process. FIG. 24G is a cross sectional view showing the F-F′ cross section in the sixteenth process.

As shown in FIGS. 24A to 24D and 24G, in the sixteenth process, the nitride film 23 is removed by a wet etching using phosphoric acid or the like.

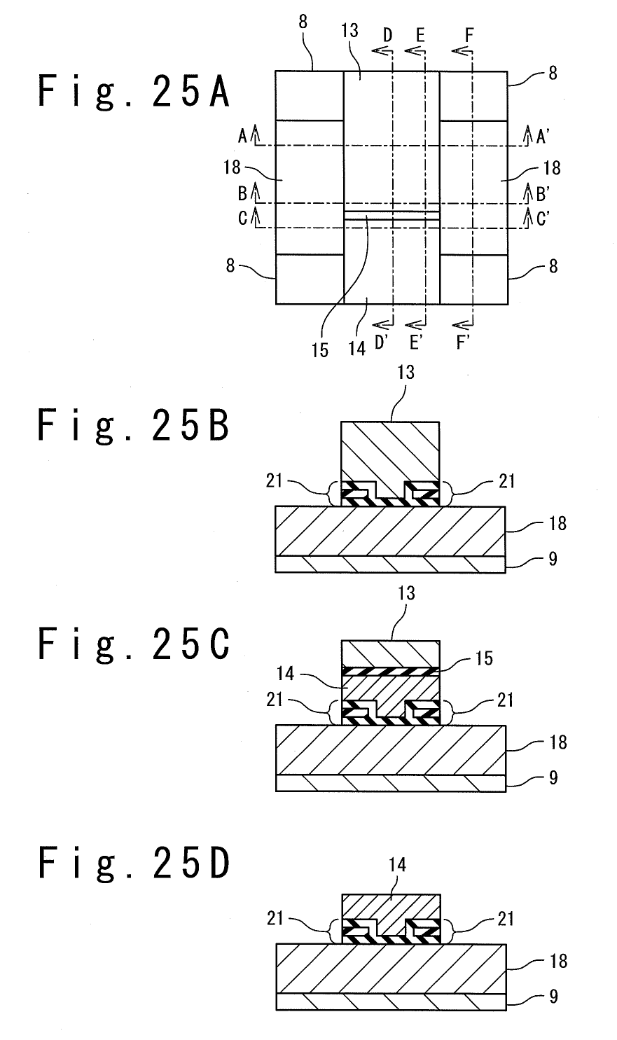

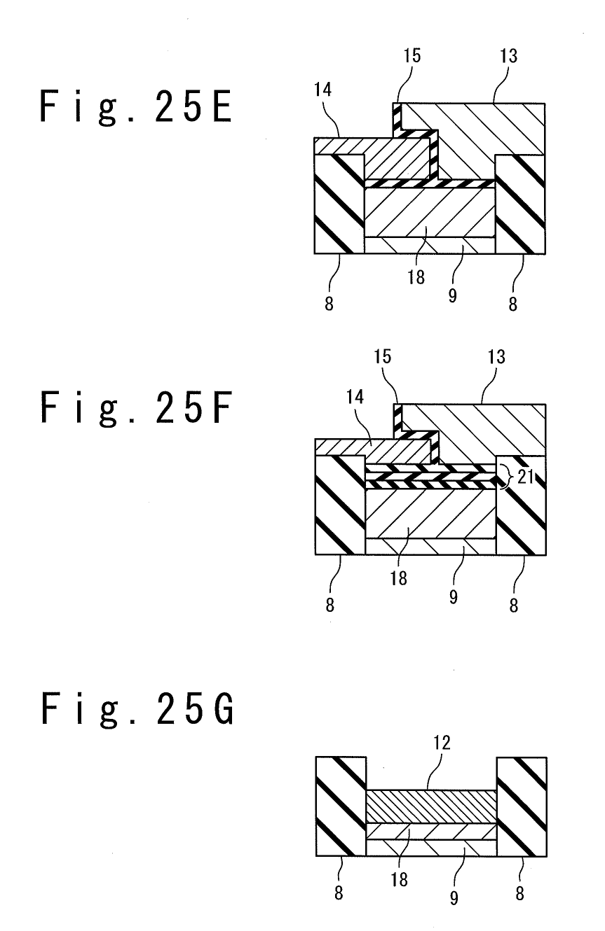

FIGS. 25A to 25G show a state in a seventeenth process for manufacturing the nonvolatile semiconductor memory element 2. FIG. 25A is a plan view showing a structure in the seventeenth process viewed from above. FIG. 25B is a cross sectional view showing the A-A′ cross section in the seventeenth process. FIG. 25C is a cross sectional view showing the B-B′ cross section in the seventeenth process. FIG. 25D is a cross sectional view showing the C-C′ cross section in the seventeenth process. FIG. 25E is a cross sectional view showing the D-D′ cross section in the seventeenth process. FIG. 25F is a cross sectional view showing the E-E′ cross section in the seventeenth process. FIG. 25G is a cross sectional view showing the F-F′ cross section in the seventeenth process.

As shown in FIGS. 25A to 25G, the oxide film 26 on the first polysilicon film 27 and the oxide film 31 on the second polysilicon film 29 are removed by a dry etching method. At this time, the charge storage layer 21 formed on the P well 18 also is removed by the etching.

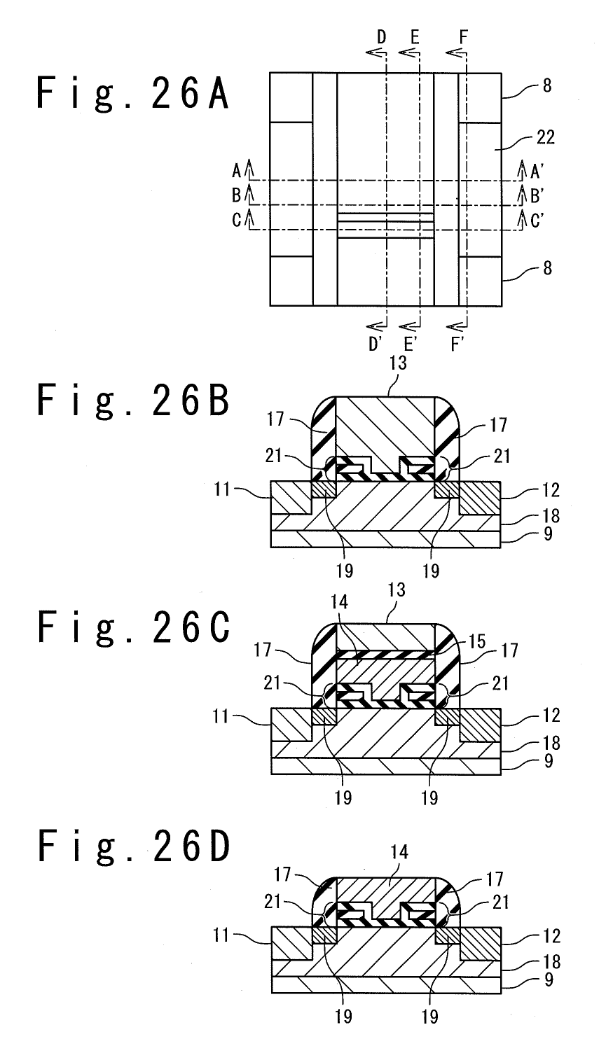

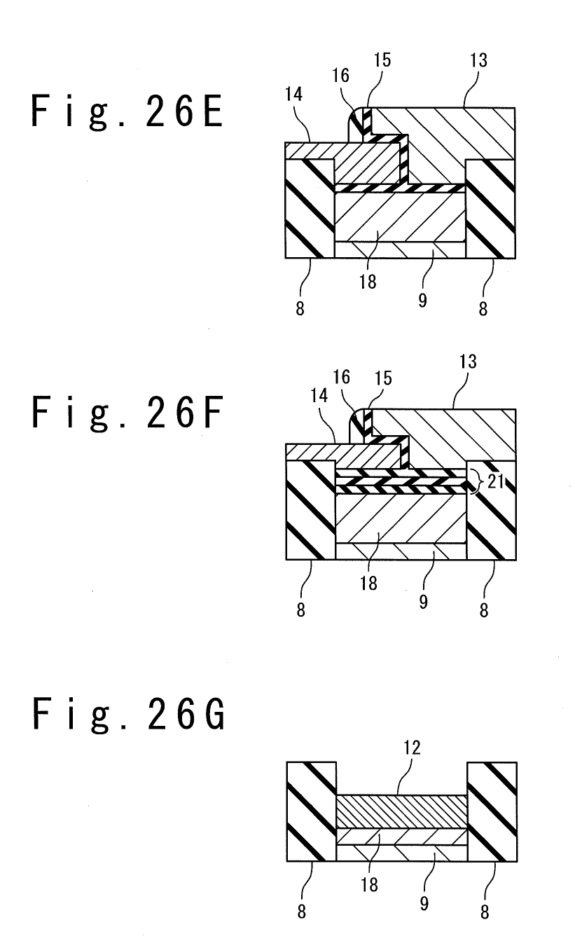

FIGS. 26A to 26G show a state in an eighteenth process for manufacturing the nonvolatile semiconductor memory element 2. FIG. 26A is a plan view showing a structure in the eighteenth process viewed from above. FIG. 26B is a cross sectional view showing the A-A′ cross section in the eighteenth process. FIG. 26C is a cross sectional view showing the B-B′ cross section in the eighteenth process. FIG. 26D is a cross sectional view showing the C-C′ cross section in the eighteenth process. FIG. 26E is a cross sectional view showing the D-D′ cross section in the eighteenth process. FIG. 26F is a cross sectional view showing the E-E′ cross section in the eighteenth process. FIG. 26G is a cross sectional view showing the F-F′ cross section in the eighteenth process.

In the eighteenth process, n-type impurities such as arsenic and phosphorus are injected into the entire surface with a degree of about 3e13/cm to form the LDD structure 19. Then, an oxide film with a film thickness of about 100 nm is deposited and the oxide film is etched back to form the side wall 16 and the side walls 17. Next, n-type impurities such as arsenic and phosphorus are injected into the entire surface with a degree of about 5e15/cm to form the first source/drain region 11 and the second source/drain region 12.

After that, an interlayer insulating film is formed, and a contact and an interconnect layer are formed. The aforementioned manufacturing method is applied to manufacture the nonvolatile semiconductor memory element 2, whereby a memory cell in which the ONO film serving as a trap layer is formed only in a portion adjacent to the source and drain diffusion layers and two gates are formed on the channel region is completed.

### Second Embodiment

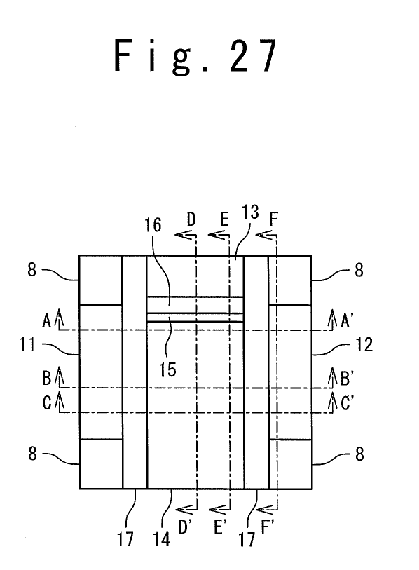

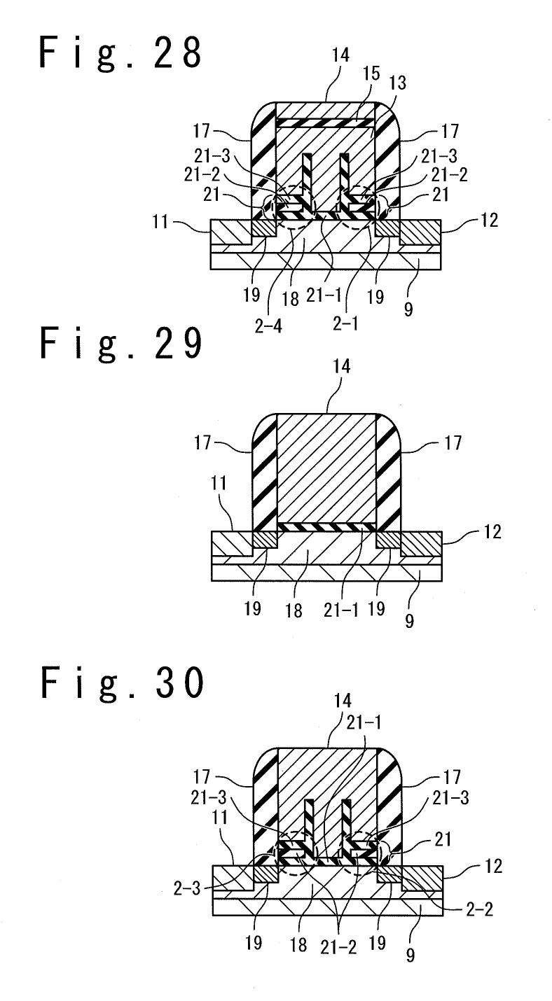

A second embodiment of the present invention will be described below with reference to drawings. FIG. 27 is a plan view showing a structure of the nonvolatile semiconductor memory element 2 according to the second embodiment. FIGS. 28 to 33 are cross sectional views showing the structure of the nonvolatile semiconductor memory element 2 according to the second embodiment.

As shown in FIG. 27, the nonvolatile semiconductor memory element 2 is placed between two STIs 8. The nonvolatile semiconductor memory element 2 has a first source/drain region 11, a second source/drain region 12, a first word gate 13 and a second word gate 14. An insulating film 15 is provided between the first word gate 13 and the second word gate 14. The nonvolatile semiconductor memory element 2 is also provided with a side wall 16 and side walls 17.

FIG. 28 shows a cross section which is obtained when the nonvolatile semiconductor memory element 2 in the plan view of FIG. 27 is cut along a line A-A′. As shown in FIG. 28, the nonvolatile semiconductor memory element 2 is formed on a P well 18 which is formed on the semiconductor substrate 9. In the second embodiment, a case is exemplified in which the semiconductor substrate 9 is a P-type silicon substrate (P-type well) as in the case of the first embodiment. The first source/drain region 11, the second source/drain region 12 and an LDD structure 19 are formed in the P well 18. Each of the first source/drain region 11 and the second source/drain region 12 serves as a source or a drain. In this case, the first source/drain region 11 and the second source/drain region 12 each is an N-type diffusion region. A semiconductor region between the first source/drain region 11 and the second source/drain region 12 serves as a channel region. The nonvolatile semiconductor memory element 2 is provided with a plurality of gate electrodes (the first word gate 13 and the second word gate 14) formed on the channel region. Side surfaces of the first word gate 13 are electrically insulated from the surrounding by the side walls 17. The LDD structures 19 are formed in the P well 18 below the respective side walls 17.

As shown in FIG. 28, the nonvolatile semiconductor memory element 2 in the A-A′ cross section includes a charge storage layer 21 corresponding to the first memory section 2-1 and a charge storage layer 21 corresponding to the fourth memory section 2-4 between the first word gate 13 and the P well 18. Each of the charge storage layers 21 includes a bottom insulating film 21-1, a charge trapping film 21-2 and a top insulating film 21-3.

The bottom insulating film 21-1 is an insulating film facing the P well 18 and formed between the charge trapping film 21-2 and the P well 18. On the other hand, the top insulating film 21-3 is an insulating film facing the first word gate 13 and formed between the charge trapping film 21-2 and the first word gate 13. The charge trapping film 21-2 is an insulating film having charge trapping ability and is sandwiched between the bottom insulating film 21-1 and the top insulating film 21-3. The charge storage layer 21 is, for example, an ONO film. In this case, the bottom insulating film 21-1, the charge trapping film 21-2 and the top insulating film 21-3 are a silicon oxide film, a silicon nitride film and a silicon oxide film, respectively. In the nonvolatile semiconductor memory element 2 according to the present embodiment, the first memory section 2-1 and the fourth memory section 2-4 are so formed as to have the same shape, as in the case of the first embodiment. Furthermore, as shown in FIG. 28, the nonvolatile semiconductor memory element 2 includes, between the first memory section 2-1 and the fourth memory section 2-4, a region in which the charge trapping film 21-2 is not formed. Accordingly, movement of charges between the first memory section 2-1 and the fourth memory section 2-4 is suppressed.

FIG. 29 shows a cross section which is obtained when the nonvolatile semiconductor memory element 2 in the plan view of FIG. 27 is cut along a line B-B′. As shown in FIG. 29, the nonvolatile semiconductor memory element 2 in the B-B′ cross section includes the bottom insulating film 21-1 and the second word gate 14. The bottom insulating film 21-1 is formed between the second word gate 14 and the P well 18. The nonvolatile semiconductor memory element 2 in the B-B′ cross section does not include the charge trapping film 21-2 nor the top insulating film 21-3. Accordingly, the nonvolatile semiconductor memory element 2 suppresses movement of charges between the first memory section 2-1 and the second memory section 2-2 and suppresses movement of charges between the third memory section 2-3 and the fourth memory section 2-4, in the B-B cross section.

FIG. 30 shows a cross section which is obtained when the nonvolatile semiconductor memory element 2 in the plan view of FIG. 27 is cut along a line C-C′. As shown in FIG. 30, in the C-C′ cross section, the nonvolatile semiconductor memory element 2 is provided with the second word gate 14. The nonvolatile semiconductor memory element 2 in the C-C′ cross section includes a charge storage layer 21 corresponding to the second memory section 2-2 and a charge storage layer 21 corresponding to the third memory section 2-3 between the second word gate 14 and the P well 18. Each charge storage layer 21 includes the bottom insulating film 21-1, the charge trapping film 21-2 and the top insulating film 21-3.

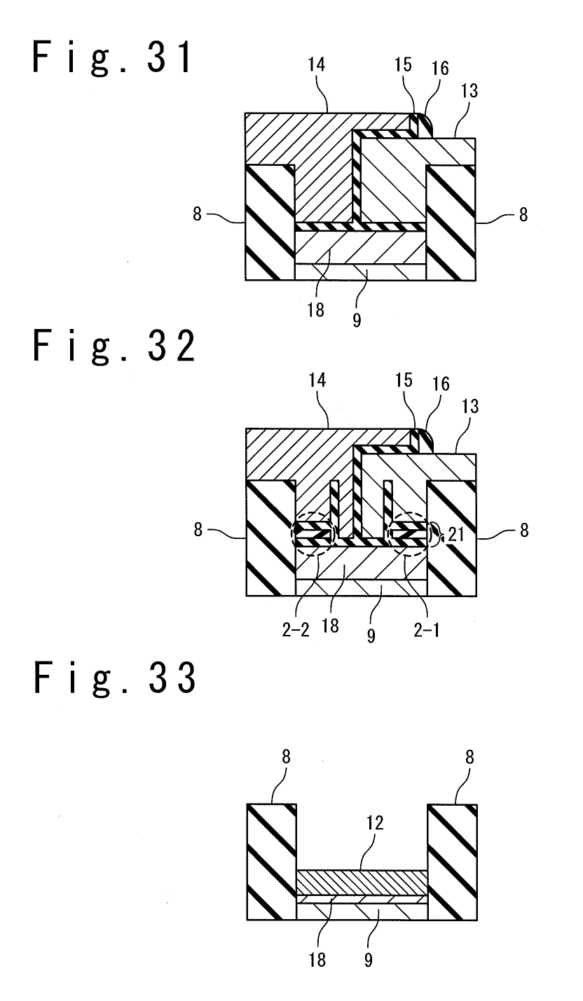

FIG. 31 shows a cross section which is obtained when the nonvolatile semiconductor memory element 2 in the plan view of FIG. 27 is cut along a line D-D′. The nonvolatile semiconductor memory element 2 is formed between two STIs 8. In the D-D′ cross section, the nonvolatile semiconductor memory element 2 is provided with the bottom insulating film 21-1 which is formed on the P well 18. The bottom insulating film 21-1 is connected to the insulating film 15. Therefore, the first word gate 13 and the second word gate 14 are electrically insulated from each other due to the insulating film 15.

Moreover, in the D-D′ cross section, the nonvolatile semiconductor memory element 2 is not provided with the charge trapping film 21-2 nor the top insulating film 21-3. Therefore, as shown in FIG. 31, the nonvolatile semiconductor memory element 2 suppresses movement of charges between the first memory section 2-1 and the third memory section 2-3 and suppresses movement of charges between the second memory section 2-2 and the fourth memory section 2-4.

FIG. 32 shows a cross section which is obtained when the nonvolatile semiconductor memory element 2 in the plan view of FIG. 27 is cut along a line E-E′. The nonvolatile semiconductor memory element 2 in the E-E′ cross section includes the first memory section 2-1 and the second memory section 2-2. As shown in FIG. 32, the charge storage layers 21 are formed between two STIs 8. The nonvolatile semiconductor memory element 2 is provided with the insulating film 15 which is connected to the top insulating film 21-3. The first word gate 13 and the second word gate 14 are electrically insulated from each other due to the insulating film 15.

FIG. 33 shows the F-F′ cross section of the plan view of FIG. 27. The nonvolatile semiconductor memory element 2 in the F-F′ cross section is provided with the second source/drain region 12, and the second source/drain region 12 is formed between two STIs 8. The second source/drain region 12 is formed in the P well 18. It should be noted that the first source/drain region 11 is formed in the same manner as in the case of the second source/drain region 12.

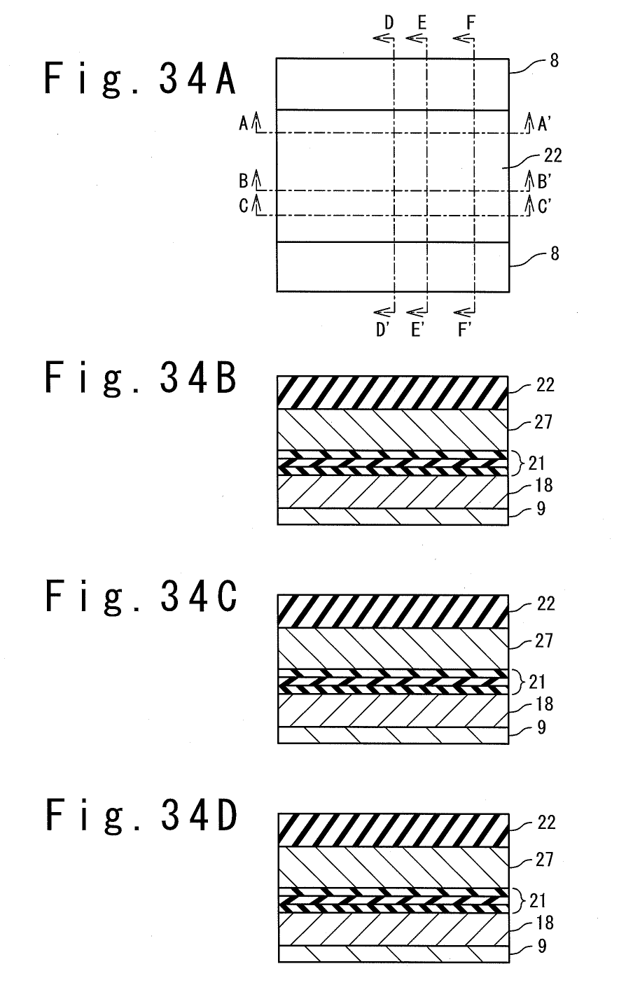

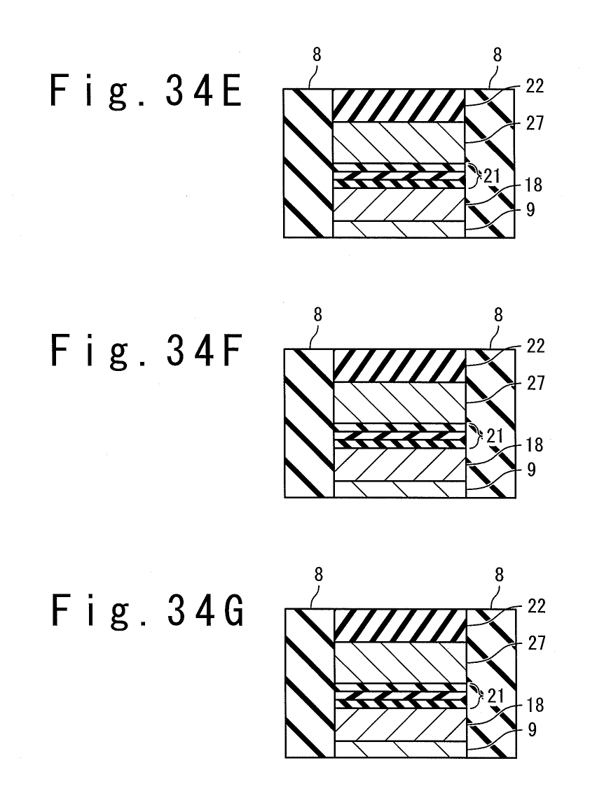

Next, a process of manufacturing the nonvolatile semiconductor memory element 2 according to the second embodiment will be described below. FIGS. 34A to 34G show a state in a first process for manufacturing the nonvolatile semiconductor memory element 2 according to the second embodiment. FIG. 34A is a plan view showing a structure in the first process viewed from above. FIG. 34B is a cross sectional view showing a cross sectional structure in the first process taken along a line A-A′ shown in FIG. 34A. FIG. 34C is a cross sectional view showing a cross sectional structure in the first process taken along a line B-B′ shown in FIG. 34A. FIG. 34D is a cross sectional view showing a cross sectional structure in the first process taken along a line C-C′ shown in FIG. 34A. FIG. 34E is a cross sectional view showing a cross sectional structure in the first process taken along a line D-D′ shown in FIG. 34A. FIG. 34F is a cross sectional view showing a cross sectional structure in the first process taken along a line E-E′ shown in FIG. 34A. FIG. 34G is a cross sectional view showing a cross sectional structure in the first process taken along a line F-F′ shown in FIG. 34A.

As shown in FIG. 34A, in the first process, a nitride film 22 is formed between the STIs 8. As shown in FIGS. 34B, 34C and 34D, in the first process, an oxide film (i.e. bottom insulating film 21-1) with a thickness of 3 to 6 nm, a nitride film (i.e. charge trapping film 21-2) with a thickness of 4 to 8 nm and an oxide film (i.e. top insulating film 21-3) with a thickness of 3 to 6 nm are formed in this order on the P well 18 on the semiconductor substrate 9 by the CVD method, to form the charge storage layer 21. The thermal oxidization method may be used for forming the oxide films. The oxide film, nitride film and oxide film serve as an ONO film (charge storage layer 21) which forms a trap layer in the memory cell.

Then, a first polysilicon film 27 with a thickness of 100 to 200 nm and the nitride film 22 with a thickness of 50 to 100 nm are formed in this order on the charge storage layer 21 by the CVD method. The first polysilicon film 27 may be doped polysilicon that is doped with n-type impurities such as phosphorus and arsenic. Alternatively, after the first polysilicon film 27 is formed, n-type impurities such as phosphorus and arsenic may be injected into the first polysilicon film 27.

Next, photoresist is applied on the nitride film 22 and then patterning of it is carried out (not shown), in the first process. Then, as shown in FIGS. 34E, 34F and 34G, by using the patterned resist (not shown) as a mask, the nitride film 22, the first polysilicon film 27, the charge storage layer 21 and the semiconductor substrate 9 are removed sequentially by an etching. At this time, the semiconductor substrate 9 is etched by about 200 to 300 nm. Thereafter, the resist is peeled off.

Next, an oxide film is blanket deposited by the CVD method. A trench portion which is formed previously by etching is also filled with the oxide film. Then, the oxide film is planarized by the CMP method until the surface of the nitride film 22 is exposed, and thereby the STI 8 (field insulating film) is formed. That is, the oxide film filled in the trench portion is used as the STI 8.

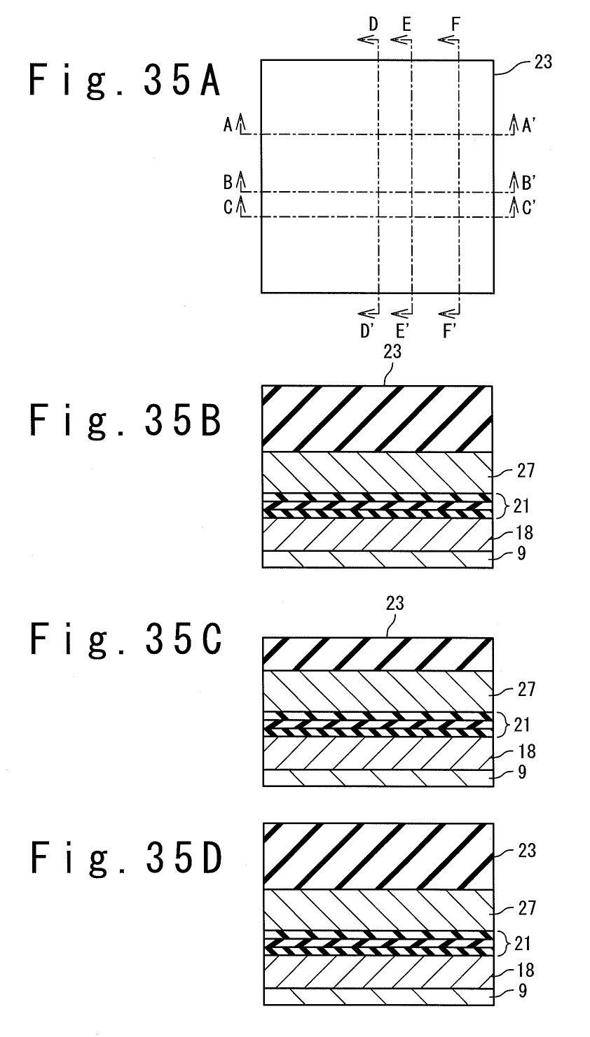

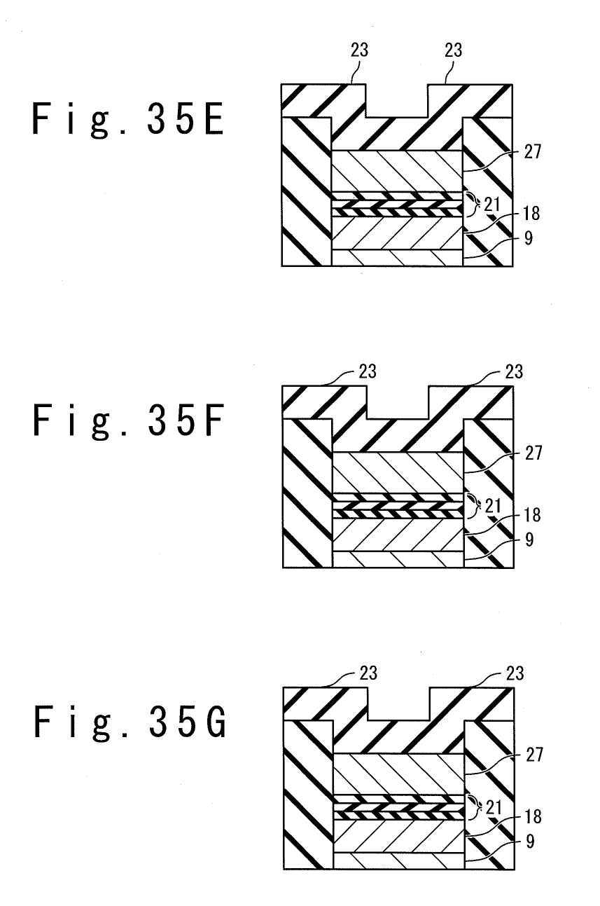

FIGS. 35A to 35G show a state in a second process for manufacturing the nonvolatile semiconductor memory element 2 according to the second embodiment. FIG. 35A is a plan view showing a structure in the second process viewed from above. FIG. 35B is a cross sectional view showing the A-A′ cross section in the second process. FIG. 35C is a cross sectional view showing the B-B′ cross section in the second process. FIG. 35D is a cross sectional view showing the C-C′ cross section in the second process. FIG. 35E is a cross sectional view showing the D-D′ cross section in the second process. FIG. 35F is a cross sectional view showing the E-E′ cross section in the second process. FIG. 35G is a cross sectional view showing the F-F′ cross section in the second process.

As shown in FIG. 35A, in the second process, a nitride film 23 is blanket deposited.

As shown in FIGS. 35B to 35G, in the second process, the nitride film 22 is removed selectively by a wet etching using phosphoric acid. After that, a nitride film 23 is blanket deposited with a thickness of 100 to 150 nm by the CVD method.

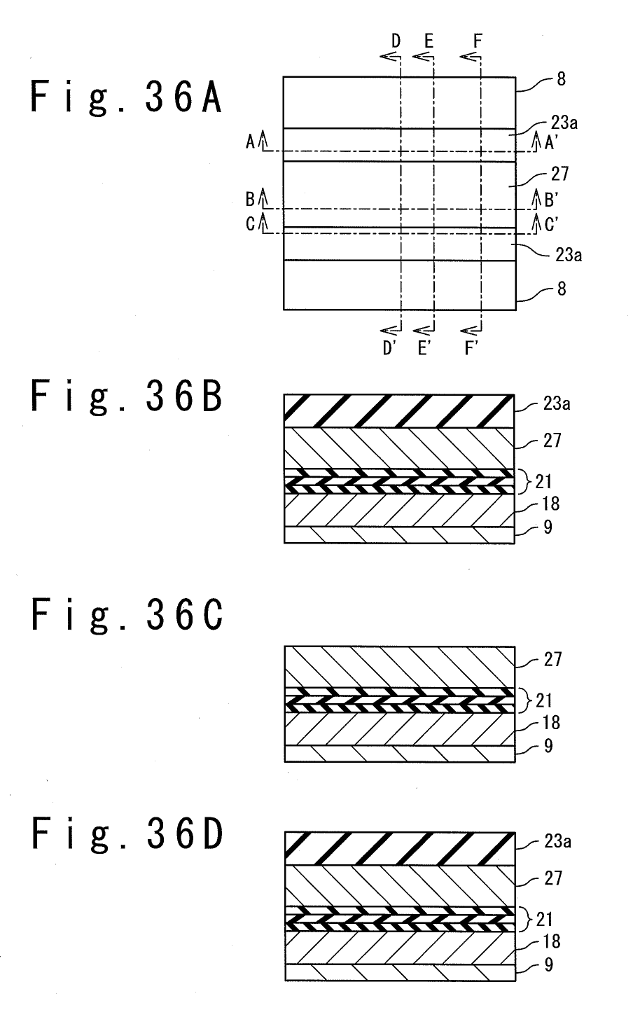

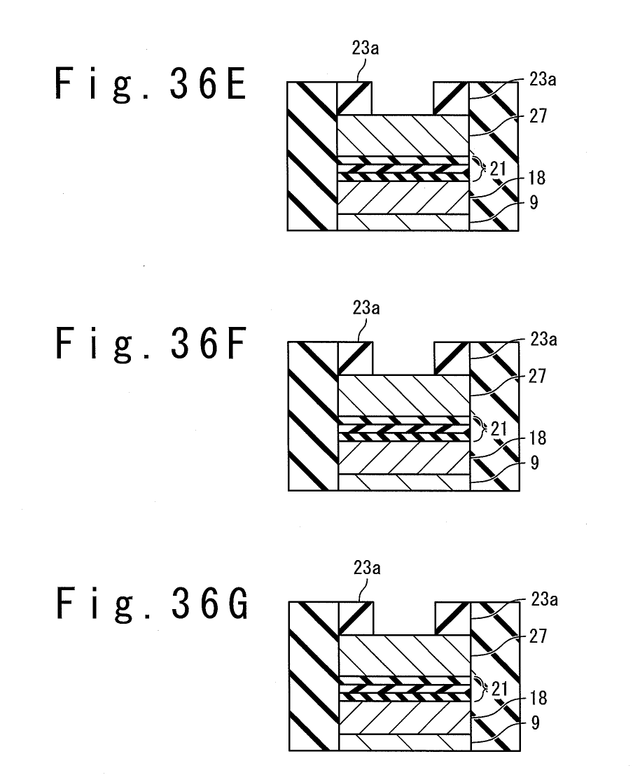

FIGS. 36A to 36G show a state in a third process for manufacturing the nonvolatile semiconductor memory element 2 according to the second embodiment. FIG. 36A is a plan view showing a structure in the third process viewed from above. FIG. 36B is a cross sectional view showing the A-A′ cross section in the third process. FIG. 36C is a cross sectional view showing the B-B′ cross section in the third process. FIG. 36D is a cross sectional view showing the C-C′ cross section in the third process. FIG. 36E is a cross sectional view showing the D-D′ cross section in the third process. FIG. 36F is a cross sectional view showing the E-E′ cross section in the third process. FIG. 36G is a cross sectional view showing the F-F′ cross section in the third process.

As shown in FIG. 36A, in the third process, the nitride film 23 is dry-etched to form nitride film side walls 23a on side surfaces of the STIs 8. The nitride film side walls 23a serve as a mask used in etching the first polysilicon film 27 in a later process.

As shown in FIGS. 36B and 36D, the nitride film side wall 23a is formed in the A-A′ cross section and the C-C′ cross section. Moreover, as shown in FIG. 36C, in the B-B′ cross section, the nitride film 23 is etched back and a surface of the first polysilicon film 27 is exposed.

As shown in FIGS. 36E to 36G, in the third process, the nitride film side walls 23a are so formed as to have the same level as the top surface of the STIs 8. Along with the formation of the nitride film side walls 23a, the surface of the first polysilicon film 27 between the nitride film side walls 23a is exposed.

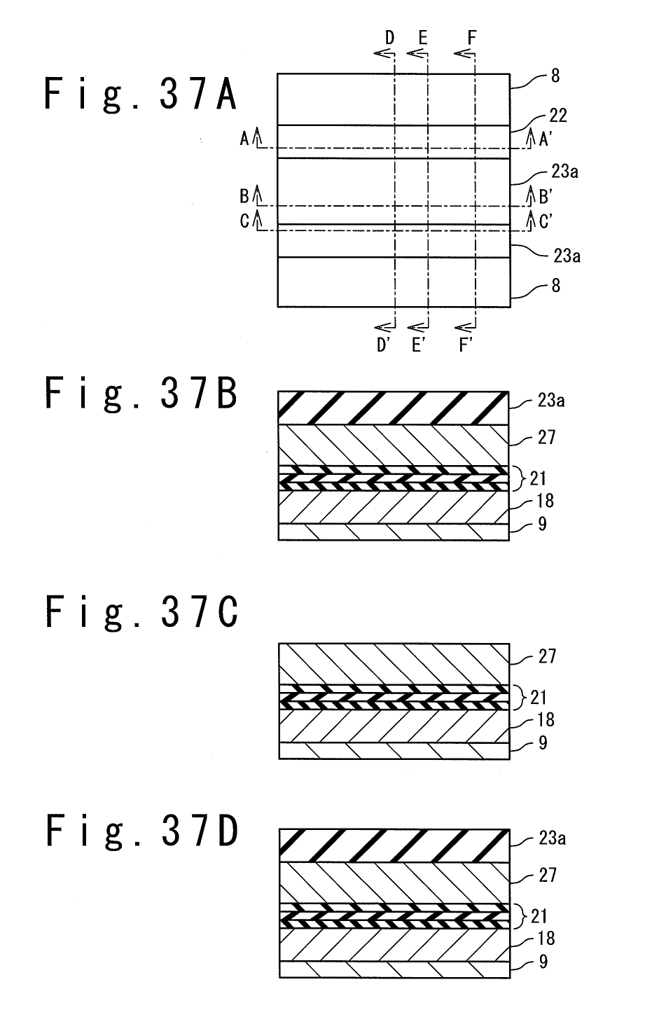

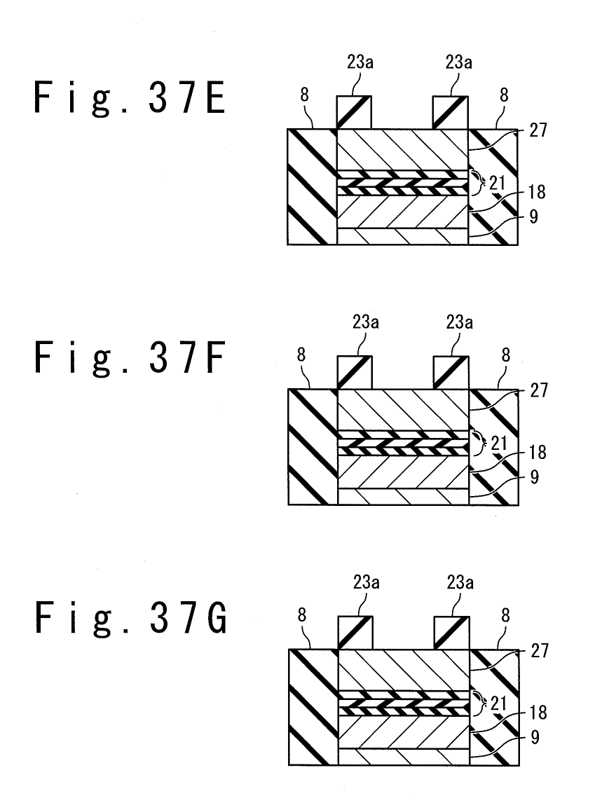

FIGS. 37A to 37G show a state in a fourth process for manufacturing the nonvolatile semiconductor memory element 2 according to the second embodiment. FIG. 37A is a plan view showing a structure in the fourth process viewed from above. FIG. 37B is a cross sectional view showing the A-A′ cross section in the fourth process. FIG. 37C is a cross sectional view showing the B-B′ cross section in the fourth process. FIG. 37D is a cross sectional view showing the C-C′ cross section in the fourth process. FIG. 37E is a cross sectional view showing the D-D′ cross section in the fourth process. FIG. 37F is a cross sectional view showing the E-E′ cross section in the fourth process. FIG. 37G is a cross sectional view showing the F-F′ cross section in the fourth process.

As shown in FIGS. 37E to 37G, in the fourth process, dry etching or wet etching is performed with respect to the STIs 8 such that surfaces of the STIs 8 become almost the same level as the top surface of the first polysilicon film 27. As shown in FIGS. 37A to 37D, structures in the A-A′ cross section, the B-B′ cross section and the C-C′ cross section at this time are the same as those in the third process.

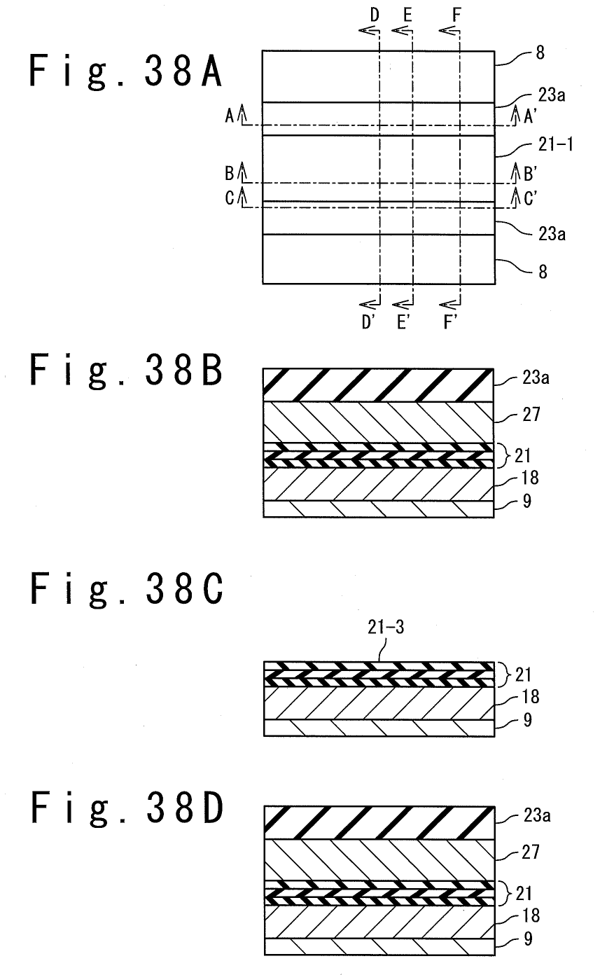

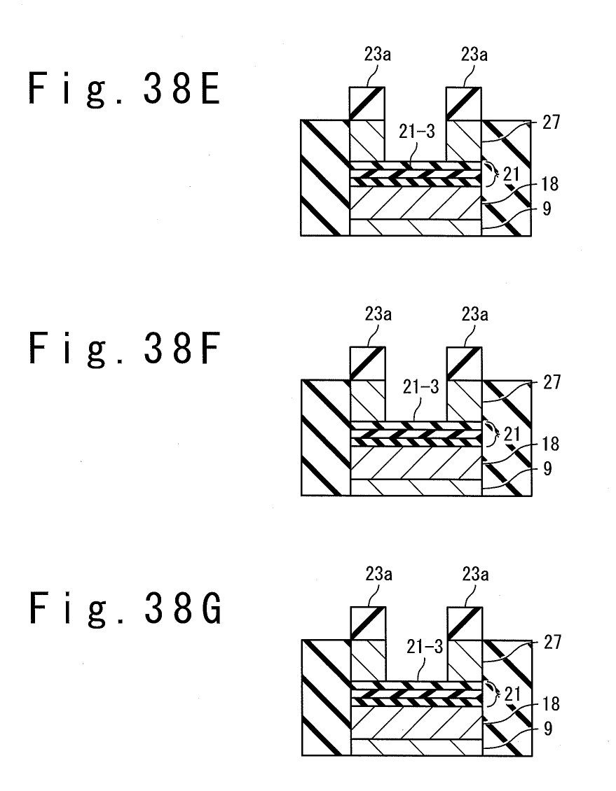

FIGS. 38A to 38G show a state in a fifth process for manufacturing the nonvolatile semiconductor memory element 2 according to the second embodiment. FIG. 38A is a plan view showing a structure in the fifth process viewed from above. FIG. 38B is a cross sectional view showing the A-A′ cross section in the fifth process. FIG. 38C is a cross sectional view showing the B-B′ cross section in the fifth process. FIG. 38D is a cross sectional view showing the C-C′ cross section in the fifth process. FIG. 38E is a cross sectional view showing the D-D′ cross section in the fifth process. FIG. 38F is a cross sectional view showing the E-E′ cross section in the fifth process. FIG. 38G is a cross sectional view showing the F-F′ cross section in the fifth process.

As shown in FIG. 38A, in the fifth process, the first polysilicon film 27 between the nitride film side walls 23a is removed and the charge storage layer 21 (top insulating film 21-3) is exposed. As shown in FIG. 38C, in the fifth process, the first polysilicon film 27 is removed and the bottom insulating film 21-1 is exposed in the B-B′ cross section. As shown in FIGS. 38E to 38F, in the fifth process, the nitride film side walls 23a are used as a mask for removing the first polysilicon film 27 by the dry etching. It should be noted that, as shown in FIGS. 38B to 38D, structures in the A-A′ cross section, the B-B′ cross section and the C-C′ cross section at this time are the same as those in the third process.

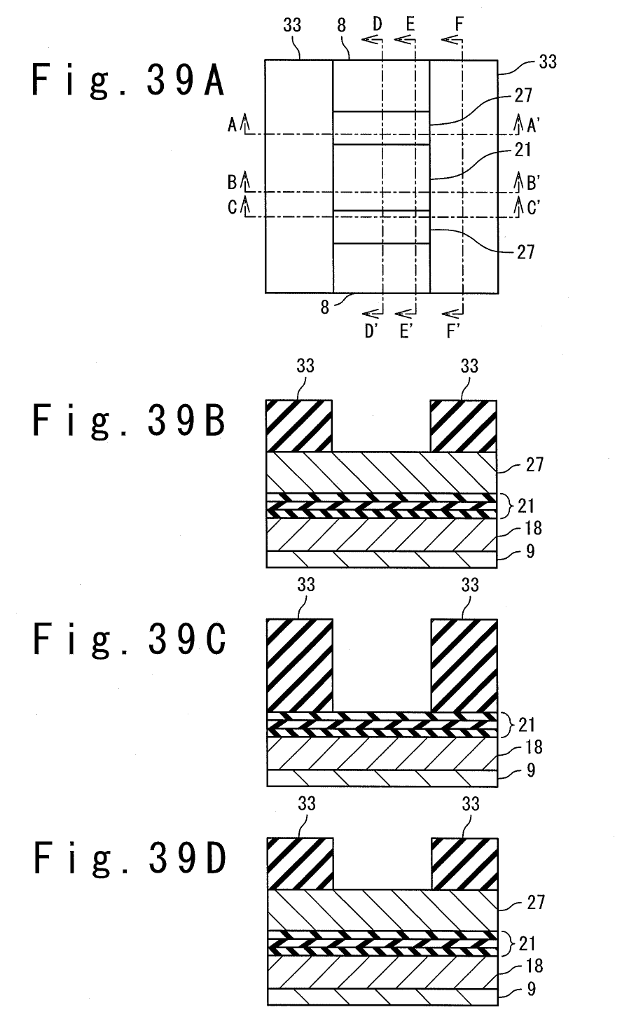

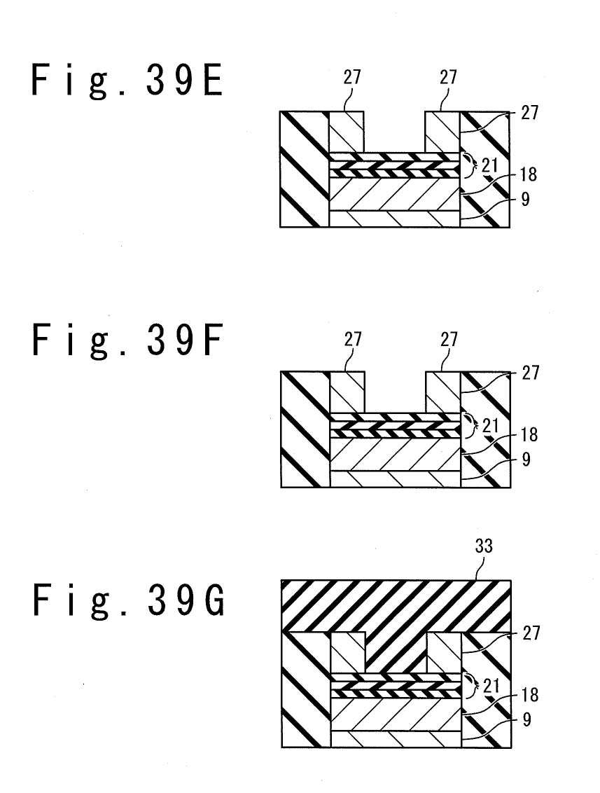

FIGS. 39A to 39G show a state in a sixth process for manufacturing the nonvolatile semiconductor memory element 2 according to the second embodiment. FIG. 39A is a plan view showing a structure in the sixth process viewed from above. FIG. 39B is a cross sectional view showing the A-A′ cross section in the sixth process. FIG. 39C is a cross sectional view showing the B-B′ cross section in the sixth process. FIG. 39D is a cross sectional view showing the C-C′ cross section in the sixth process. FIG. 39E is a cross sectional view showing the D-D′ cross section in the sixth process. FIG. 39F is a cross sectional view showing the E-E′ cross section in the sixth process. FIG. 39G is a cross sectional view showing the F-F′ cross section in the sixth process.

As shown in FIG. 39A, in the sixth process, a nitride film 33 is formed. As shown in FIGS. 39B to 39D, in the sixth process, the nitride film side walls 23a are first removed selectively by a wet etching using phosphoric acid. Next, the nitride film 33 with a film thickness of 300 to 400 nm is formed by the CVD method. After that, photoresist is applied and then patterning of it is carried out (not shown). Then, the nitride film 33 is dry etched by using the patterned resist as a mask and thereby the nitride film 33 having an opening portion is formed. As shown in FIG. 39G, the first polysilicon films 27 in the F-F′ cross section are covered by the nitride film 33 formed in the sixth process. At this time, as shown in FIGS. 39E and 39F, surfaces and side surfaces of the first polysilicon films 27 are exposed in the D-D′ cross section and the E-E′ cross section.

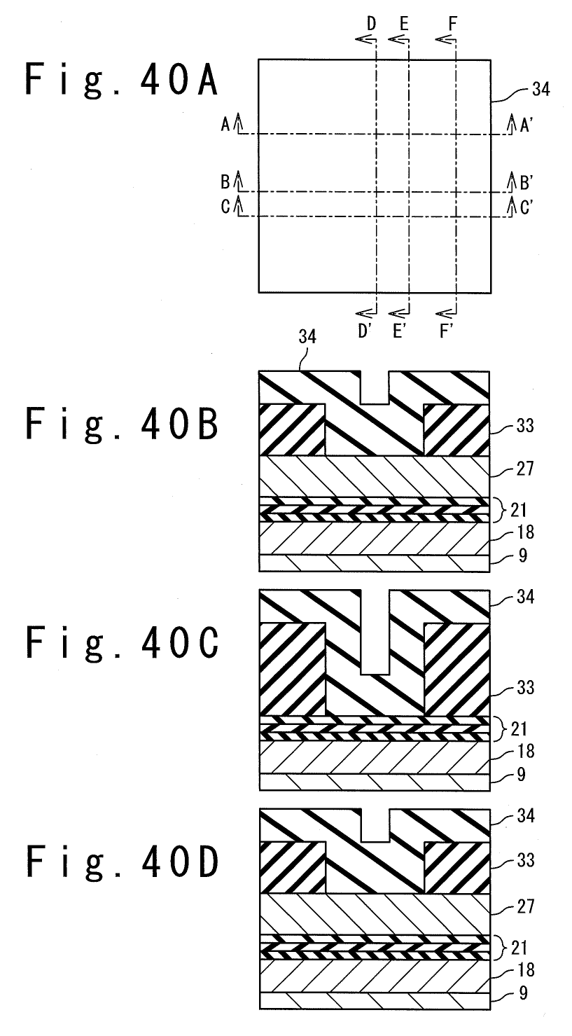

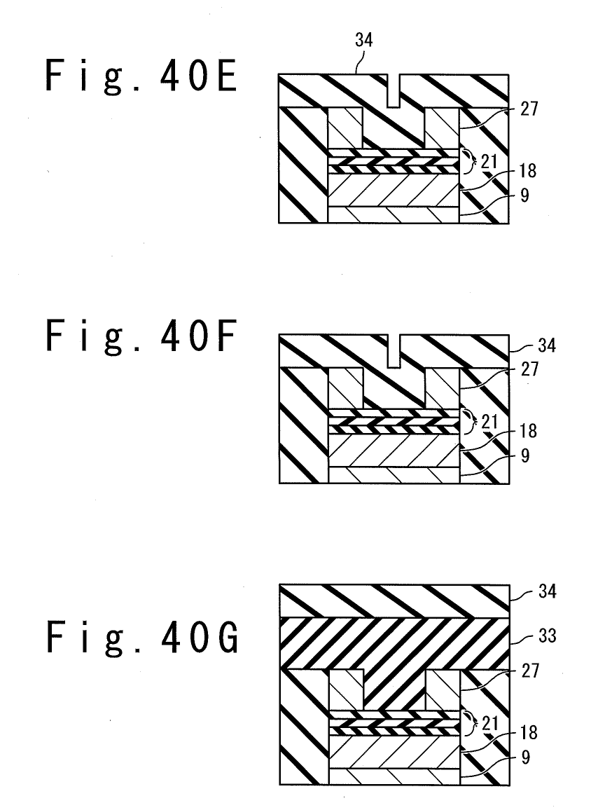

FIGS. 40A to 40G show a state in a seventh process for manufacturing the nonvolatile semiconductor memory element 2 according to the second embodiment. FIG. 40A is a plan view showing a structure in the seventh process viewed from above. FIG. 40B is a cross sectional view showing the A-A′ cross section in the seventh process. FIG. 40C is a cross sectional view showing the B-B′ cross section in the seventh process. FIG. 40D is a cross sectional view showing the C-C′ cross section in the seventh process. FIG. 40E is a cross sectional view showing the D-D′ cross section in the seventh process. FIG. 40F is a cross sectional view showing the E-E′ cross section in the seventh process. FIG. 40G is a cross sectional view showing the F-F′ cross section in the seventh process.

As shown in FIGS. 40A to 40G, in the seventh process, an oxide film 34 with a film thickness of about 100 to 200 nm is blanket deposited by using the CVD method or the like.

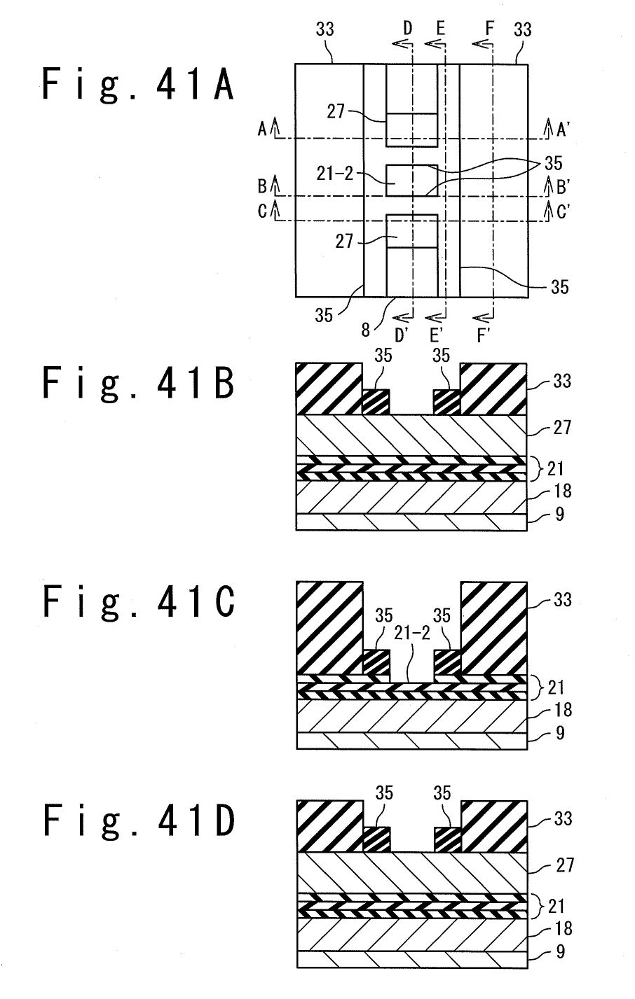

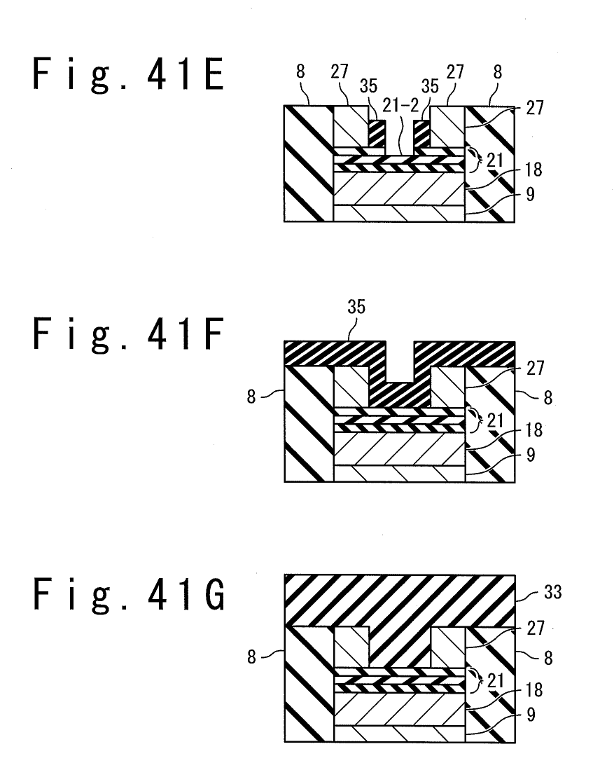

FIGS. 41A to 41G show a state in an eighth process for manufacturing the nonvolatile semiconductor memory element 2 according to the second embodiment. FIG. 41A is a plan view showing a structure in the eighth process viewed from above. FIG. 41B is a cross sectional view showing the A-A′ cross section in the eighth process. FIG. 41C is a cross sectional view showing the B-B′ cross section in the eighth process. FIG. 41D is a cross sectional view showing the C-C′ cross section in the eighth process. FIG. 41E is a cross sectional view showing the D-D′ cross section in the eighth process. FIG. 41F is a cross sectional view showing the E-E′ cross section in the eighth process. FIG. 41G is a cross sectional view showing the F-F′ cross section in the eighth process.

As shown in FIG. 41A, in the eighth process, the oxide film 34 is etched back by anisotropic dry etching and thereby oxide film side walls 35 are formed on the first polysilicon film 27 and the charge storage layer 21. In a later process, the oxide film side wall 35 is used as a mask for removing the first polysilicon film 27 by dry etching.

As shown in FIGS. 41B and 41D, in the eighth process, the oxide film side walls 35 are formed on side surfaces of the nitride films 33 in the A-A′ cross section and the C-C′ cross section. Moreover, as shown in FIG. 41C, the oxide film side walls 35 are formed on the charge storage layer 21 in the B-B′ cross section. Moreover, along with the etching of the oxide film 34, the top insulating film 21-3 is removed and the charge trapping film 21-2 is exposed in a region between the two oxide film side walls 35.

As shown in FIG. 41E, in the eighth process, the oxide film side walls 35 are formed on the side surfaces of the first polysilicon films 27 in the D-D′ cross section. Moreover, in a region between the two oxide film side walls 35 in the D-D′ cross section, the top insulating film 21-3 also is removed along with the etching of the oxide film 34. Therefore, the charge trapping film 21-2 between the two oxide film side walls 35 is exposed. Moreover, as shown in FIG. 41F, in the eighth process, the oxide film side wall 35 in the E-E′ cross section is formed to be aligned with the nitride film 33.

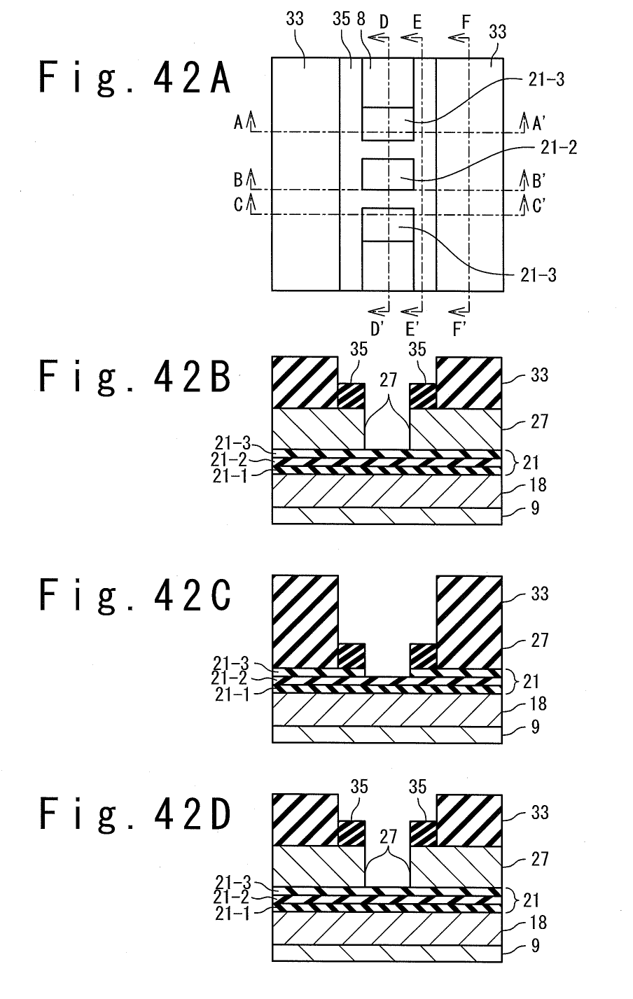

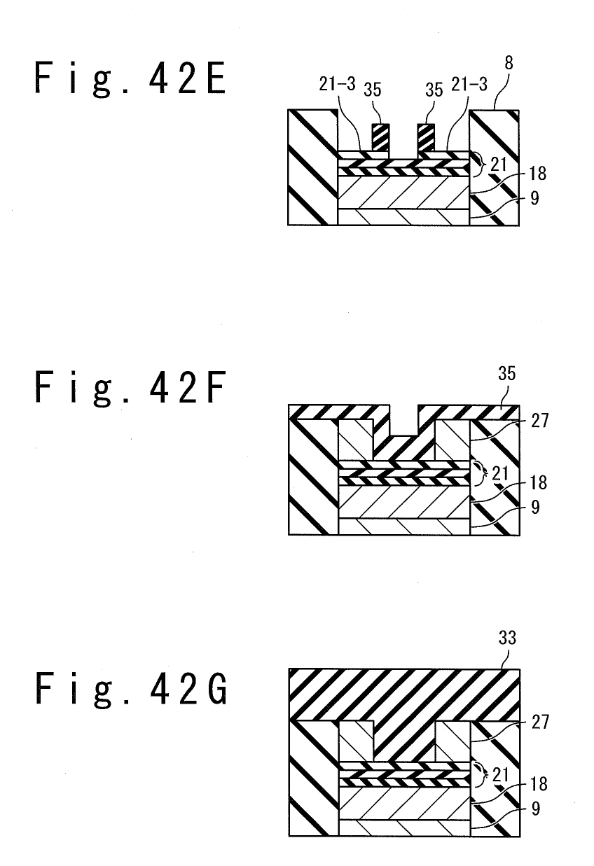

FIGS. 42A to 42G show a state in a ninth process for manufacturing the nonvolatile semiconductor memory element 2 according to the second embodiment. FIG. 42A is a plan view showing a structure in the ninth process viewed from above. FIG. 42B is a cross sectional view showing the A-A′ cross section in the ninth process. FIG. 42C is a cross sectional view showing the B-B′ cross section in the ninth process. FIG. 42D is a cross sectional view showing the C-C′ cross section in the ninth process. FIG. 42E is a cross sectional view showing the D-D′ cross section in the ninth process. FIG. 42F is a cross sectional view showing the E-E′ cross section in the ninth process. FIG. 42G is a cross sectional view showing the F-F′ cross section in the ninth process.

As shown in FIG. 42A, in the ninth process, the oxide film side walls 35 are used as a mask for removing the first polysilicon film 27 by a dry etching.

As shown in FIGS. 42B and 42D, in the ninth process, the first polysilicon film 27 between the oxide film side walls 35 is removed in the A-A′ cross section and the C-C′ cross section. As a result, a surface of the charge storage layer 21 (bottom insulating film 21-1) in a region between the oxide film side walls 35 is exposed. As shown in FIG. 42C, the structure in the B-B′ cross section is the same as that in the eighth process, wherein the charge trapping film 21-2 is exposed.

As shown in FIG. 42E, in the ninth process, the first polysilicon film 27 is removed in the D-D′ cross section. As a result, the top insulating film 21-3 is exposed. At this time, structures in the E-E′ cross section and the F-F′ cross section are the same as those in the eighth process.

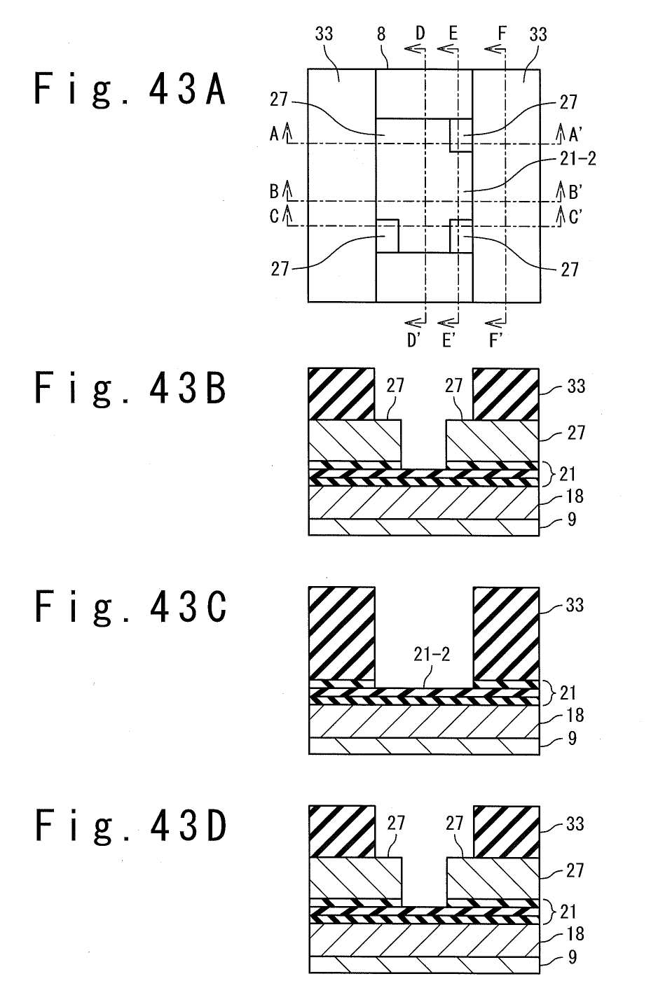

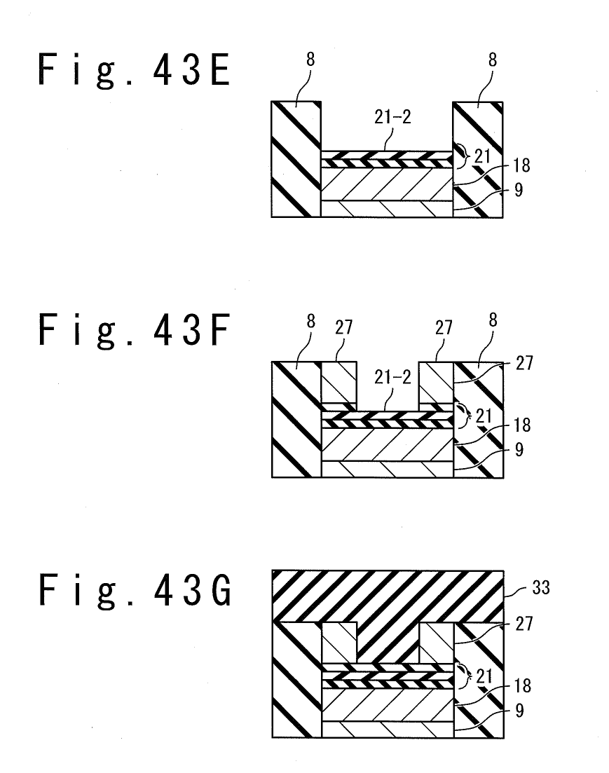

FIGS. 43A to 43G show a state in a tenth process for manufacturing the nonvolatile semiconductor memory element 2 according to the second embodiment. FIG. 43A is a plan view showing a structure in the tenth process viewed from above. FIG. 43B is a cross sectional view showing the A-A′ cross section in the tenth process. FIG. 43C is a cross sectional view showing the B-B′ cross section in the tenth process. FIG. 43D is a cross sectional view showing the C-C′ cross section in the tenth process. FIG. 43E is a cross sectional view showing the D-D′ cross section in the tenth process. FIG. 43F is a cross sectional view showing the E-E′ cross section in the tenth process. FIG. 43G is a cross sectional view showing the F-F′ cross section in the tenth process.

As shown in FIG. 43A, in the tenth process, the oxide film side walls 35 and the top insulating film 21-3 of the charge storage layer 21 are removed by a wet etching using hydrofluoric acid.

As shown in FIGS. 43B and 43D, in the tenth process, the oxide film side walls 35 which are formed on the first polysilicon films 27 are removed in the A-A′ cross section and the C-C′ cross section. As a result, the surface of the first polysilicon film 27 is exposed. Moreover, as shown in FIG. 43C, in the B-B′ cross section in the tenth process, the oxide film side walls 35 and the top insulating films 21-3 under the oxide film side walls 35 are removed, and thereby the charge trapping film 21-2 is exposed.

As shown in FIG. 43E, in the D-D′ cross section in the tenth process, the oxide film side walls 35 and the top insulating films 21-3 are removed, and thereby the charge trapping film 21-2 is exposed. As shown in FIG. 43F, in the E-E′ cross section in the tenth process, the oxide film side wall 35 which is formed to be aligned with the nitride film 33 is removed, and the surfaces and the side surfaces of the first polysilicon film 27 are exposed. Moreover, the charge trapping film 21-2 is exposed. At this time, a structure in the F-F′ cross section is the same as that in the eighth process.

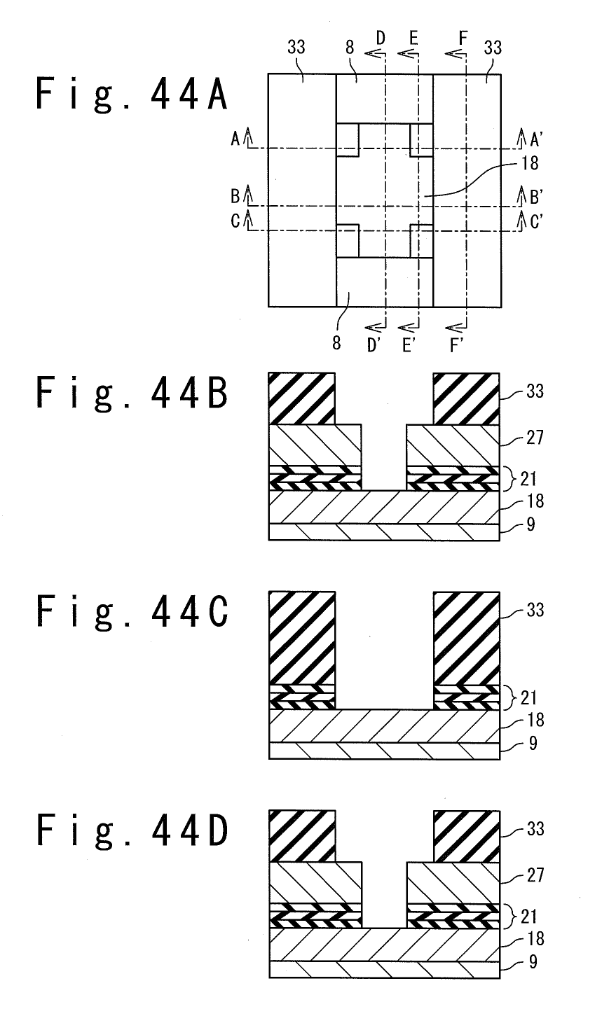

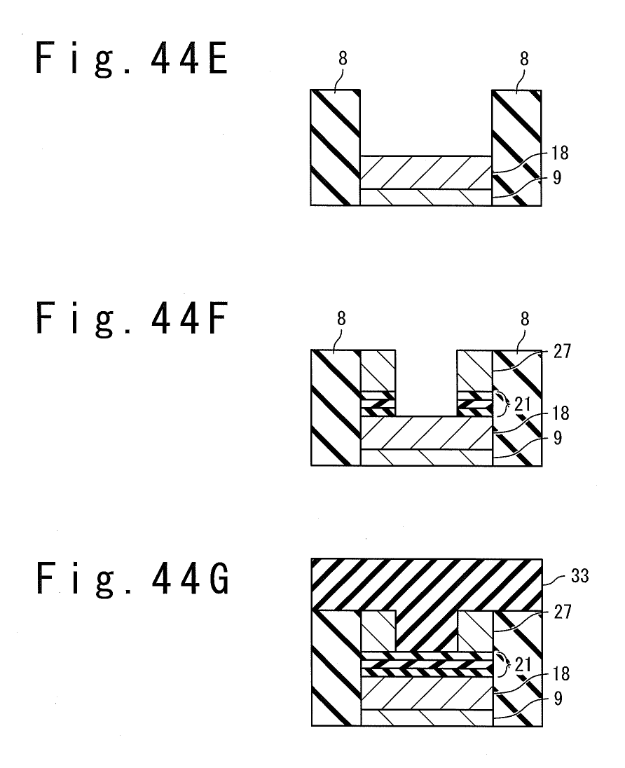

FIGS. 44A to 44G show a state in an eleventh process for manufacturing the nonvolatile semiconductor memory element 2 according to the second embodiment. FIG. 44A is a plan view showing a structure in the eleventh process viewed from above. FIG. 44B is a cross sectional view showing the A-A′ cross section in the eleventh process. FIG. 44C is a cross sectional view showing the B-B′ cross section in the eleventh process. FIG. 44D is a cross sectional view showing the C-C′ cross section in the eleventh process. FIG. 44E is a cross sectional view showing the D-D′ cross section in the eleventh process. FIG. 44F is a cross sectional view showing the E-E′ cross section in the eleventh process. FIG. 44G is a cross sectional view showing the F-F′ cross section in the eleventh process.

When the tenth process is completed, in a region surrounded by the nitride films 33 and the STIs 8, the first polysilicon films 27 which are covered by the oxide film side walls 35 remain without being removed. As shown in FIG. 44A, in the eleventh process, the first polysilicon films 27 are used as a mask for removing the charge storage layer 21 in the region surrounded by the nitride films 33 and the STIs 8 by a dry etching.

As shown in FIGS. 44B and 44D, in the A-A′ cross section and the C-C′ cross section in the eleventh process, the charge storage layer 21 between the first polysilicon films 27 is removed and the underneath P well 18 is exposed. Moreover, as shown in FIG. 44C, in the B-B′ cross section, the charge storage layer 21 between the nitride films 33 is removed and the underneath P well 18 is exposed.

As shown in FIG. 44E, in the D-D′ cross section in the eleventh process, the charge storage layer 21 in a region between the STIs 8 is removed and the underneath P well 18 is exposed. Moreover, as shown in FIG. 44F, in the E-E′ cross section in the eleventh process, the charge storage layer 21 in a region between the first polysilicon films 27 is removed and the underneath P well 18 is exposed. At this time, a structure in the F-F′ cross section is the same as that in the eighth process.

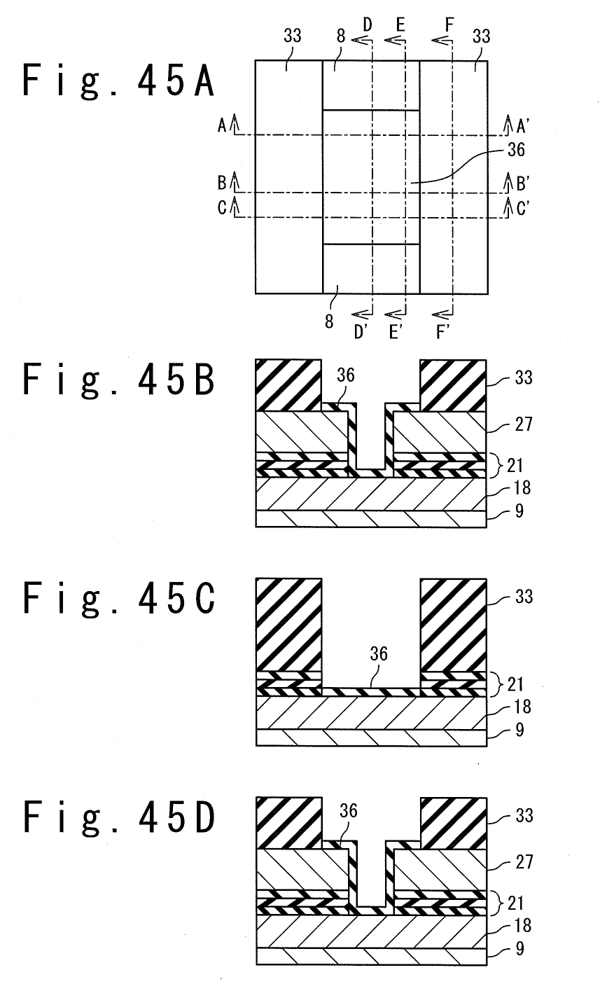

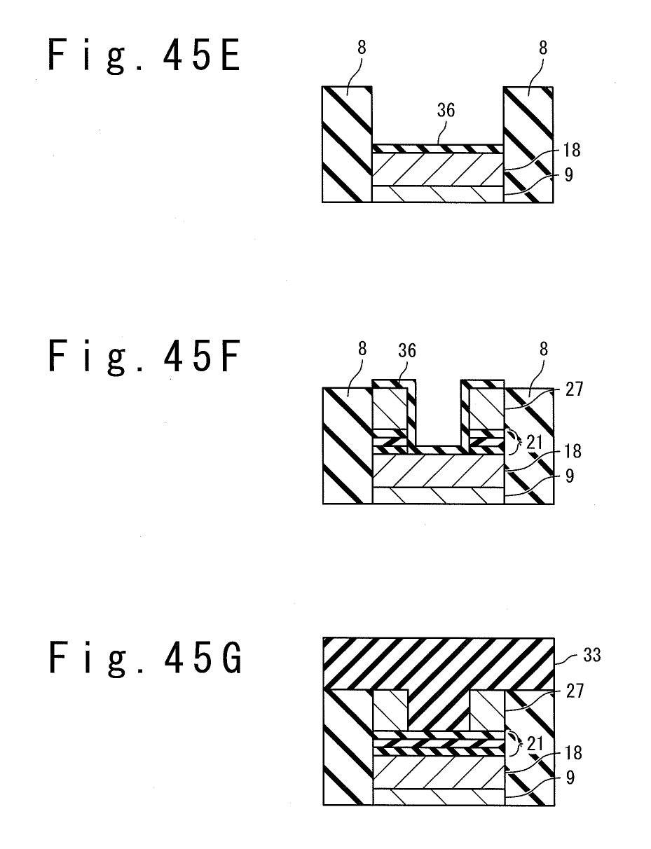

FIGS. 45A to 45G show a state in a twelfth process for manufacturing the nonvolatile semiconductor memory element 2 according to the second embodiment. FIG. 45A is a plan view showing a structure in the twelfth process viewed from above. FIG. 45B is a cross sectional view showing the A-A′ cross section in the twelfth process. FIG. 45C is a cross sectional view showing the B-B′ cross section in the twelfth process. FIG. 45D is a cross sectional view showing the C-C′ cross section in the twelfth process. FIG. 45E is a cross sectional view showing the D-D′ cross section in the twelfth process. FIG. 45F is a cross sectional view showing the E-E′ cross section in the twelfth process. FIG. 45G is a cross sectional view showing the F-F′ cross section in the twelfth process.

As shown in FIG. 45A, in the twelfth process, an oxide film 36 is formed in a region surrounded by the nitride films 33 and the STIs 8, by the CVD method, the thermal oxidization method or the like. The oxide film 36 serves as a part of the gate insulating film.

As shown in FIGS. 45B and 45D, in the A-A′ cross section and the C-C′ cross section in the twelfth process, the oxide film 36 is formed on surfaces of the first polysilicon films 27, side surfaces of the first polysilicon films 27 and the charge storage layers 21 and a surface of the P well 18. Moreover, as shown in FIG. 45C, in the B-B′ cross section in the twelfth process, the oxide film 36 is formed on the surface of the P well 18.

As shown in FIG. 45E, in the D-D′ cross section in the twelfth process, the oxide film 36 is formed on the exposed P well 18 between the STIs 8. Moreover, as shown in FIG. 45F, in the E-E′ cross section in the twelfth process, the oxide film 36 is formed on surfaces of the first polysilicon films 27, side surfaces of the first polysilicon films 27 and the charge storage layers 21 and a surface of the P well 18.

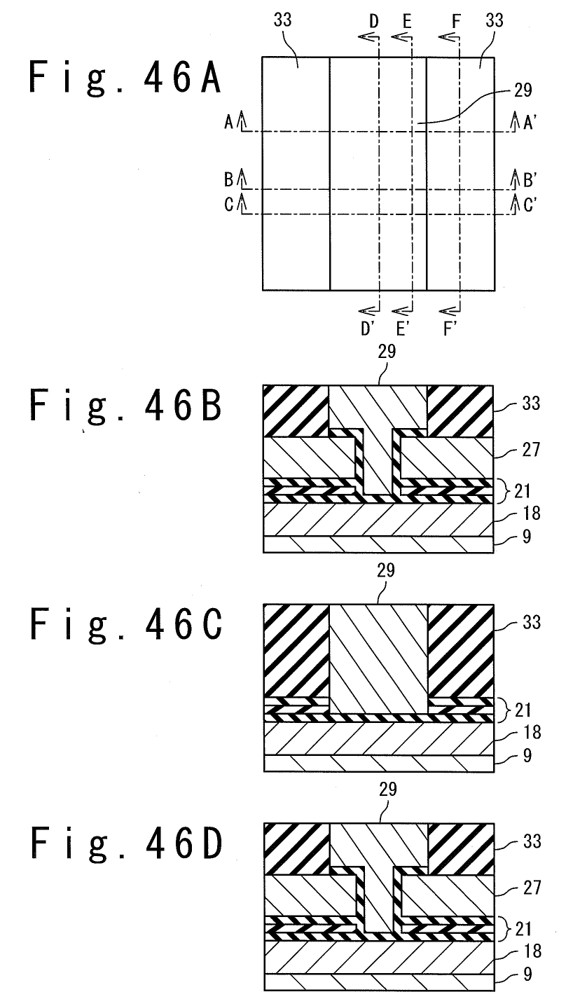

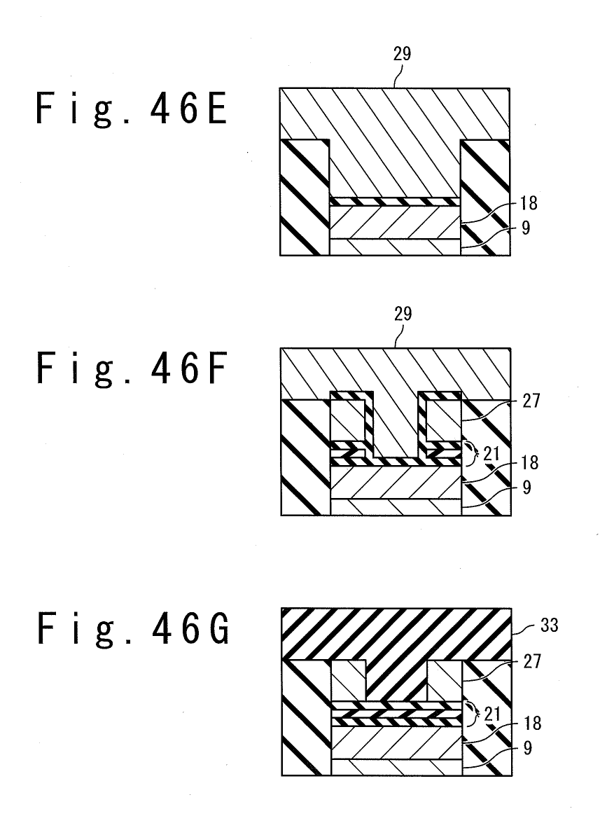

FIGS. 46A to 46G show a state in a thirteenth process for manufacturing the nonvolatile semiconductor memory element 2 according to the second embodiment. FIG. 46A is a plan view showing a structure in the thirteenth process viewed from above. FIG. 46B is a cross sectional view showing the A-A′ cross section in the thirteenth process. FIG. 46C is a cross sectional view showing the B-B′ cross section in the thirteenth process. FIG. 46D is a cross sectional view showing the C-C′ cross section in the thirteenth process. FIG. 46E is a cross sectional view showing the D-D′ cross section in the thirteenth process. FIG. 46F is a cross sectional view showing the E-E′ cross section in the thirteenth process. FIG. 46G is a cross sectional view showing the F-F′ cross section in the thirteenth process.

As shown in FIG. 46A, in the thirteenth process, a second polysilicon film 29 is formed between the nitride films 33. As shown in FIGS. 46B to 46G, in the thirteenth process, the second polysilicon film 29 is blanket deposited. The second polysilicon film 29 may be doped polysilicon that is doped with n-type impurities such as phosphorus and arsenic. Alternatively, after the second polysilicon film 29 is formed, n-type impurities such as phosphorus and arsenic may be injected into the second polysilicon film 29. After the second polysilicon film 29 is deposited, planarization process is performed by the CMP method or the like until a surface of the nitride film 33 is exposed. Consequently, the opening portion in the nitride films 33 is filled with the second polysilicon film 29.

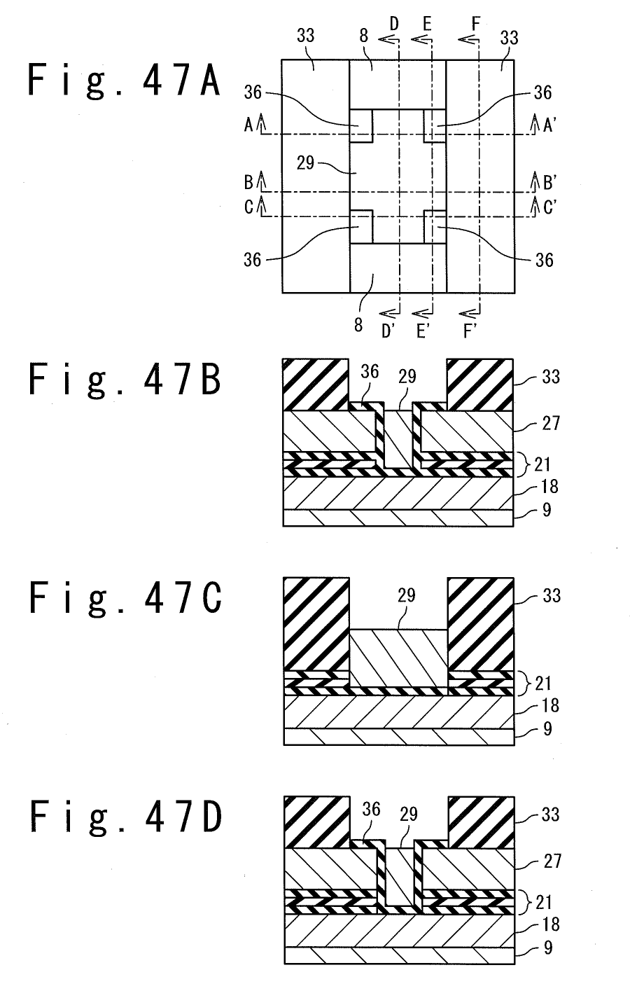

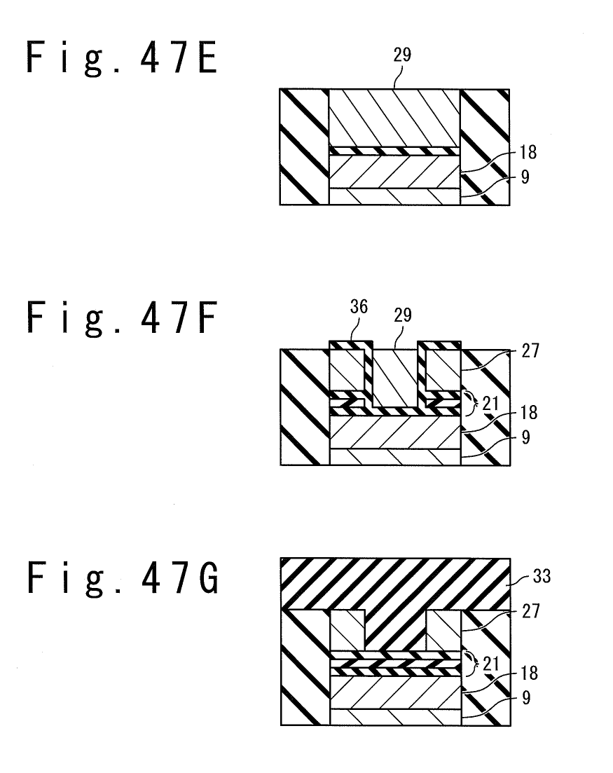

FIGS. 47A to 47G show a state in a fourteenth process for manufacturing the nonvolatile semiconductor memory element 2 according to the second embodiment. FIG. 47A is a plan view showing a structure in the fourteenth process viewed from above. FIG. 47B is a cross sectional view showing the A-A′ cross section in the fourteenth process. FIG. 47C is a cross sectional view showing the B-B′ cross section in the fourteenth process. FIG. 47D is a cross sectional view showing the C-C′ cross section in the fourteenth process. FIG. 47E is a cross sectional view showing the D-D′ cross section in the fourteenth process. FIG. 47F is a cross sectional view showing the E-E′ cross section in the fourteenth process. FIG. 47G is a cross sectional view showing the F-F′ cross section in the fourteenth process.

As shown in FIG. 47A, in the fourteenth process, a part of the second polysilicon film 29 is removed by an etching. As a result, surfaces of the oxide films 36 covering a top surface of the first polysilicon film 27 are exposed.

As shown in FIGS. 47B and 47D, in the A-A′ cross section and the C-C′ cross section in the fourteenth process, the second polysilicon film 29 is removed by a dry etching and the oxide films 36 on surfaces of the first polysilicon films 27 are exposed, in a region between the nitride films 33. Moreover, as shown in FIG. 47C, in the B-B′ cross section in the fourteenth process, the surface of the second polysilicon film 29 becomes lower than the surface of the nitride film 33.

As shown in FIGS. 47E and 47F, in the D-D′ cross section and the E-E′ cross section in the fourteenth process, the second polysilicon film 29 is so formed as to have an equivalent level to the top surface of the STI 8.

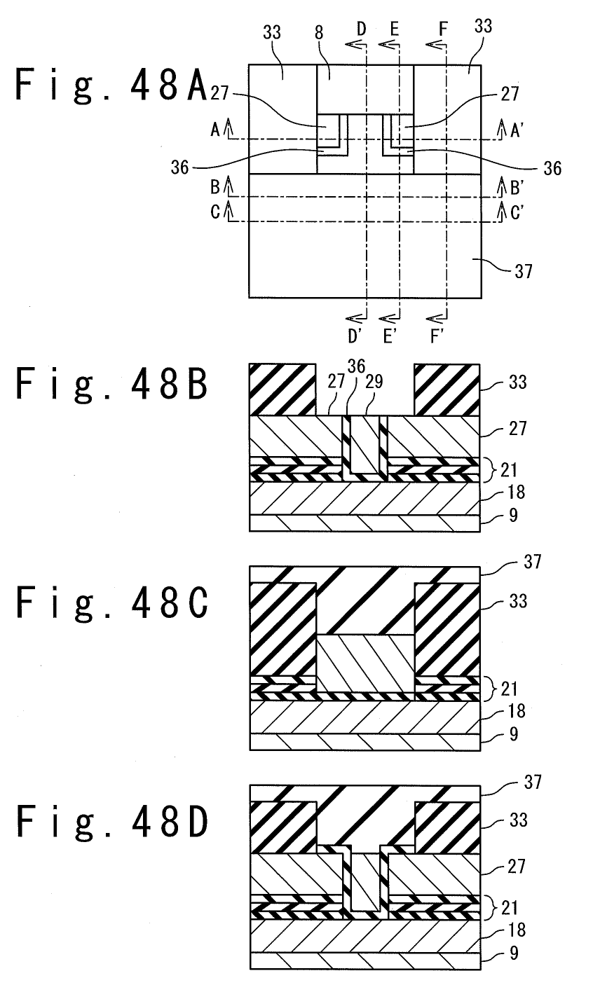

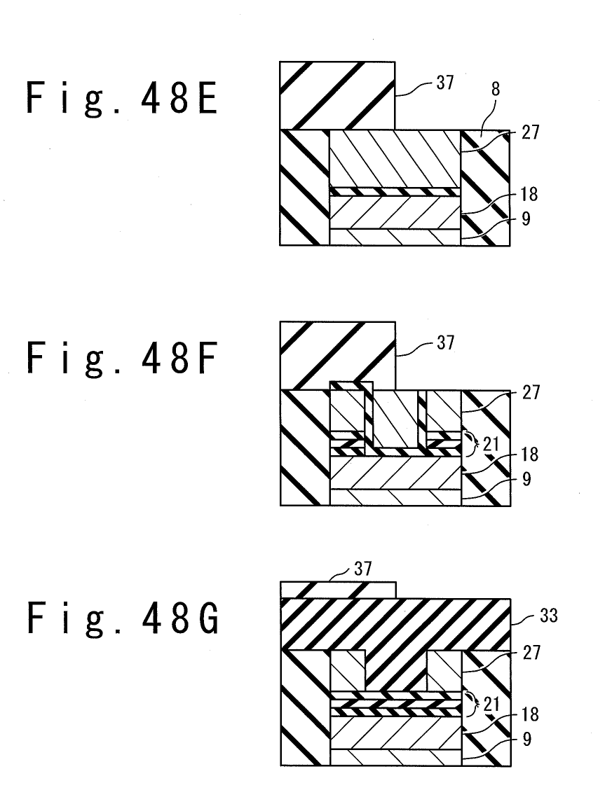

FIGS. 48A to 48G show a state in a fifteenth process for manufacturing the nonvolatile semiconductor memory element 2 according to the second embodiment. FIG. 48A is a plan view showing a structure in the fifteenth process viewed from above. FIG. 48B is a cross sectional view showing the A-A′ cross section in the fifteenth process. FIG. 48C is a cross sectional view showing the B-B′ cross section in the fifteenth process. FIG. 48D is a cross sectional view showing the C-C′ cross section in the fifteenth process. FIG. 48E is a cross sectional view showing the D-D′ cross section in the fifteenth process. FIG. 48F is a cross sectional view showing the E-E′ cross section in the fifteenth process. FIG. 48G is a cross sectional view showing the F-F′ cross section in the fifteenth process.

As shown in FIG. 48A, in the fifteenth process, a photoresist 37 is applied and patterned to form the photoresist 37 which covers half of a region surrounded by the STIs 8 and the nitride films 33. Then, the exposed oxide film 36 is removed by a dry etching method or a wet etching method using hydrofluoric acid.

As shown in FIG. 48B, in the A-A′ cross section in the fifteenth process, the oxide films 36 which covered surfaces of the first polysilicon films 27 are removed. Moreover, as shown in FIGS. 48C and 48D, in the B-B′ cross section and the C-C′ cross section in the fifteenth process, the photoresist 37 which covers the opening portion between the nitride films 33 and surfaces of the nitride films 33 is formed. As shown in FIGS. 48E to 48G, in the D-D′ cross section, the E-E′ cross section and the F-F′ cross section in the fifteenth process, the photoresist 37 covering the half of the materials is formed.

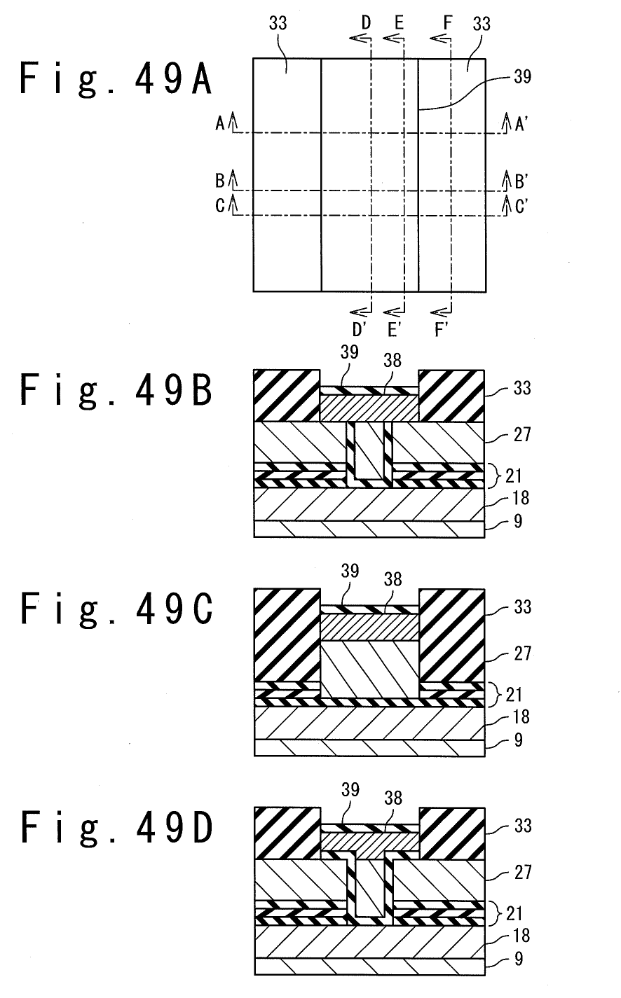

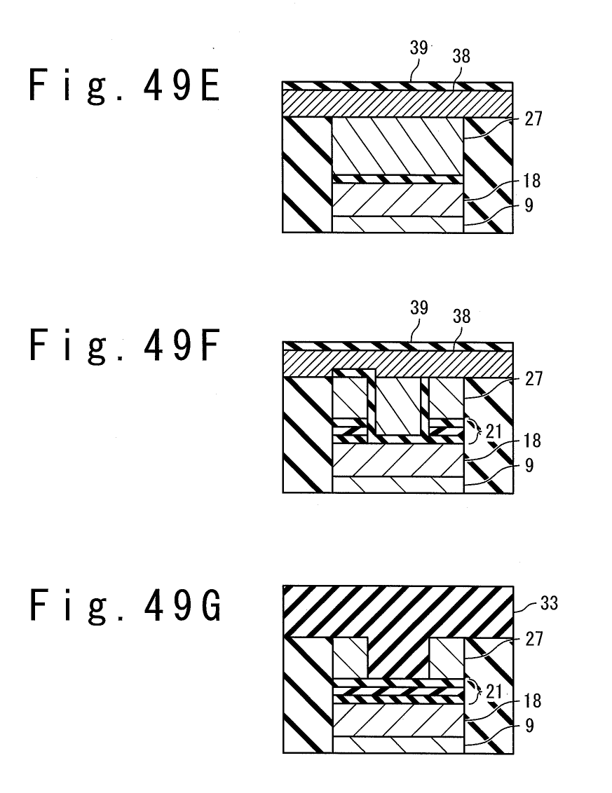

FIGS. 49A to 49G show a state in a sixteenth process for manufacturing the nonvolatile semiconductor memory element 2 according to the second embodiment. FIG. 49A is a plan view showing a structure in the sixteenth process viewed from above. FIG. 49B is a cross sectional view showing the A-A′ cross section in the sixteenth process. FIG. 49C is a cross sectional view showing the B-B′ cross section in the sixteenth process. FIG. 49D is a cross sectional view showing the C-C′ cross section in the sixteenth process. FIG. 49E is a cross sectional view showing the D-D′ cross section in the sixteenth process. FIG. 49F is a cross sectional view showing the E-E′ cross section in the sixteenth process. FIG. 49G is a cross sectional view showing the F-F′ cross section in the sixteenth process.

As shown in FIG. 49A, in the sixteenth process, after the photoresist 37 is removed, an oxide film 39 is formed between the nitride films 33. As shown in FIGS. 49B to 49G, in the sixteenth process, a third polysilicon film 38 with a film thickness of about 100 to 150 nm is blanket deposited by the CVD method or the like. Note that the third polysilicon film 38 may be doped polysilicon that is doped with n-type impurities such as phosphorus and arsenic. Alternatively, after the third polysilicon film 38 is formed, n-type impurities such as phosphorus and arsenic may be injected into the third polysilicon film 38.

After the third polysilicon film 38 is formed, the third polysilicon film 38 is etched back such that a surface of the third polysilicon film 38 is located lower than surfaces of the nitride films 33. After that, the oxide film 39 with a film thickness of about 10 to 150 nm is formed on a surface of the third polysilicon film 38 by a thermal oxidation method or the like.

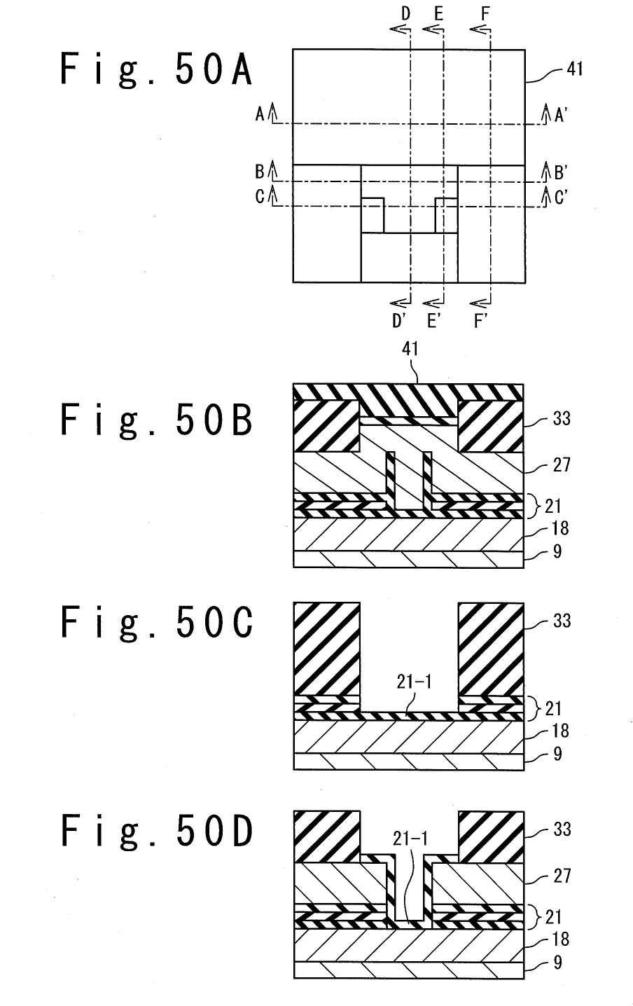

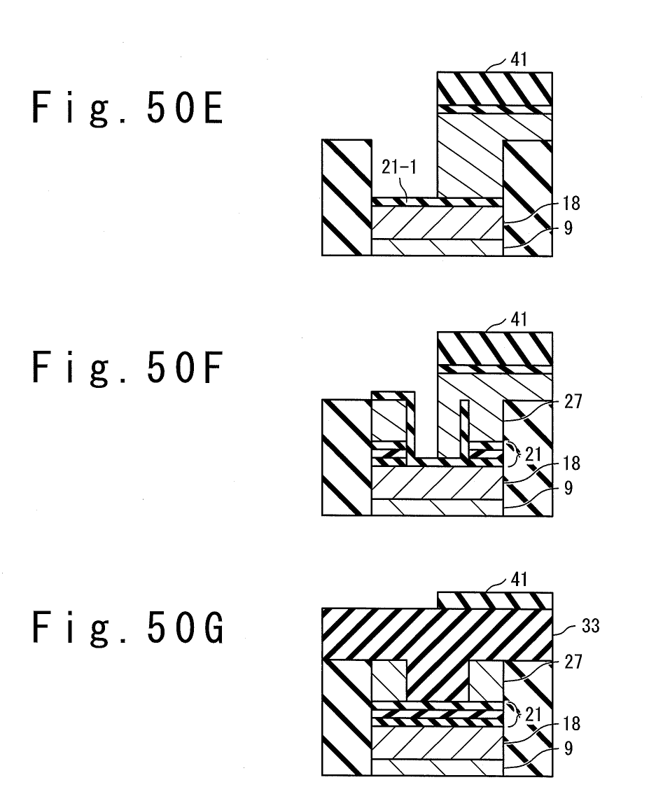

FIGS. 50A to 50G show a state in a seventeenth process for manufacturing the nonvolatile semiconductor memory element 2 according to the second embodiment. FIG. 50A is a plan view showing a structure in the seventeenth process viewed from above. FIG. 50B is a cross sectional view showing the A-A′ cross section in the seventeenth process. FIG. 50C is a cross sectional view showing the B-B′ cross section in the seventeenth process. FIG. 50D is a cross sectional view showing the C-C′ cross section in the seventeenth process. FIG. 50E is a cross sectional view showing the D-D′ cross section in the seventeenth process. FIG. 50F is a cross sectional view showing the E-E′ cross section in the seventeenth process. FIG. 50G is a cross sectional view showing the F-F′ cross section in the seventeenth process.

As shown in FIG. 50A, in the seventeenth process, a photoresist 41 is applied and patterned to form the photoresist 41 such that the region covered by the photoresist 37 in the fifteenth process is exposed. After that, by a dry etching method, the oxide film 39 formed on the third polysilicon film 38 is removed, and subsequently the third polysilicon film 38 is removed.

As shown in FIG. 50B, in the A-A′ cross in the seventeenth process, the photoresist 41 is formed on the oxide film 39. As shown in FIGS. 50C and 50D, in the B-B′ cross section and the C-C′ cross section, the oxide film 39 which is not covered by the photoresist 41 is removed and then the third polysilicon film 38 is removed. As a result, a surface of the bottom insulating film 21-1 is exposed.

As shown in FIGS. 50E to 50G, in the D-D′ cross section, the E-E′ cross section and the F-F′ cross section in the seventeenth process, the photoresist 41 masks about half of a region of the material. In the D-D′ cross section and the E-E′ cross section, the oxide film 39 and the third polysilicon film 38 which are not covered by the photoresist 41 are removed.

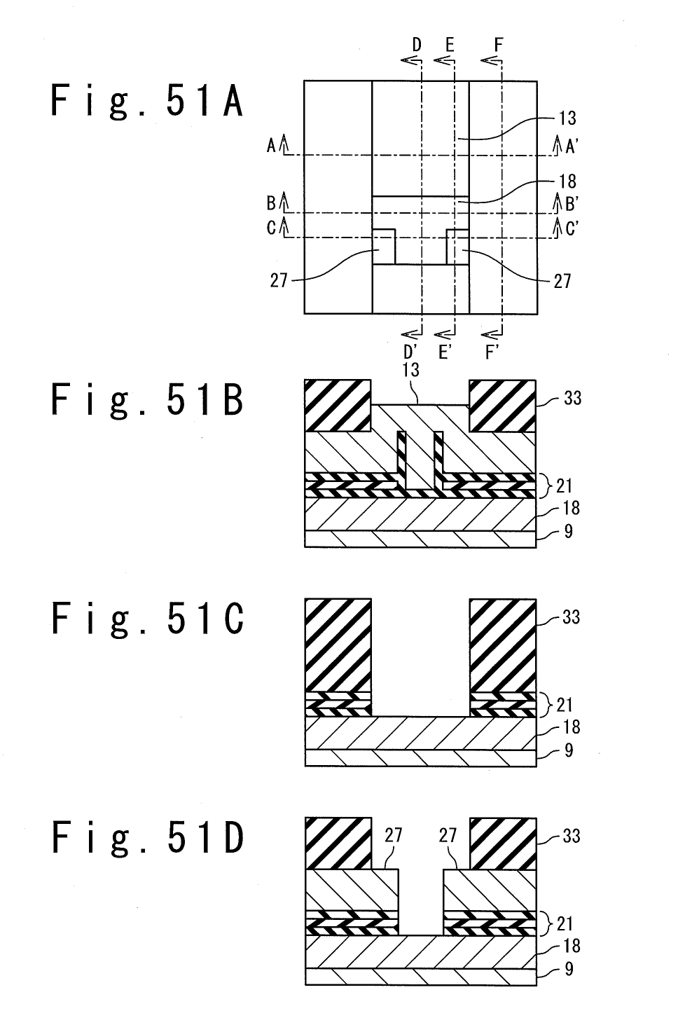

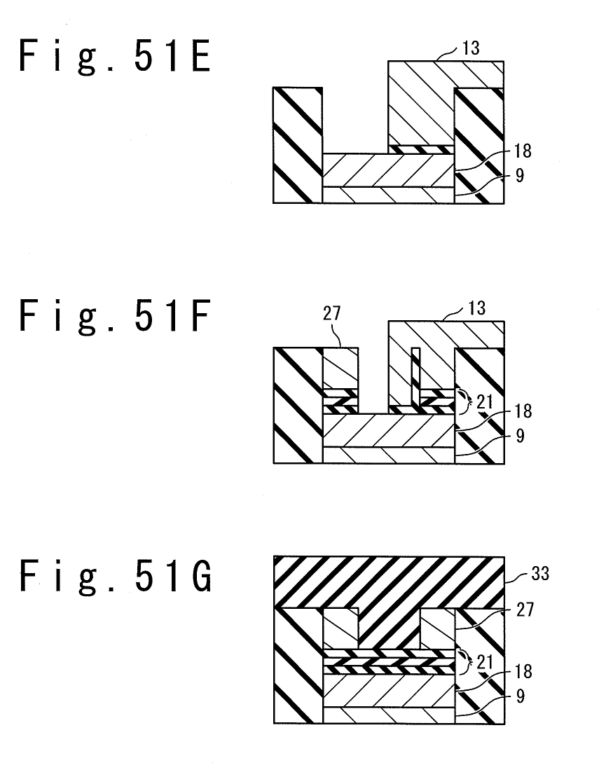

FIGS. 51A to 51G show a state in an eighteenth process for manufacturing the nonvolatile semiconductor memory element 2 according to the second embodiment. FIG. 51A is a plan view showing a structure in the eighteenth process viewed from above. FIG. 51B is a cross sectional view showing the A-A′ cross section in the eighteenth process. FIG. 51C is a cross sectional view showing the B-B′ cross section in the eighteenth process. FIG. 51D is a cross sectional view showing the C-C′ cross section in the eighteenth process. FIG. 51E is a cross sectional view showing the D-D′ cross section in the eighteenth process. FIG. 51F is a cross sectional view showing the E-E′ cross section in the eighteenth process. FIG. 51G is a cross sectional view showing the F-F′ cross section in the eighteenth process.

As shown in FIG. 51A, in the eighteenth process, the photoresist 41 is peeled off. Then, a wet etching is carried out by using hydrofluoric acid to remove the oxide film 39 on the third polysilicon film 38 and the exposed oxide film 36 (bottom insulating film 21-1). The remaining third polysilicon film 38 and the first polysilicon film 27 are integrated to function as the first word gate 13. Therefore, those polysilicon films are referred to as the first word gate 13 hereinafter.

As shown in FIG. 51B, in the A-A′ cross section in the eighteenth process, the oxide film 39 on the third polysilicon film 38 (first word gate 13) is removed. As shown in FIGS. 51C and 51D, in the B-B′ cross section and the C-C′ cross section in the eighteenth process, the oxide films (i.e. the oxide film 36 and the bottom insulating film 21-1) on the P well 18 are removed and thereby a surface of the P well 18 is exposed.

As shown in FIGS. 51E and 51F, in the D-D′ cross section and the E-E′ cross section in the eighteenth process, the oxide film 39 on the third polysilicon film 38 (first word gate 13) and the oxide films (i.e. the oxide film 36 and the bottom insulating film 21-1) on the P well 18 are removed and thereby a surface of the P well 18 is exposed.

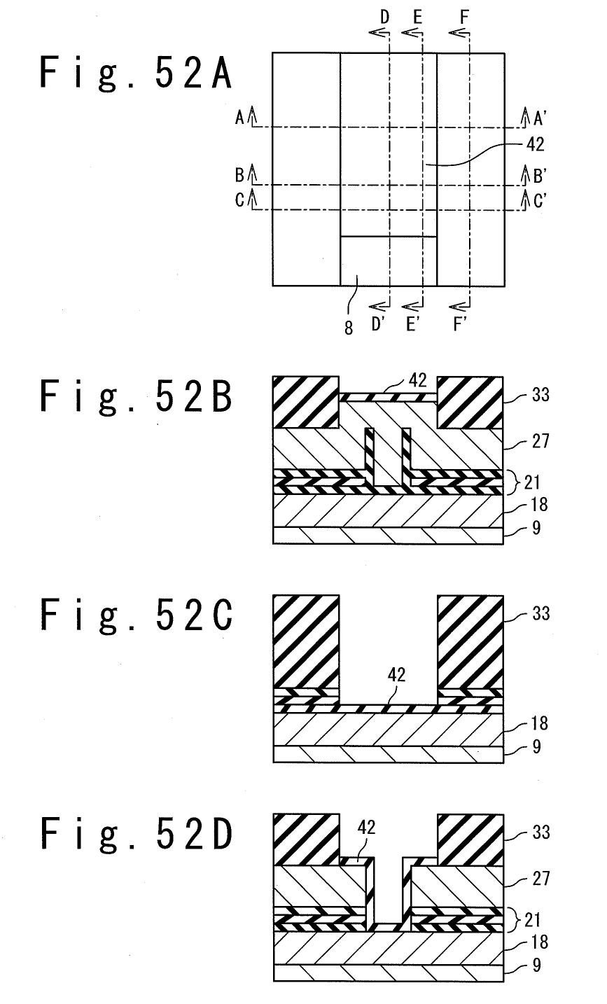

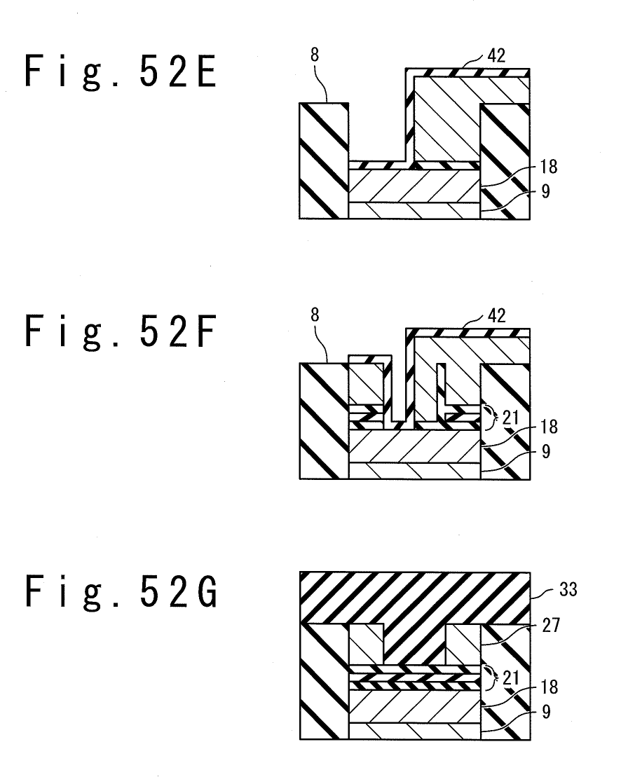

FIGS. 52A to 52G show a state in a nineteenth process for manufacturing the nonvolatile semiconductor memory element 2 according to the second embodiment. FIG. 52A is a plan view showing a structure in the nineteenth process viewed from above. FIG. 52B is a cross sectional view showing the A-A′ cross section in the nineteenth process. FIG. 52C is a cross sectional view showing the B-B′ cross section in the nineteenth process. FIG. 52D is a cross sectional view showing the C-C′ cross section in the nineteenth process. FIG. 52E is a cross sectional view showing the D-D′ cross section in the nineteenth process. FIG. 52F is a cross sectional view showing the E-E′ cross section in the nineteenth process. FIG. 52G is a cross sectional view showing the F-F′ cross section in the nineteenth process.

As shown in FIGS. 52A to 52F, in the nineteenth process, an oxide film 42 is formed between the nitride films 33. In the nineteenth process, the thermal oxidization method or the like is used for oxidizing a surface of the P well 18, a surface and a side surface of the first word gate 13, and surfaces and side surfaces of the first polysilicon films 27. At this time, it is preferable that a photoresist with a film thickness of about 3 to 6 nm is formed on the P well 18 and a photoresist with a film thickness of about 10 to 15 nm is formed on surfaces of the first word gate 13 and the first polysilicon films 27.

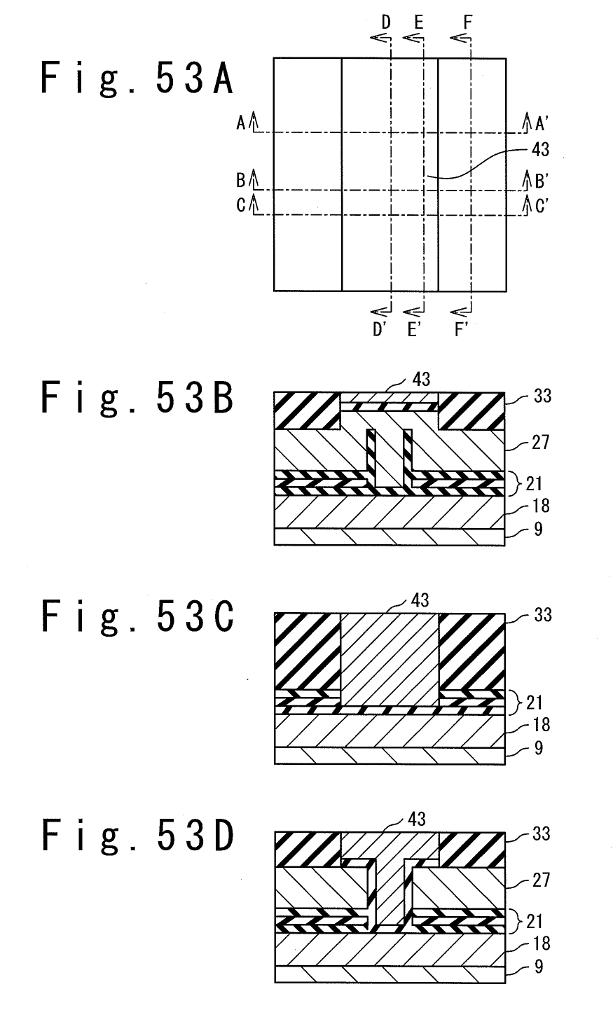

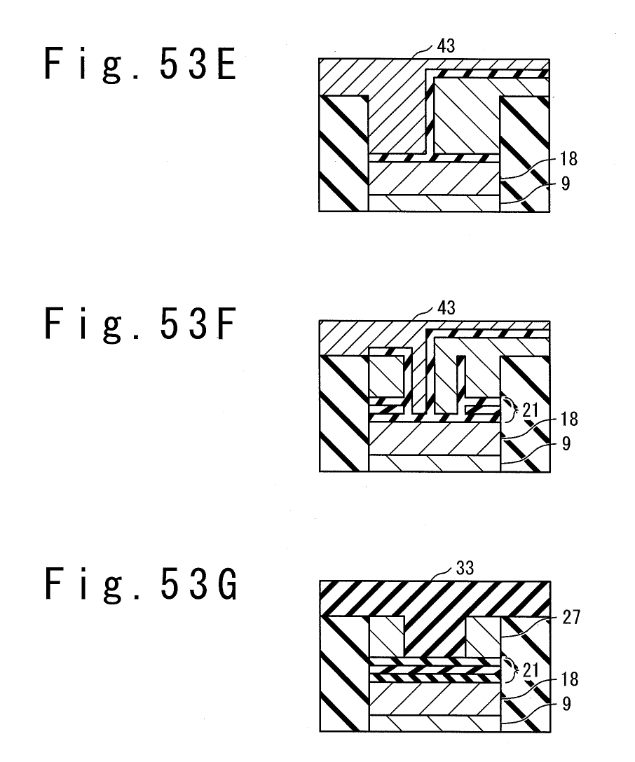

FIGS. 53A to 53G show a state in a twentieth process for manufacturing the nonvolatile semiconductor memory element 2 according to the second embodiment. FIG. 53A is a plan view showing a structure in the twentieth process viewed from above. FIG. 53B is a cross sectional view showing the A-A′ cross section in the twentieth process. FIG. 53C is a cross sectional view showing the B-B′ cross section in the twentieth process. FIG. 53D is a cross sectional view showing the C-C′ cross section in the twentieth process. FIG. 53E is a cross sectional view showing the D-D′ cross section in the twentieth process. FIG. 53F is a cross sectional view showing the E-E′ cross section in the twentieth process. FIG. 53G is a cross sectional view showing the F-F′ cross section in the twentieth process.

As shown in FIGS. 53A to 53F, in the twentieth process, the opening portion formed between the nitride films 33 is filled with a fourth polysilicon film 43. For example, the fourth polysilicon film 43 with a film thickness of about 200 to 300 nm is blanket deposited, and then the CMP is performed until surfaces of the nitride films 33 are exposed. As a result, the opening portion formed between the nitride films 33 is filled with the fourth polysilicon film 43.

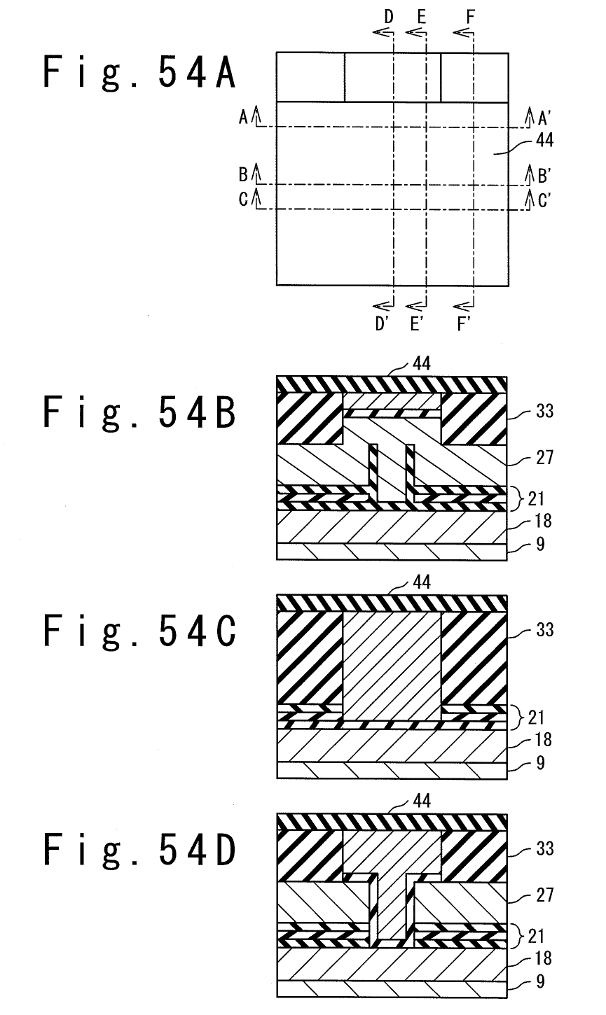

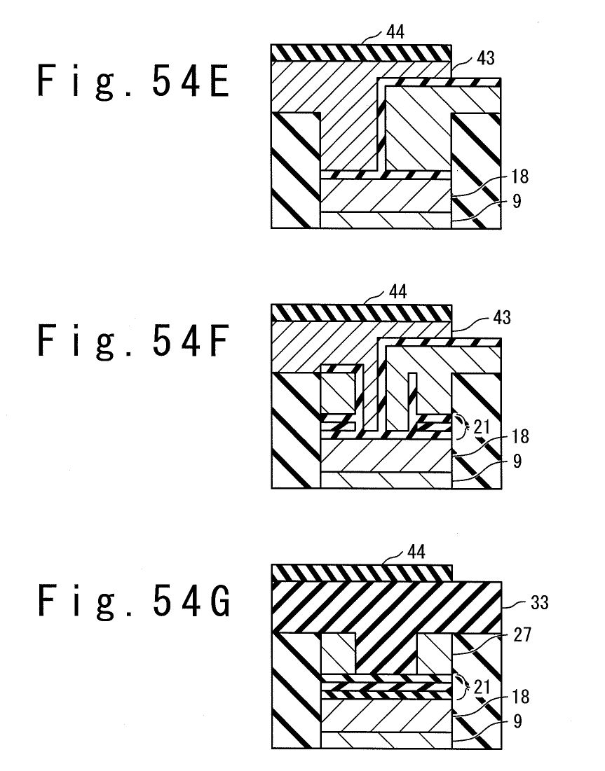

FIGS. 54A to 54G show a state in a twenty-first process for manufacturing the nonvolatile semiconductor memory element 2 according to the second embodiment. FIG. 54A is a plan view showing a structure in the twenty-first process viewed from above. FIG. 54B is a cross sectional view showing the A-A′ cross section in the twenty-first process. FIG. 54C is a cross sectional view showing the B-B′ cross section in the twenty-first process. FIG. 54D is a cross sectional view showing the C-C′ cross section in the twenty-first process. FIG. 54E is a cross sectional view showing the D-D′ cross section in the twenty-first process. FIG. 54F is a cross sectional view showing the E-E′ cross section in the twenty-first process. FIG. 54G is a cross sectional view showing the F-F′ cross section in the twenty-first process.

As shown in FIG. 54A, in the twenty-first process, a photoresist 44 is applied and patterned to form the photoresist 44 that overlaps with the first word gate 13. The fourth polysilicon film 43 is removed by a dry etching method using the photoresist 44 as a mask.

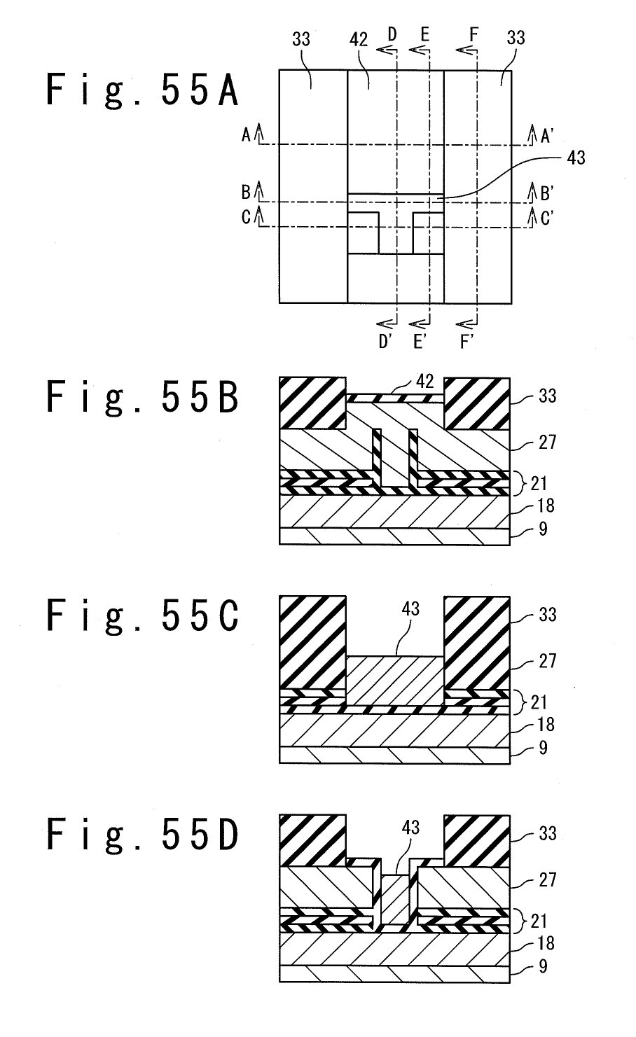

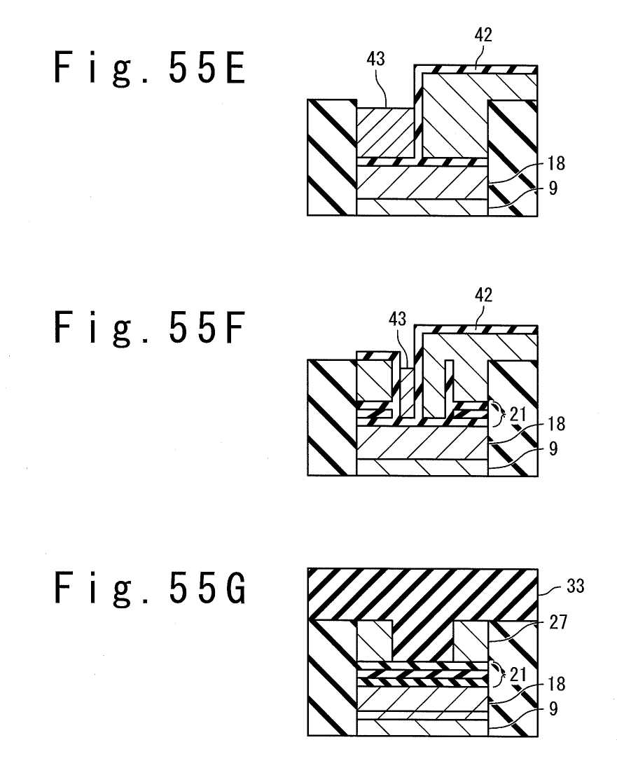

FIGS. 55A to 55G show a state in a twenty-second process for manufacturing the nonvolatile semiconductor memory element 2 according to the second embodiment. FIG. 55A is a plan view showing a structure in the twenty-second process viewed from above. FIG. 55B is a cross sectional view showing the A-A′ cross section in the twenty-second process. FIG. 55C is a cross sectional view showing the B-B′ cross section in the twenty-second process. FIG. 55D is a cross sectional view showing the C-C′ cross section in the twenty-second process. FIG. 55E is a cross sectional view showing the D-D′ cross section in the twenty-second process. FIG. 55F is a cross sectional view showing the E-E′ cross section in the twenty-second process. FIG. 55G is a cross sectional view showing the F-F′ cross section in the twenty-second process.

As shown in FIG. 55A, in the twenty-second process, after the photoresist 44 is peeled off, the fourth polysilicon film 43 is etched back and thereby the oxide film 36 on the first polysilicon film 27 is exposed. The polysilicon is filled in a trench portion between a side of the first word gate 13 and the STI 8 by the etching-back.

As shown in FIG. 55B, in the A-A′ cross section in the twenty-second process, the fourth polysilicon film 43 is removed and the oxide film 42 is exposed. Moreover, as shown in FIG. 55C, in the B-B′ cross section in the twenty-second process, the fourth polysilicon film 43 is filled in a space between the nitride films 33. As shown in FIG. 55D, in the C-C′ cross section in the twenty-second process, the fourth polysilicon film 43 is filled in a space lateral to the first polysilicon film 27.

As shown in FIG. 55E, in the D-D′ cross section in the twenty-second process, the fourth polysilicon film 43 is formed between the STI 8 and the oxide film 42 on the side surface of the first word gate 13. As shown in FIG. 55F, in the E-E′ cross section in the twenty-second process, the fourth polysilicon film 43 is filled in a space between the oxide film 42 on the side surface of the first word gate 13 and the oxide film 36 on the side surface of the first polysilicon film 27.

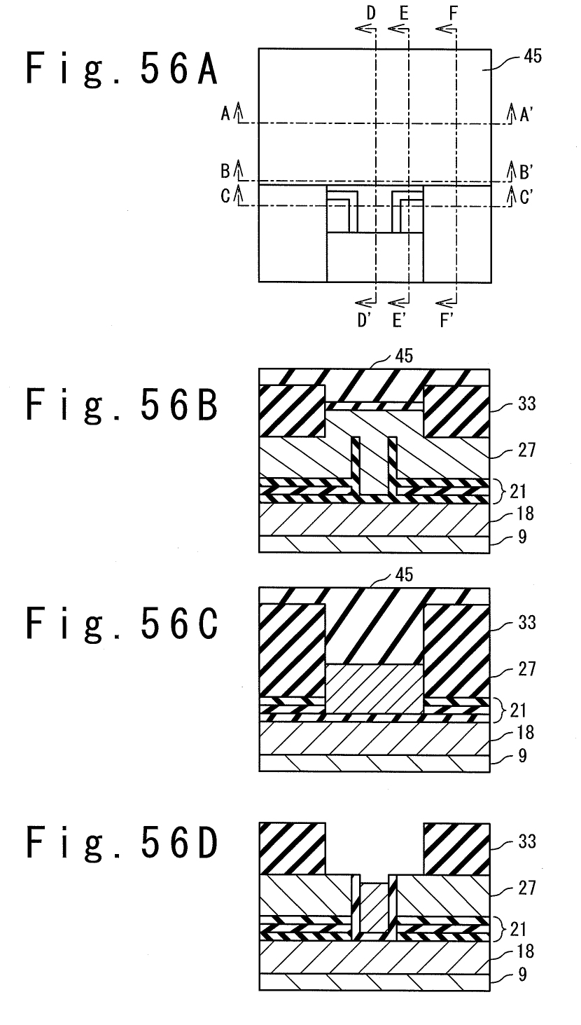

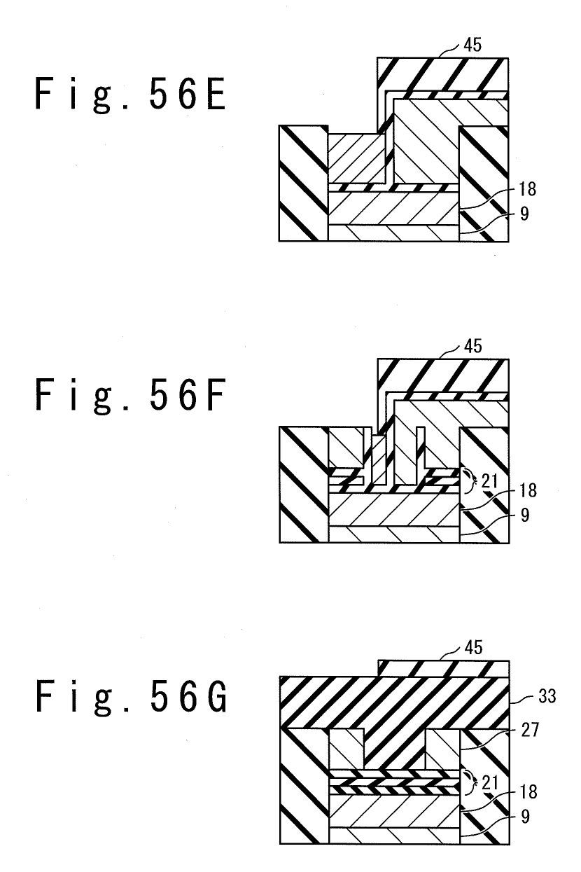

FIGS. 56A to 56G show a state in a twenty-third process for manufacturing the nonvolatile semiconductor memory element 2 according to the second embodiment. FIG. 56A is a plan view showing a structure in the twenty-third process viewed from above. FIG. 56B is a cross sectional view showing the A-A′ cross section in the twenty-third process. FIG. 56C is a cross sectional view showing the B-B′ cross section in the twenty-third process. FIG. 56D is a cross sectional view showing the C-C′ cross section in the twenty-third process. FIG. 56E is a cross sectional view showing the D-D′ cross section in the twenty-third process. FIG. 56F is a cross sectional view showing the E-E′ cross section in the twenty-third process. FIG. 56G is a cross sectional view showing the F-F′ cross section in the twenty-third process.

As shown in FIG. 56A, in the twenty-third process, a resist is applied and patterning of it is performed. Thereby, a photoresist 45 is formed such that the oxide film 42 is covered while the oxide film 36 on the first polysilicon film 27 is exposed. Then, the oxide film 36 on the top surface of the first polysilicon film 27 is removed by a wet etching method using hydrofluoric acid or the like.

As shown in FIGS. 56B and 56C, in the A-A′ cross section in the twenty-third process, a surface of the oxide film 42 is covered by the photoresist 45. In the B-B′ cross section, a top surface of the fourth polysilicon film 43 is covered by the photoresist 45. As shown in FIG. 56D, in the C-C′ cross section in the twenty-third process, the oxide films 36 on the first polysilicon films 27 are removed. As a result, surfaces of the first polysilicon film 27 and the fourth polysilicon film 43 are exposed.

As shown in FIG. 56E, in the twenty-third process, the photoresist 45 covers the exposed top surface and side surface of the oxide film 42. At this time, in the D-D′ cross section, the photoresist 45 is formed to mask a part of the surface of the fourth polysilicon film 43. As shown in FIG. 56F, in the twenty-third process, the oxide film 36 which is formed on the first polysilicon film 27 and not covered by the photoresist 45 is removed. As a result, a surface of the first polysilicon film 27 is exposed.

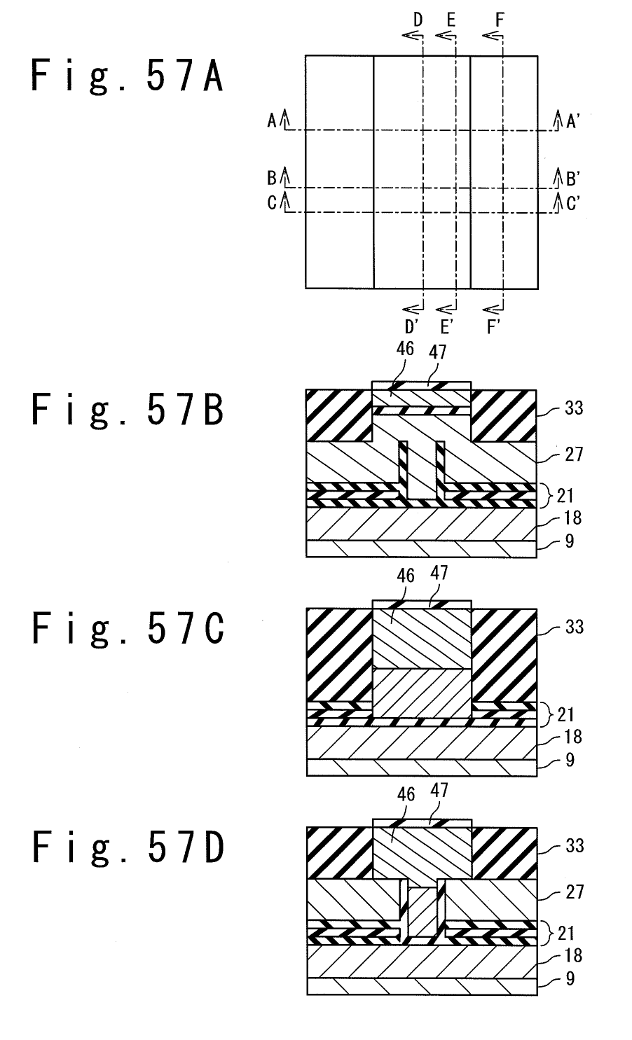

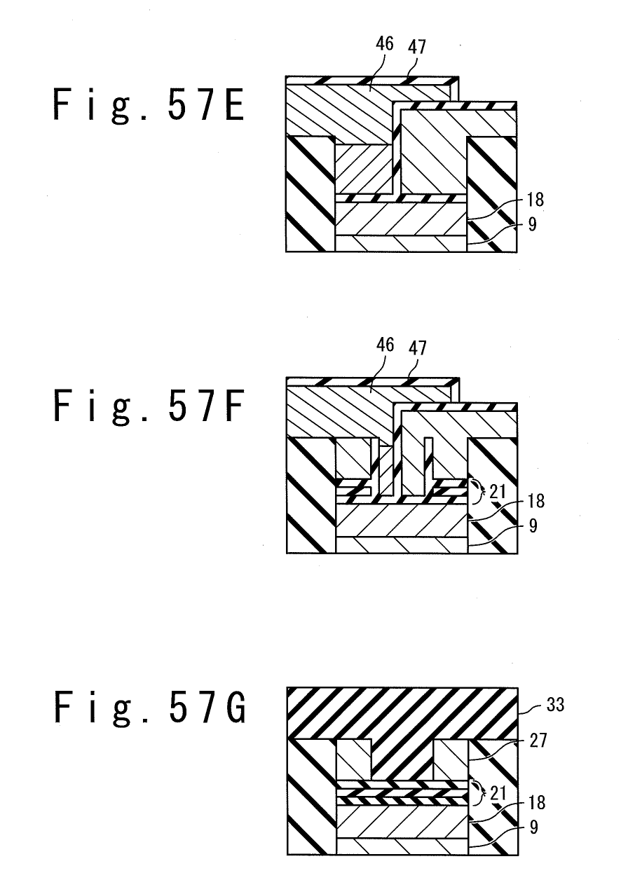

FIGS. 57A to 57G show a state in a twenty-fourth process for manufacturing the nonvolatile semiconductor memory element 2 according to the second embodiment. FIG. 57A is a plan view showing a structure in the twenty-fourth process viewed from above. FIG. 57B is a cross sectional view showing the A-A′ cross section in the twenty-fourth process. FIG. 57C is a cross sectional view showing the B-B′ cross section in the twenty-fourth process. FIG. 57D is a cross sectional view showing the C-C′ cross section in the twenty-fourth process. FIG. 57E is a cross sectional view showing the D-D′ cross section in the twenty-fourth process. FIG. 57F is a cross sectional view showing the E-E′ cross section in the twenty-fourth process. FIG. 57G is a cross sectional view showing the F-F′ cross section in the twenty-fourth process.

As shown in FIG. 57A, in the twenty-fourth process, an oxide film 47 is formed between the nitride films 33. As shown in FIGS. 57B to 57F, in the twenty-fourth process, after the photoresist 45 is peeled off, a fifth polysilicon film 46 with a film thickness of about 100 to 150 nm is blanket deposited. The fifth polysilicon film 46 may be doped polysilicon that is doped with n-type impurities such as phosphorus and arsenic. Alternatively, after the fifth polysilicon film 46 is formed, n-type impurities such as phosphorus and arsenic may be injected into the fifth polysilicon film 46.

After that, a photoresist is applied on the fifth polysilicon film 46 and patterning of it is carried out to form a resist pattern (not shown). By using the resist pattern as a mask, the fifth polysilicon film 46 is removed by a dry etching. Then, the oxide film 47 with a thickness of about 10 to 15 nm is formed on a surface of the fifth polysilicon film 46 by the thermal oxidization method.

As shown in FIGS. 57E and 57F, it is preferable that the resist pattern is so formed as to cover the surface of the first polysilicon film 27 and the surface of the fourth polysilicon film 43 which are exposed in the twenty-third process and the fifth polysilicon film 46.

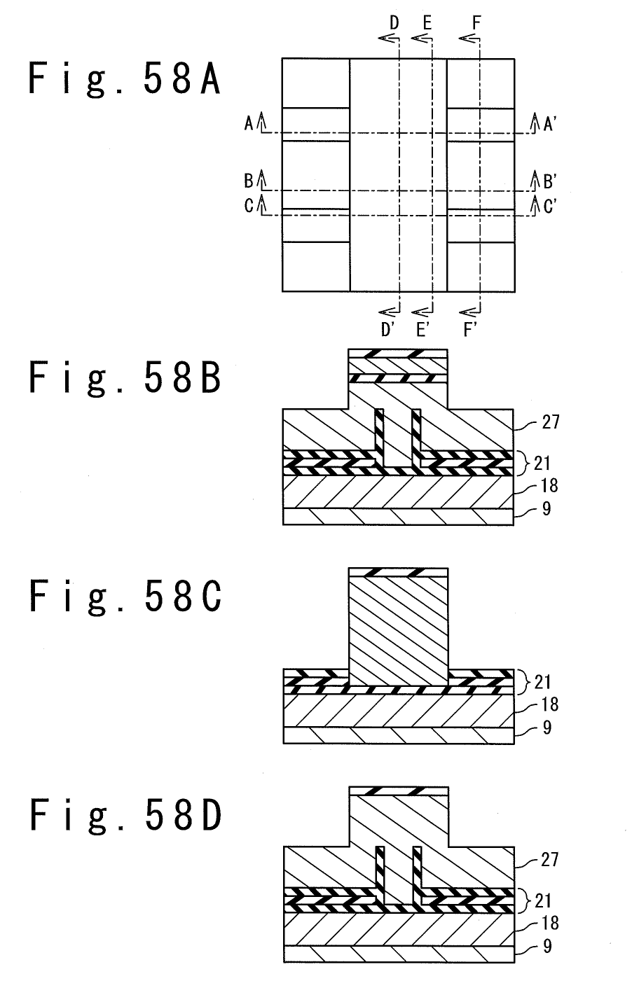

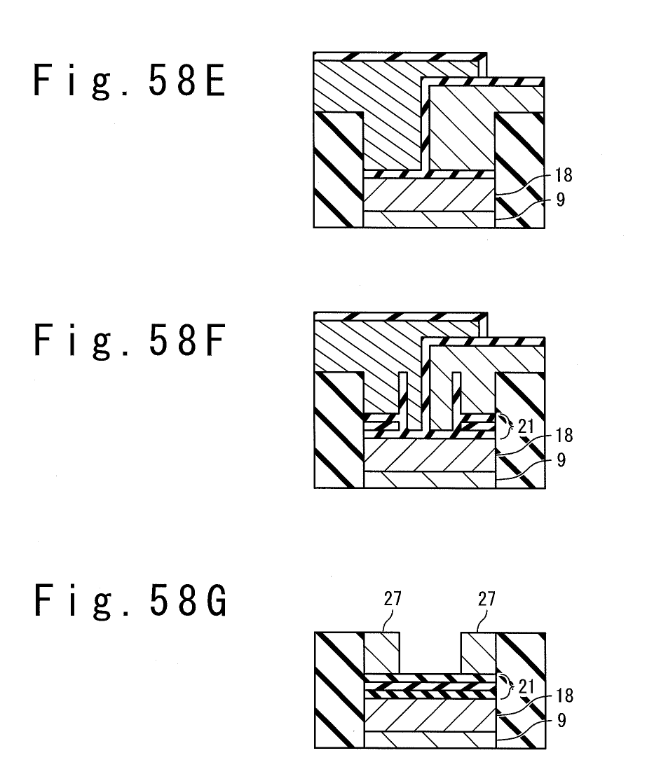

FIGS. 58A to 58G show a state in a twenty-fifth process for manufacturing the nonvolatile semiconductor memory element 2 according to the second embodiment. FIG. 58A is a plan view showing a structure in the twenty-fifth process viewed from above. FIG. 58B is a cross sectional view showing the A-A′ cross section in the twenty-fifth process. FIG. 58C is a cross sectional view showing the B-B′ cross section in the twenty-fifth process. FIG. 58D is a cross sectional view showing the C-C′ cross section in the twenty-fifth process. FIG. 58E is a cross sectional view showing the D-D′ cross section in the twenty-fifth process. FIG. 58F is a cross sectional view showing the E-E′ cross section in the twenty-fifth process. FIG. 58G is a cross sectional view showing the F-F′ cross section in the twenty-fifth process.

As shown in FIG. 58A, in the twenty-fifth process, wet etching using phosphoric acid or the like is carried out to remove the nitride films 33. As shown in FIGS. 58B and 58D, in the A-A′ cross section and the C-C′ cross section in the twenty-fifth process, the nitride film 33 is removed and thereby a surface of the first polysilicon film 27 covered by the nitride films 33 is exposed. Moreover, as shown in FIG. 58C, in the B-B′ cross section, the nitride film 33 is removed and thereby the charge storage layer 21 covered by the nitride films 33 is exposed. As shown in FIG. 58G, in the F-F′ cross section in the twenty-fifth process, the first polysilicon film 27 and the charge storage layer 21 (the top insulating film 21-3) covered by the nitride film 33 are exposed.

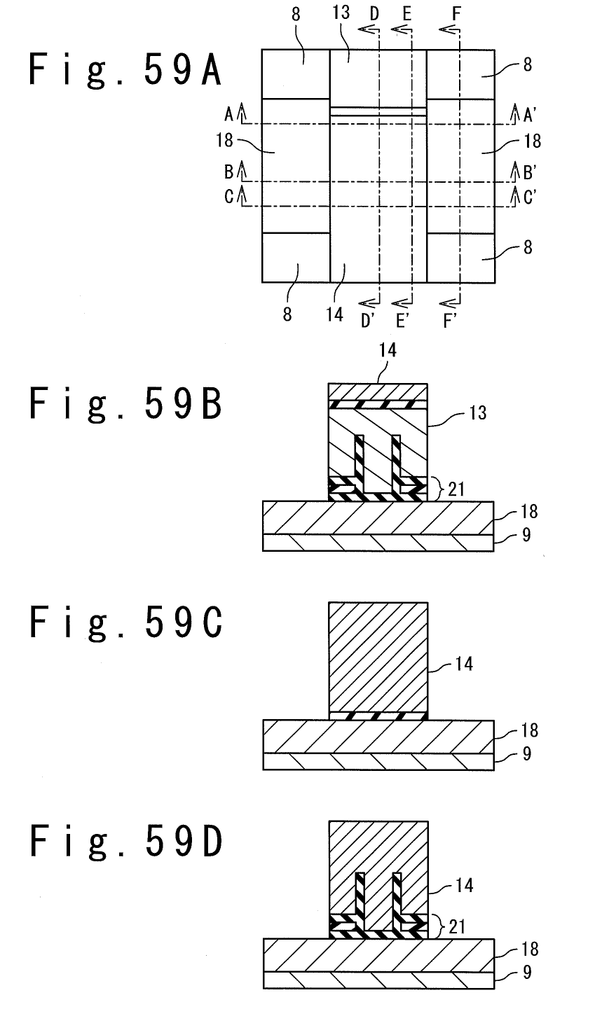

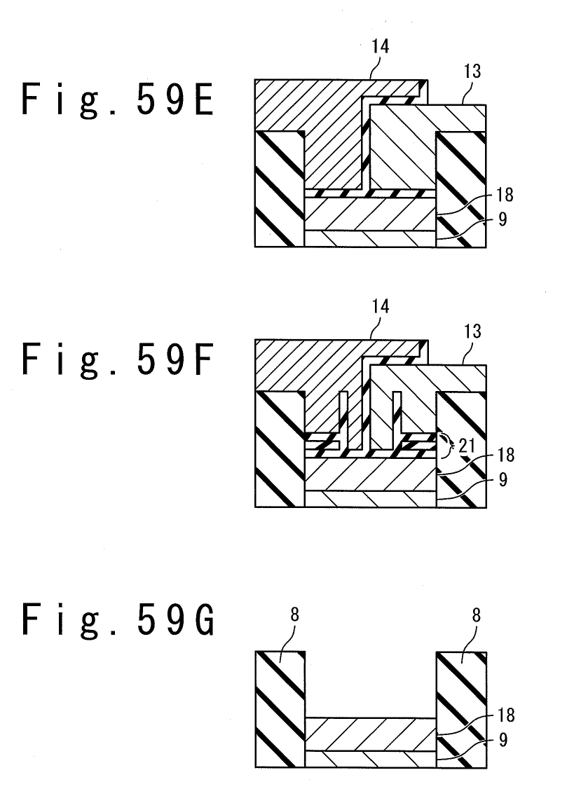

FIGS. 59A to 59G show a state in a twenty-sixth process for manufacturing the nonvolatile semiconductor memory element 2 according to the second embodiment. FIG. 59A is a plan view showing a structure in the twenty-sixth process viewed from above. FIG. 59B is a cross sectional view showing the A-A′ cross section in the twenty-sixth process. FIG. 59C is a cross sectional view showing the B-B′ cross section in the twenty-sixth process. FIG. 59D is a cross sectional view showing the C-C′ cross section in the twenty-sixth process. FIG. 59E is a cross sectional view showing the D-D′ cross section in the twenty-sixth process. FIG. 59F is a cross sectional view showing the E-E′ cross section in the twenty-sixth process. FIG. 59G is a cross sectional view showing the F-F′ cross section in the twenty-sixth process.

As shown in FIG. 59A, in the twenty-sixth process, the exposed first polysilicon film 27 and the oxide film 47 are removed.

As shown in FIGS. 59B and 59D, in the A-A′ cross section and the C-C′ cross section, the exposed first polysilicon film 27 is selectively removed by a dry etching by using the oxide film 47 formed on the fifth polysilicon film 46 as a mask. Moreover, as shown in FIGS. 59B to 59D, in the twenty-sixth process, after the first polysilicon film 27 is removed by the etching, the charge storage layer 21 is removed by a dry etching. At this time, the oxide film 47 on the fifth polysilicon film 46 also is removed simultaneously.

As shown in FIG. 59G, in the F-F′ cross section in the twenty-sixth process, the exposed first polysilicon film 27 is removed. After the first polysilicon film 27 is removed by the etching, the charge storage layer 21 is removed by a dry etching. Moreover, as shown in FIGS. 59E and 59F, when the charge storage layer 21 is removed, the oxide film 47 formed on the fifth polysilicon film 46 also is removed simultaneously.

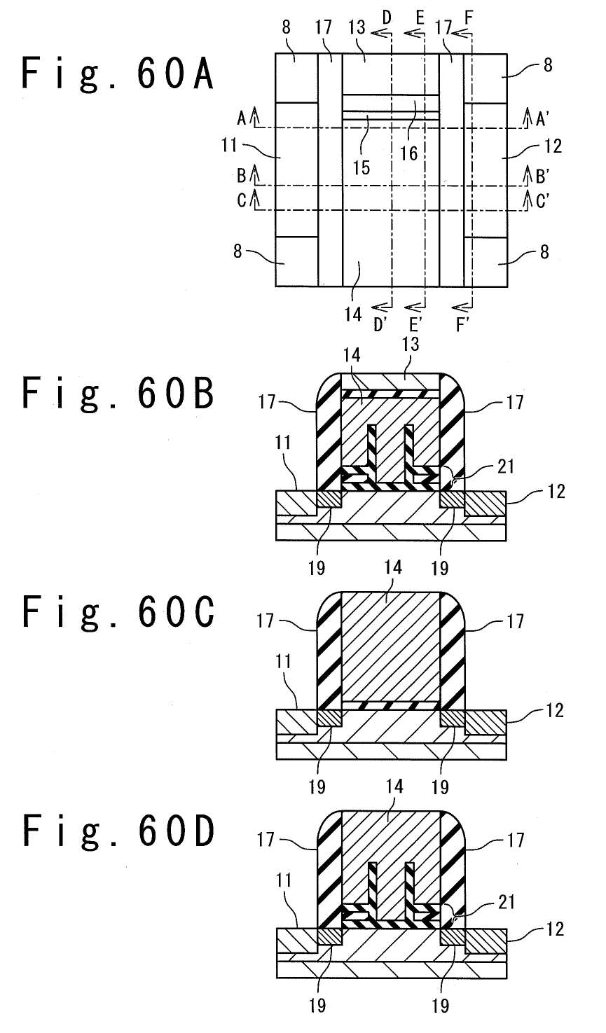

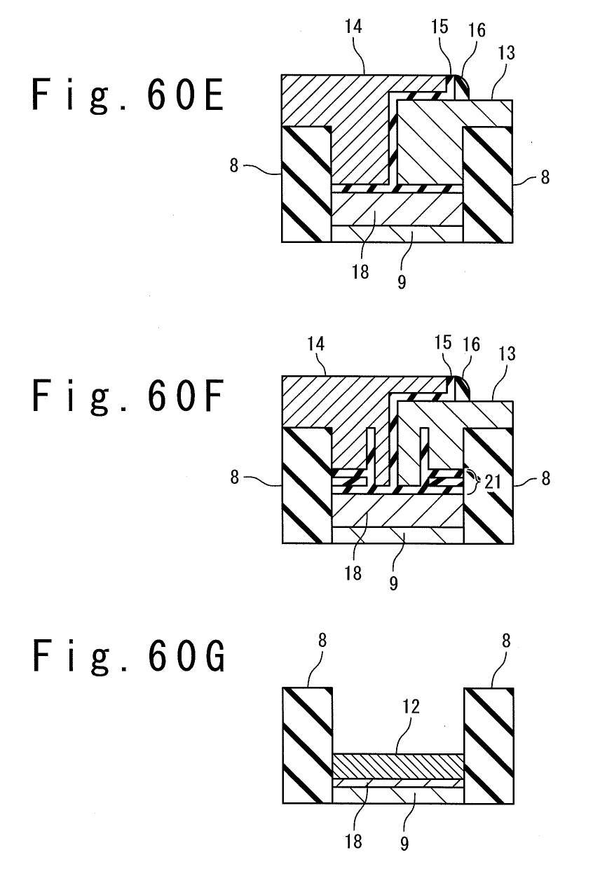

FIGS. 60A to 60G show a state in a twenty-seventh process for manufacturing the nonvolatile semiconductor memory element 2 according to the second embodiment. FIG. 60A is a plan view showing a structure in the twenty-seventh process viewed from above. FIG. 60B is a cross sectional view showing the A-A′ cross section in the twenty-seventh process. FIG. 60C is a cross sectional view showing the B-B′ cross section in the twenty-seventh process. FIG. 60D is a cross sectional view showing the C-C′ cross section in the twenty-seventh process. FIG. 60E is a cross sectional view showing the D-D′ cross section in the twenty-seventh process. FIG. 60F is a cross sectional view showing the E-E′ cross section in the twenty-seventh process. FIG. 60G is a cross sectional view showing the F-F′ cross section in the twenty-seventh process.

As shown in FIG. 60A, in the twenty-seventh process, the first source/drain region 11, the second source/drain region 12, the side wall 16 and the side walls 17 are formed.

As shown in FIGS. 60B to 60D, in the twenty-seventh process, by using the formed gate structure as a mask, n-type impurities such as arsenic and phosphorus are injected into the P well 18 with a degree of about 3e15/cm to form the LDD structure 19. Then, an oxide film with a film thickness of about 100 nm is deposited and the oxide film is etched back to form the side wall 16 and the side walls 17. Next, n-type impurities such as arsenic and phosphorus are injected into the entire surface with a degree of about 5e15/cm to form the first source/drain region 11 and the second source/drain region 12.

After that, an interlayer insulating film is formed, and a contact and an interconnect layer are formed. In this manner, a memory cell in which the ONO film serving as a trap layer is formed only in a portion adjacent to the first source/drain region 11 and the second source/drain region 12 and two gates are formed on the channel region is completed.

### Third Embodiment

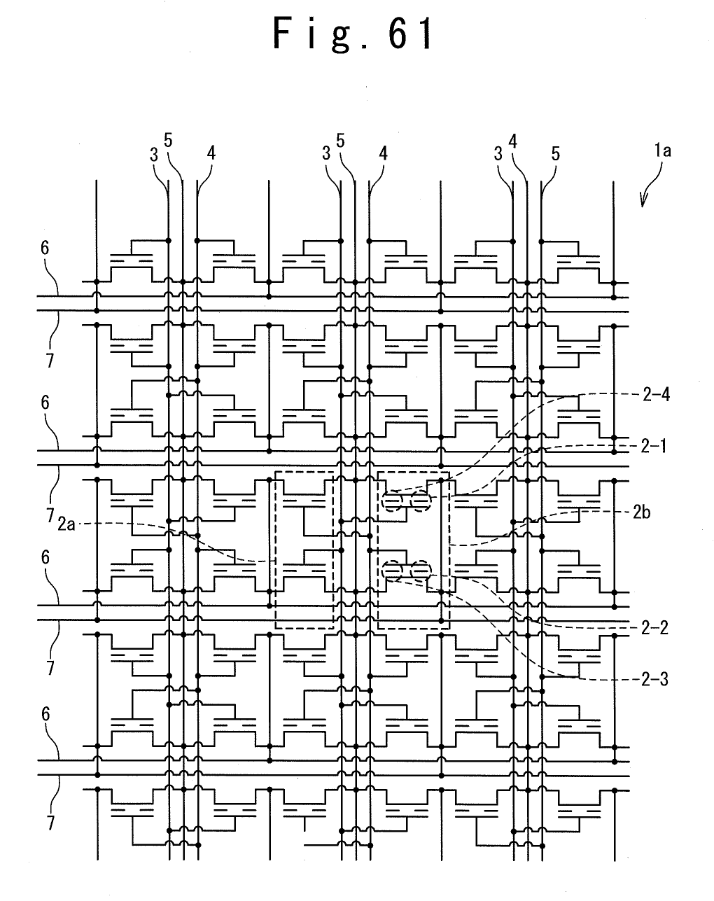

A third embodiment of the present invention will be described below with reference to drawings. FIG. 61 is an equivalent circuit diagram showing a configuration example of a memory array 1a having the nonvolatile semiconductor memory elements 2. The memory cell array 1a includes a plurality of nonvolatile semiconductor memory elements 2 arranged in an array form. The memory cell array 1a according to the present embodiment further includes the first word line 3, the second word line 4, the source line 5, the first bit line 6 and the second bit line 7.

As shown in FIG. 61, the source line 5 is shared by two adjacent memory cells (i.e. first memory cell 2a and second memory cell 2b) in the memory cell array 1a. A drain of the first memory cell 2a is connected to the first bit line 6, and a drain of the second memory cell 2b is connected to the second bit line 7. When data is written to the first memory cell 2a, a predetermined voltage is applied to the second bit line 7 to prevent data writing to the second memory cell 2b. On the other hand, when data is written to the second memory cell 2b, a predetermined voltage is applied to the first bit line 6 to prevent data writing to the first memory cell 2a.

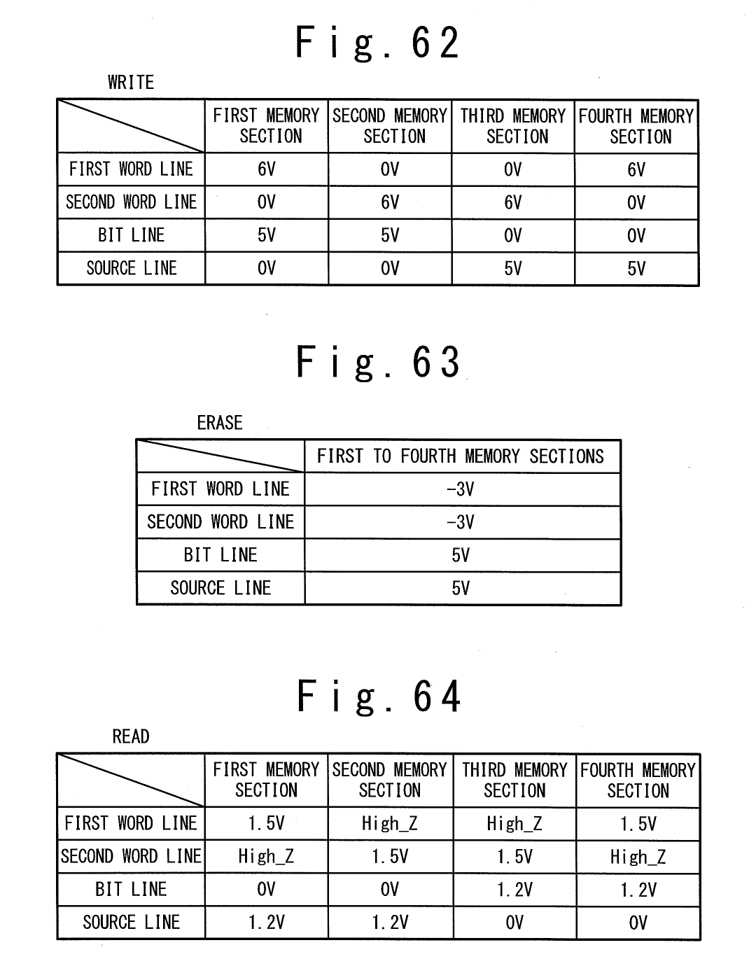

FIG. 62 is a table showing an operation of writing data to the nonvolatile semiconductor memory element 2. As an example, data writing to the first memory cell 2a is shown in FIG. 62. When data is written to the first memory section 2-1 or the second memory section 2-2, a voltage of 0 V is applied to the source line 5 and a voltage of 5 V is applied to the first bit line 6. A write voltage of 6 V is applied to one of the first word line 3 and the second word line 4, and a voltage of 0 V is applied to the other one. Thus, the data writing to the first memory section 2-1 or the second memory section 2-2 is achieved. Similarly, when data is written to the third memory section 2-3 or the fourth memory section 2-4, a voltage of 0 V is applied to the first bit line 6 and a voltage of 5 V is applied to the source line 5. A write voltage of 6 V is applied to one of the first word line 3 and the second word line 4, and a voltage of 0 V is applied to the other one. Thus, the data writing to the third memory section 2-3 or the fourth memory section 2-4 is achieved.

FIG. 63 is a table showing an operation of erasing data from the nonvolatile semiconductor memory element 2. As shown in FIG. 63, when data stored in the nonvolatile semiconductor memory element 2 is erased, a voltage of −3 V is applied to the first word line 3 and the second word line 4 and a voltage of 5 V is applied to the source line 5 and the first bit line 6 (or the second bit line 7).

FIG. 64 is a table showing an operation of reading data stored in the nonvolatile semiconductor memory element 2. As shown in FIG. 64, when data stored in the first memory section 2-1 or the second memory section 2-2 is read, a voltage of 0 V is applied to the first bit line 6 and a voltage of 1.2 V is applied to the source line 5. A read voltage of 1.5 V is applied to one of the first word line 3 and the second word line 4, and the other one is set to high impedance state. Thus, data reading from the first memory section 2-1 or the second memory section 2-2 is achieved. Similarly, when data stored in the third memory section 2-3 or the fourth memory section 2-4 is read, a voltage of 0 V is applied to the source line 5 and a voltage of 1.2 V is applied to the first bit line 6. A read voltage of 1.5 V is applied to one of the first word line 3 and the second word line 4, and the other one is set to high impedance state. Thus, data reading from the third memory section 2-3 or the fourth memory section 2-4 is achieved.

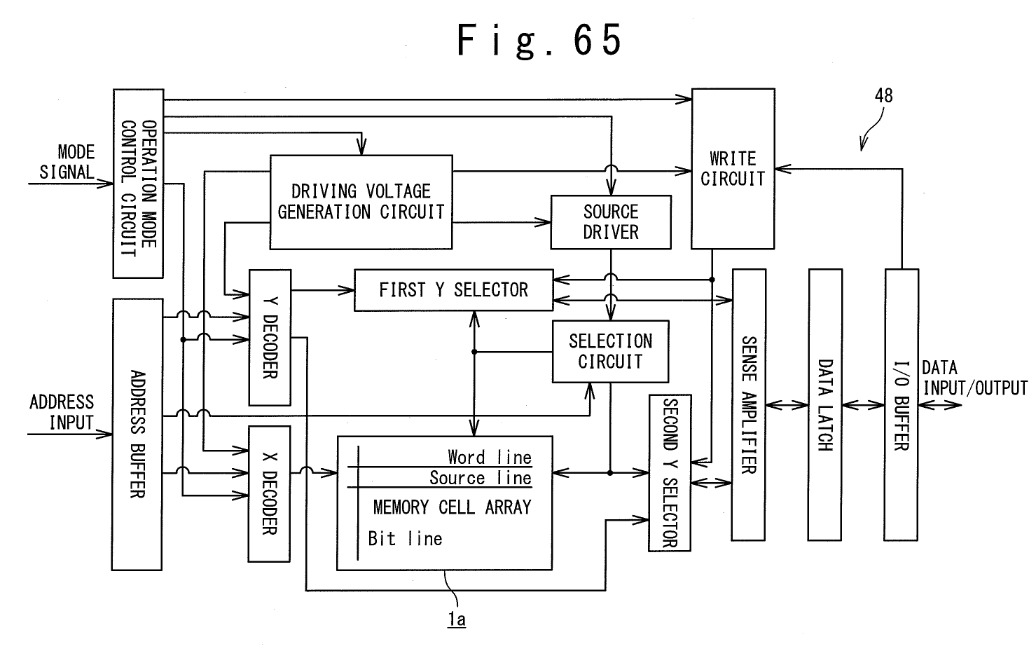

FIG. 65 is a block diagram showing a configuration example of a memory circuit 48 having the above-described memory cell array 1a. The memory circuit 48 may be configured as an independent memory device or may be configured as a part of an integrated circuit such as system LSI.

At the time of data writing, a write mode signal is input to an operation mode control circuit. In response to the write mode signal, the operation mode control circuit outputs a signal for generating a write voltage to a driving voltage generation circuit. The driving voltage generation circuit is a circuit for generating voltages required for the write operation, the erase operation and the read operation. The driving voltage generation circuit generates a write voltage (referred to as a word line write voltage hereinafter) supplied to the word lines, a write voltage (referred to as a bit line write voltage hereinafter) supplied to the bit lines, and a write voltage (referred to as a source line write voltage hereinafter) supplied to the source line. The generated word line write voltage is input to an X decoder. Also, the generated bit line write voltage is input to a write circuit.

A write data which is input through an input/output buffer is input to the write circuit, and the bit line write voltage is output to a first Y selector and a second Y selector. An address signal is input to an address buffer, and an address data is input to the X decoder and a Y decoder. A desired word line is selected by the X decoder and the word line write voltage is applied to the selected word line. A desired Y selector (i.e. first Y selector or second Y selector) and a desired bit line are selected by the Y decoder, and the bit line write voltage which is output from the write circuit is applied thereto. At this time, the source line write voltage is determined by a selection circuit through a source driver. In this manner, the data writing is achieved.

At the time of data erasing, an erase mode signal is input to the operation mode control circuit. In response to the erase mode signal, the operation mode control circuit outputs a signal for generating an erase voltage to the driving voltage generation circuit. The driving voltage generation circuit generates an erase voltage (referred to as a word line erase voltage hereinafter) supplied to the word lines, an erase voltage (referred to as a bit line erase voltage hereinafter) supplied to the bit lines, and an erase voltage (referred to as a source line erase voltage hereinafter) supplied to the source line.

The generated word line erase voltage is input to the X decoder. The bit line erase voltage and the source line erase voltage are input to the source driver. The selection circuit selects the first Y selector side (i.e. bit line) or the second Y selector side (i.e. source line) and applies the erase voltage thereto. It is also possible that the selection circuit selects both the first Y selector and the second Y selector.

At the time of data reading, a read mode signal is input to the operation mode control circuit. In response to the read mode signal, the operation mode control circuit outputs a signal for generating a read voltage to the driving voltage generation circuit. The driving voltage generation circuit generates a read voltage (referred to as a word line read voltage hereinafter) supplied to the word lines, a read voltage (referred to as a bit line read voltage hereinafter) supplied to the bit lines, and a read voltage (referred to as a source line read voltage hereinafter) supplied to the source line.

The generated word line read voltage is input to the X decoder. The generated bit line read voltage is input to the write circuit. An address signal is input to the address buffer, and address data is input to the X decoder and the Y decoder. A desired word line is selected by the X decoder and the word line read voltage is applied thereto. A desired Y selector (i.e. first Y selector or second Y selector) and a desired bit line are selected through the Y decoder, and the bit line read voltage output from the write circuit is applied thereto. A source voltage is determined by the selection circuit through the source driver. A read data which is read out by such an operation is latched by a data latch circuit through the Y selector and a sense amplifier.

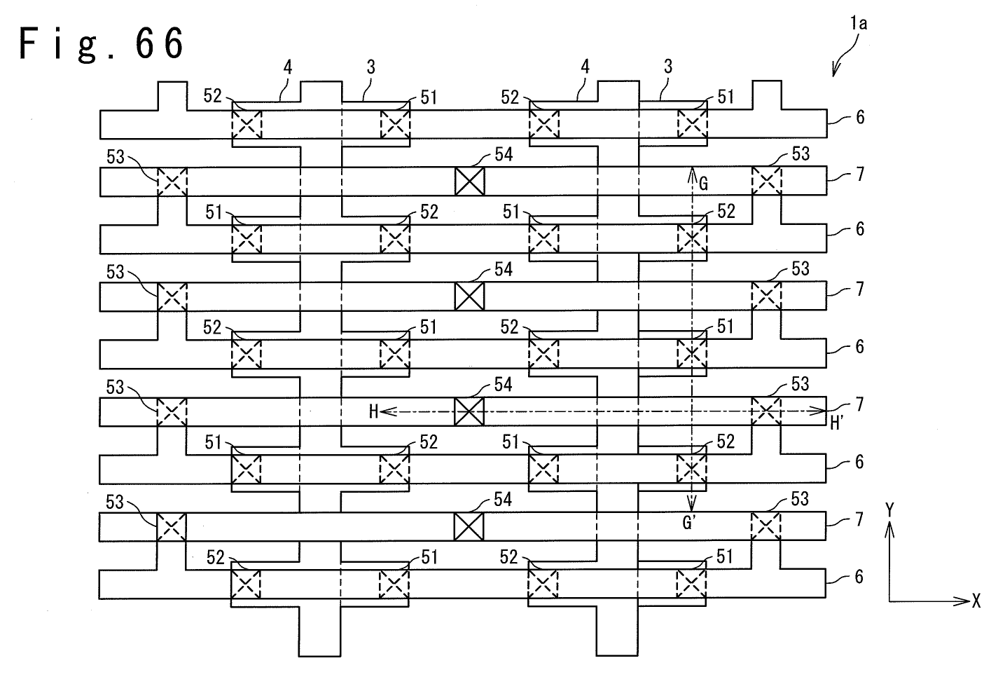

An interconnect layout for achieving the above-described operations will be described below. FIG. 66 is a plan view showing a configuration example of an interconnect layout in the memory cell array 1a. In order to facilitate understanding of the configuration of the interconnect layout according to the present embodiment, semiconductor elements are omitted in FIG. 66 and contacts and metal interconnections are shown.

As shown in FIG. 66, the memory cell array 1a includes a first contact 51, a second contact 52, a third contact 53 and a fourth contact 54. The first contact 51 connects the first word line 3 and the nonvolatile semiconductor memory element 2. The second contact 52 connects the second word line 4 and the nonvolatile semiconductor memory element 2. The third contact 53 connects the first bit line 6 and the nonvolatile semiconductor memory element 2. The fourth contact 54 connects the second bit line 7 and the nonvolatile semiconductor memory element 2. The memory cell array 1a is further provided with a slit-like contact which is connected to the first source/drain region 11, though it is not shown in FIG. 66. The slit-like contact serves as the source line 5. The first contact 51, the second contact 52, the third contact 53, the fourth contact 54 and the source line 5 are preferably made of tungsten or the like. The first word line 3, the second word line 4, the first bit line 6 and the second bit line 7 are preferably aluminum interconnections.

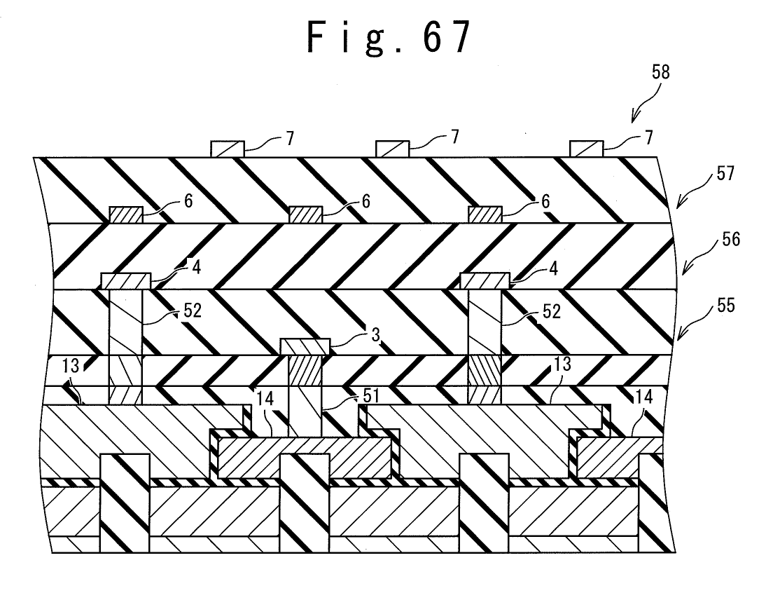

FIG. 67 is a cross sectional view showing a cross sectional structure of the memory cell array 1a. FIG. 67 shows a cross sectional structure which is obtained when the memory cell array 1a is cut along a line segment G-G′ shown in FIG. 66. As shown in FIG. 67, the first word line 3 is provided in a first interconnect layer 55. The first word line 3 is connected to the second word gate 14 of the nonvolatile semiconductor memory element 2 through the first contact 51. The second word line 4 is provided in the second interconnect layer 56. The second word line 4 is connected to the first word gate 13 of the nonvolatile semiconductor memory element 2 through the second contact 52. The first bit line 6 is provided in a third interconnect layer 57, and the second bit line 7 is provide in a fourth interconnect layer 58.

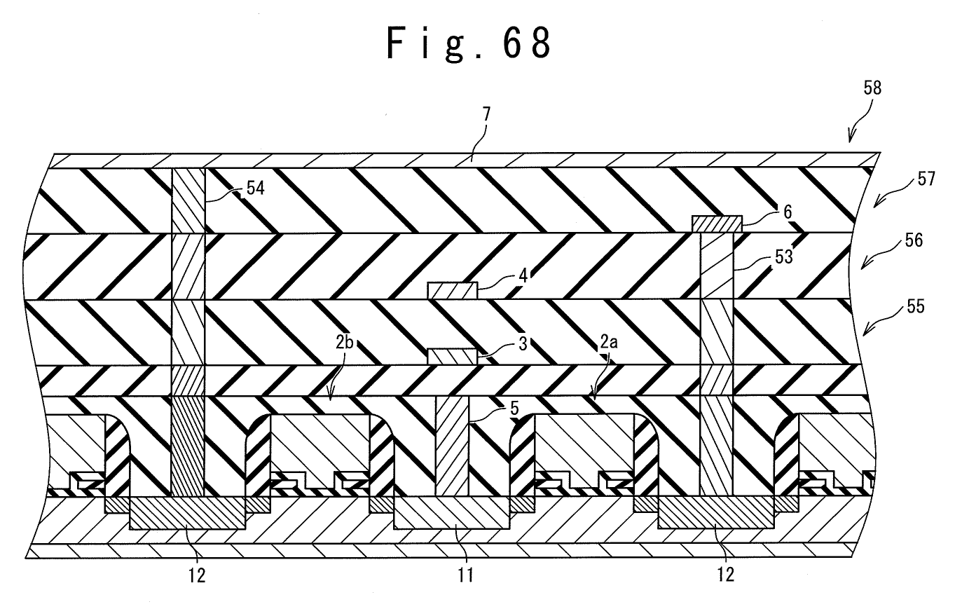

FIG. 68 is a cross sectional view showing a cross sectional structure of the memory cell array 1a. FIG. 68 shows a cross sectional structure obtained when the memory cell array 1a is cut along a line segment H-H′ shown in FIG. 66. As shown in FIG. 68, the source line 5 is provided below the first word line 3. Moreover, two nonvolatile semiconductor memory elements 2 (i.e. first memory cell 2a and second memory cell 2b) are formed on both sides of the source line 5. The second source/drain region 12 on the side of the first memory cell 2a is connected to the first bit line 6 through the third contact 53. The second source/drain region 12 on the side of the second memory cell 2b is connected to the second bit line 7 through the fourth contact 54.

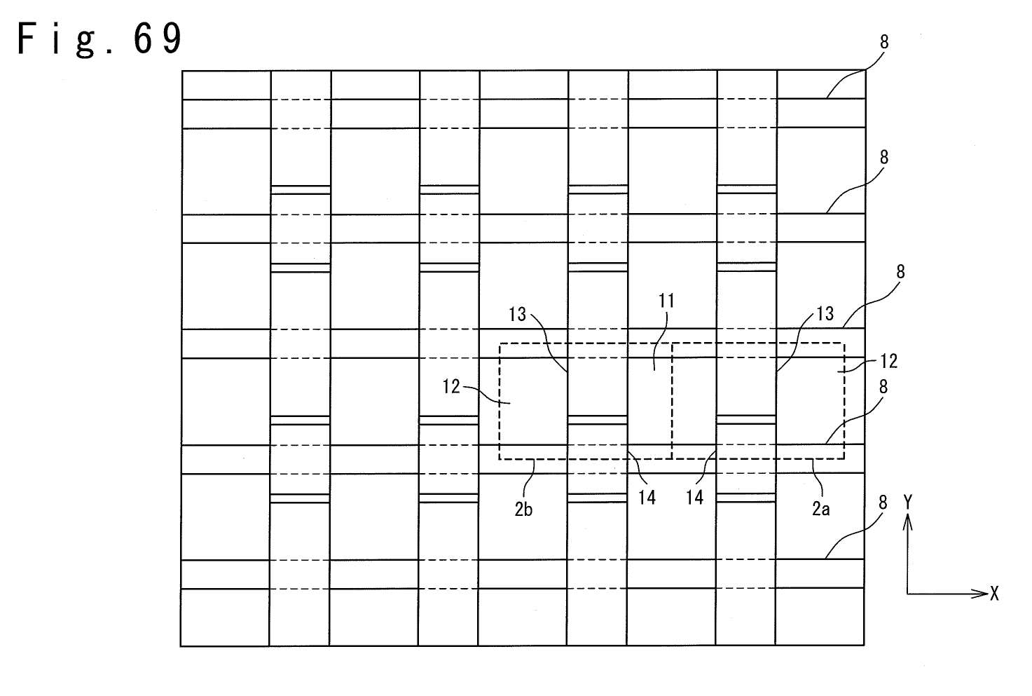

FIGS. 69 to 74 are plan views showing an example of structures of a base layer and the respective interconnect layers. FIG. 69 is a plan view showing a structure of the base layer on which the plurality of nonvolatile semiconductor memory elements 2 are formed. In order to facilitate understanding of the present embodiment, the side wall 16 and the side walls 17 of the nonvolatile semiconductor memory elements 2 are omitted in FIG. 69. As shown in FIG. 69, the plurality of nonvolatile semiconductor memory elements 2 are arranged in an X-axis direction and between the STIs 8. Two adjacent nonvolatile semiconductor memory elements 2 (i.e. first memory cell 2a and second memory cell 2b) sharing the source are provided with the first word gate 13 and the second word gate 14, respectively. The first word gate 13 of a nonvolatile semiconductor memory element 2 is shared by another element 2 which is adjacent thereto through one of the STIs 8. Similarly, the second word gate 14 of the nonvolatile semiconductor memory element 2 is shared by another element 2 which is adjacent thereto through the other STI 8.

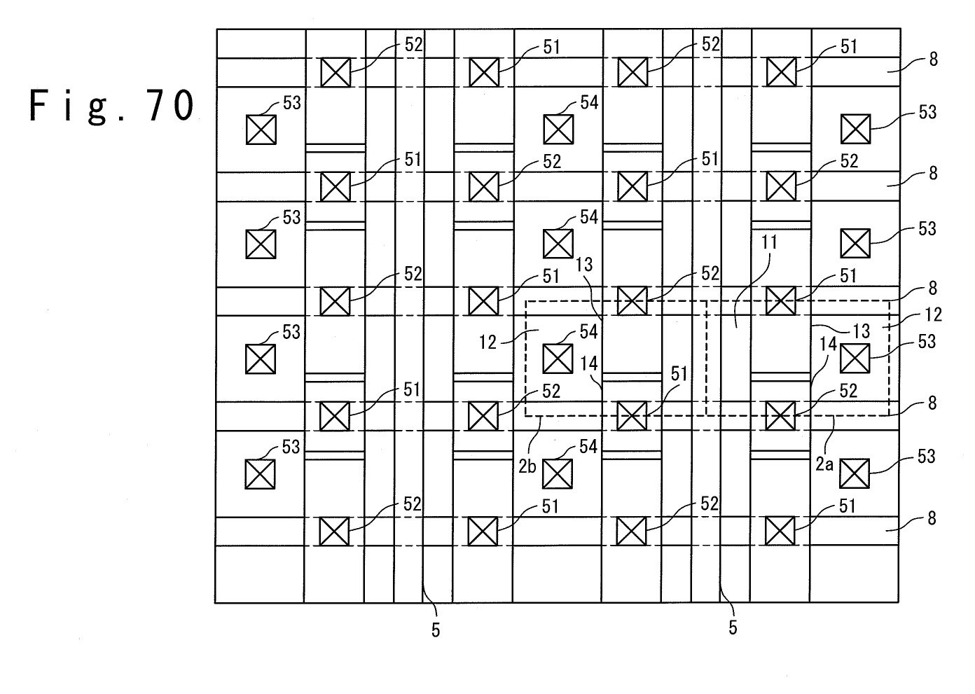

FIG. 70 is a plan view showing a structure in which the contacts are formed on the base layer. As shown in FIG. 70, the first memory cell 2a is formed to be associated with the first contact 51, the second contact 52, the third contact 53 and the source line 5. The second memory cell 2b is formed to be associated with the first contact 51, the second contact 52, the fourth contact 54 and the source line 5.

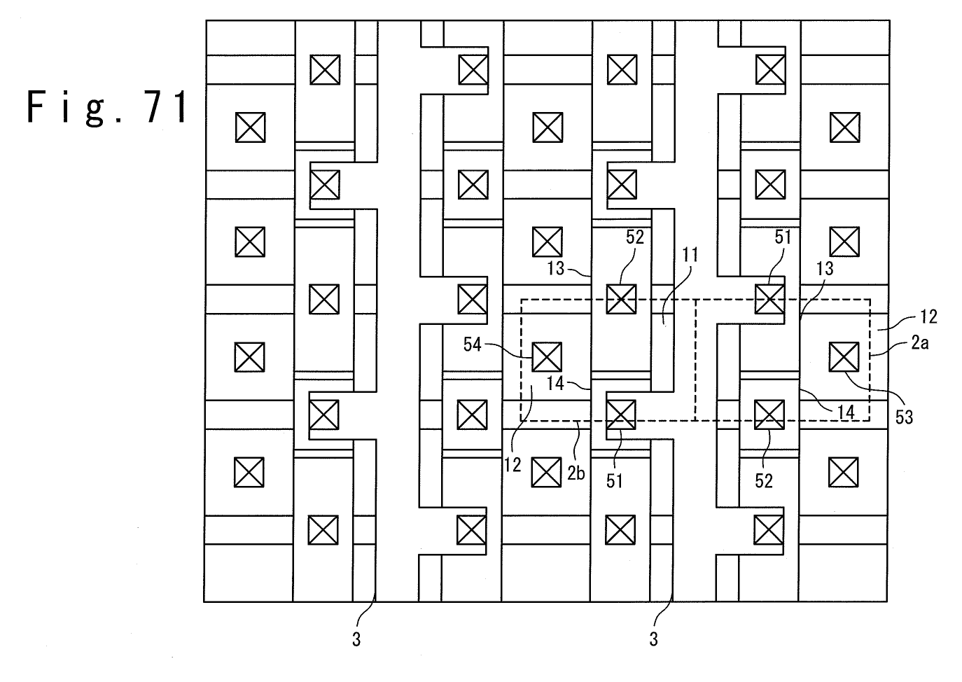

FIG. 71 is a plan view showing the base layer and the first word line 3 formed in the first interconnect layer 55. As shown in FIG. 71, the first word line 3 is connected to the first word gate 13 of the first memory cell 2a through the first contact 51. The same first word line 3 is connected to the second word gate 14 of the second memory cell 2b through the first contact 51.

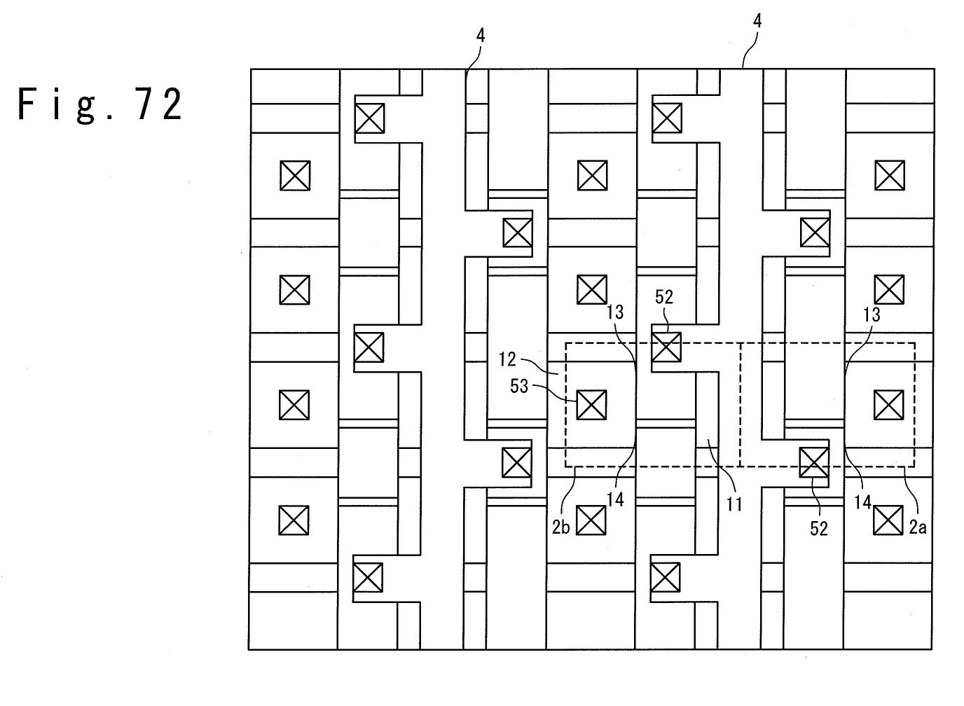

FIG. 72 is a plan view showing the base layer and the second word line 4 formed in the second interconnect layer 56. In order to facilitate understanding of the present embodiment, the first interconnect layer 55 is omitted in FIG. 72. As shown in FIG. 72, the second word line 4 is connected to the second word gate 14 of the first memory cell 2a through the second contact 52. The same second word line 4 is connected to the first word gate 13 of the second memory cell 2b through the second contact 52.

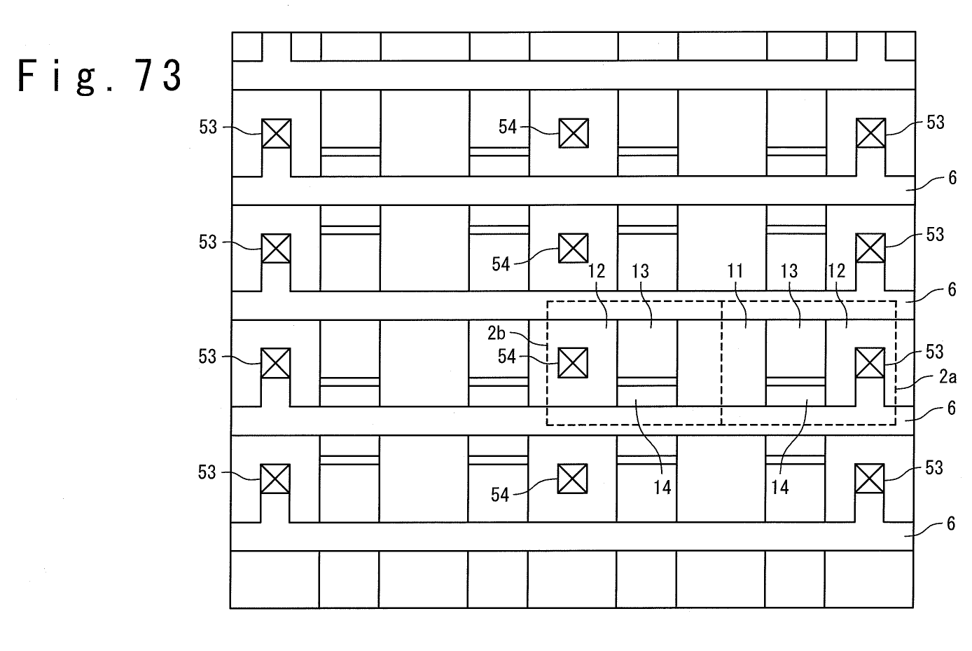

FIG. 73 is a plan view showing the base layer and the first bit line 6 formed in the third interconnect layer 57. In order to facilitate understanding of the present embodiment, the first interconnect layer 55 and the second interconnect layer 56 are omitted in FIG. 73. As shown in FIG. 73, the first bit line 6 is connected to the second source/drain region 12 on the side of the first memory cell 2a through the third contact 53. Here, the first bit line 6 is not connected to the second source/drain region 12 on the side of the second memory cell 2b.

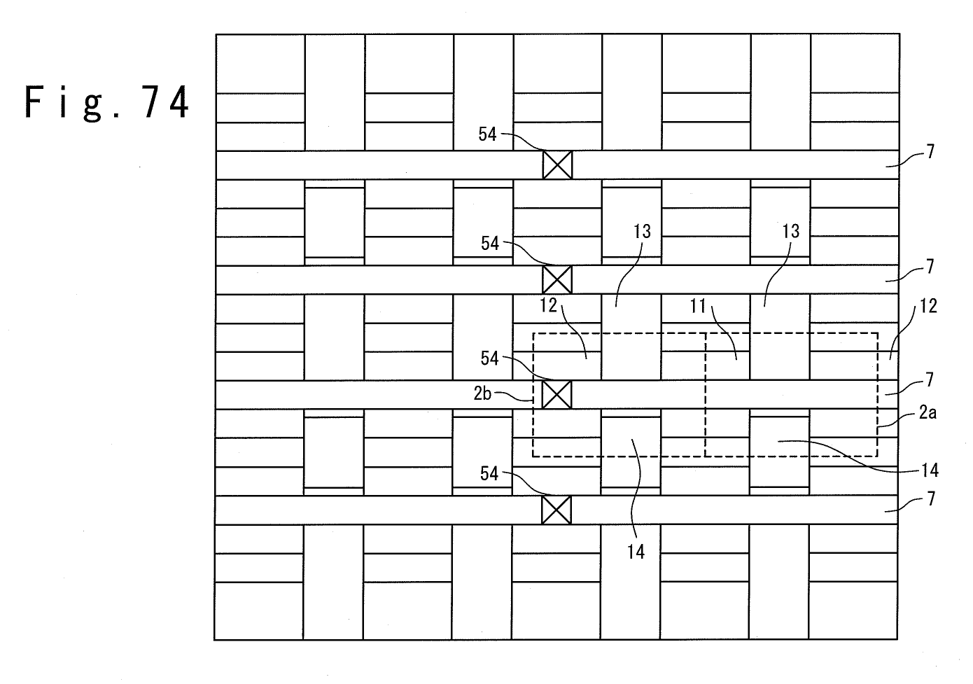

FIG. 74 is a plan view showing the base layer and the second bit line 7 formed in the fourth interconnect layer 58. In order to facilitate understanding of the present embodiment, the first interconnect layer 55, the second interconnect layer 56 and the third interconnect layer 57 are omitted in FIG. 74. As shown in FIG. 74, the second bit line 7 is connected to the second source/drain region 12 on the side of the second memory cell 2b through the fourth contact 54. Here, the second bit line 7 is not connected to the second source/drain region 12 on the side of the first memory cell 2a.

It is apparent that the present invention is not limited to the above embodiments and may be modified and changed without departing from the scope and spirit of the invention.

What is claimed is:

1. A nonvolatile semiconductor memory device comprising:
a first source/drain diffusion region;
a second source/drain diffusion region;
a channel region between said first source/drain diffusion region and said second source/drain diffusion region;
a first charge storage layer formed on said channel region;
a second charge storage layer formed in a same layer as said first charge storage layer and electrically isolated from said first charge storage layer;
a first gate electrode; and
a second gate electrode electrically isolated from said first gate electrode,
wherein said first charge storage layer includes a first memory section and a second memory section,
said second charge storage layer includes a third memory section and a fourth memory section,
said first gate electrode is formed on said first memory section and said third memory section, and
said second gate electrode is formed on said second memory section and said fourth memory section.

2. The nonvolatile semiconductor memory device according to claim 1, further comprising:
a first isolation region configured to electrically isolate said first memory section and said second memory section from each other; and
a second isolation region configured to electrically isolate said third memory section and said fourth memory section from each other.

3. The nonvolatile semiconductor memory device according to claim 1,
wherein said first charge storage layer and said second charge storage layer are separated from each other in a first direction,
said first memory section and said second memory section are separated from each other in a second direction orthogonal to said first direction, and
said third memory section and said fourth memory section are separated from each other in said second direction.

4. The nonvolatile semiconductor memory device according to claim 1,
wherein said first gate electrode is formed independently of said second memory section and said fourth memory section and is configured to apply a first gate voltage simultaneously to said first memory section and said third memory section, and
wherein said second gate electrode is formed independently of said first memory section and said third memory section and is configured to apply a second gate voltage simultaneously to said second memory section and said fourth memory section.

5. A nonvolatile semiconductor memory device comprising memory elements arranged in an array form,
wherein each of said memory elements comprises:
a first charge storage layer including a first trap region and a second trap region;
a second charge storage layer including a third trap region and a fourth trap region;
a first gate electrode formed on said first trap region and said third trap region; and
a second gate electrode formed on said second trap region and said fourth trap region.

6. A semiconductor device comprising:
a first element formed between a first device isolation and a second device isolation and comprising: a first gate formed on a side of said first device isolation; and a second gate formed on a side of said second device isolation;
a second element formed between said first device isolation and said second device isolation and comprising: a third gate formed on a side of said second device isolation and a fourth gate formed on a side of said first device isolation;
a first source diffusion region shared by said first element and said second element;
a first drain diffusion region associated with said first element;
a second drain diffusion region associated with said second element;
a first interconnection connected to said first gate and said fourth gate;
a second interconnection connected to said second gate and said third gate;
a third interconnection connected to said first drain diffusion region; and
a fourth interconnection connected to said second drain diffusion region.

7. The semiconductor device according to claim 6, further comprising:
a second source diffusion region;
a third element that shares said second drain diffusion region with said second element;
a fourth element that shares said second source diffusion region with said third element; and
a third drain diffusion region associated with said fourth element,
wherein said third interconnection is connected to each of said first drain diffusion region and said third drain diffusion region.

8. The semiconductor device according to claim 7, further comprising:
a third source diffusion region;
a fifth element that shares said first drain diffusion region with said first element;
a sixth element that shares said third source diffusion region with said fifth element; and
a fourth drain diffusion region associated with said sixth element,
wherein said fourth interconnection is connected to each of said second drain diffusion region and said fourth drain diffusion region.
